(19) United States
(12) Patent Application Publication
(10) Pub. No.: US 2012/0187386 A1
(43) Pub. Date: Jul. 26, 2012

(54) ORGANIC ELECTRO LUMINESCENCE DISPLAY DEVICE AND METHOD FOR MANUFACTURING SAME

(75) Inventor: Tatsuya Matsumi, Kanagawa (JP)

(73) Assignee: Sony Corporation, Tokyo (JP)

(21) Appl. No.: 13/348,762

(22) Filed: Jan. 12, 2012

(30) Foreign Application Priority Data
Jan. 20, 2011 (JP) 2011-009853

(51) Int. Cl. H01L 51/54; H01L 51/56

(52) U.S. Cl. 257/40; 438/34; 257/E51.026; 257/E51.018

(57) ABSTRACT

Disclosed herein is an organic electro luminescence display device including: on a substrate, a plurality of lower electrodes provided correspondingly in number to organic electro luminescence elements for a plurality of color light emissions; an organic layer provided on the lower electrodes and including a plurality of hole injection/transport layers having at least one of hole injection and hole transport characteristics, a plurality of organic light-emitting layers; and a plurality of electron injection/transport layers having at least one of electron injection and electron transport characteristics, and an upper electrode formed on the organic layer. The hole injection/transport layer, the organic light-emitting layer and the electron injection/transport layer are classified into an individual layer and a common layer. A thickness of the common layer is larger than a thickness of the individual layer.

### BACKGROUND

The present disclosure relates to an organic electro luminescence (EL) display device making use of an organic electro luminescence phenomenon and a method for manufacturing same.

As the information and communication industry is being acceleratedly developed, there have been demanded high-performance display elements. Among them, organic EL elements, to which attention has been paid as a next-generation display element, have advantages in that not only they have a wide view angle when used as a spontaneous luminescent-type display element and are excellent in contrast, but also a response time is fast.

The materials used as an emission layer of an organic EL element are broadly classified into low molecular weight materials and high molecular weight materials. It is known that low molecular weight materials generally show a higher luminescent efficiency and a longer life. Especially, they have been accepted to show a high blue color performance.

The organic film is formed by a dry method (deposition method) such as a vacuum deposition method for low molecular weight materials and by a wet method (coating method), such as a spin coating method, an inkjet method or a nozzle coating method, for high molecular weight materials.

The vacuum deposition method is advantageous in that it is not necessary to dissolve an organic thin film formation material in solvents and thus, a step of removing the solvent after film formation is unnecessary. In this regard, however, the vacuum deposition method has a difficulty in selective coating with a metal mask and especially, is high in costs of manufacturing equipment for large-sized panel, so that a difficulty is also involved in application to substrates for large-sized display screen and also in mass-production. Hence, attention has been paid to an inkjet method or a nozzle coating that is relatively easy in making a large-sized display screen.

However, a blue light-emitting material out of high molecular weight materials used in the inkjet method or nozzle coating method is low in emission brightness and life characteristic and is not suitable for practical use. Hence, it has been accepted as being difficult to form a blue light-emitting layer in pattern according to a coating method.

In Japanese Patent Nos. 4062352 (Japanese Patent Laid-open No. 2007-073532) and 3899566 (Japanese Patent Laid-open No. Hei 10-153967), for example, there are disclosed display devices wherein a red light-emitting layer and a green light-emitting layer are formed by a coating method such as an inkjet method, on which a blue light-emitting layer and others, which cannot ensure satisfactory characteristics when using a coating method, are formed as a common layer by a vacuum deposition method.

### SUMMARY

However, with the organic EL display devices set out in Japanese Patent Nos. 4062352 (Japanese Patent Laid-open No. 2007-073532) and 3899566 (Japanese Patent Laid-open No. Hei 10-153967), a problem is involved in that brightness and color unevennesses are caused within a panel plane. This is ascribed to a difference in luminescent efficiency and a variation in chromaticity on element-to-element basis of the organic EL display elements. With organic EL display devices provided with a micro resonator structure, it is necessary in view of the characteristics of the micro resonator to exactly control the film thickness of the organic layers including light-emitting layers, which are sandwiched between a pixel electrode and a counter electrode. In the film formation method making use of coating techniques, it has generally been difficult to control the film thickness because of the necessity for drying or heating treatment for removing a solvent after film formation. More particularly, when compared with vacuum deposition methods, the film thickness remains out of control to an extent of about several times to ten and several times. Therefore, there have been demanded a readjustment or improvement of coating and peripheral steps and an improvement in structure of device per se. However, because the device becomes complicated and electric characteristics of the display device have to be degraded, new improvements have been expected.

Accordingly, it is desirable to provide an organic EL display device that is able to reduce a difference in luminescent efficiency and a variation in chromaticity on element-to-element basis and also a method for manufacturing same.

According to an embodiment of the present disclosure, there is provided an organic electro luminescence display device including: on a substrate, a plurality of lower electrodes provided correspondingly in number to organic electro luminescence elements for a plurality of color light emissions; an organic layer provided on the lower electrodes and including a plurality of hole injection/transport layers having at least one of hole injection and hole transport characteristics, a plurality of organic light-emitting layers; and a plurality of electron injection/transport layers having at least one of electron injection and electron transport characteristics, and an upper electrode formed on the organic layer. The hole injection/transport layer, the organic light-emitting layer and the electron injection/transport layer are classified into an individual layer formed for each of the organic electro luminescence elements for the respective color light emissions and a common layer formed on the entire surface of the organic electro luminescence elements of the respective color light emissions. A thickness of the common layer is larger than a thickness of the individual layer.

According to another embodiment of the present disclosure, there is provided a method for manufacturing an organic electro luminescence display device including: forming, on a substrate, a lower electrode for each of first organic electro luminescence elements for blue light emission and second organic electro luminescence elements for other light emission; forming a hole injection/transport layer having at least one of hole injection and hole transport characteristics on the lower electrode for each of the first organic electro luminescence elements and the second organic electro luminescence elements according to a coating method; forming a second organic light-emitting layer for other light emission on the hole injection/transport layer for the second organic electro luminescence element according to a coating method; forming a first organic light-emitting layer for blue light emission over an entire surface of the second organic light-emitting layer and the hole injection/transport layer for the first organic electro luminescence element according to a vacuum deposition method; forming an electron injection/transport layer having at least one of electron injection and electron transport characteristics on the first organic light-emitting layer and the second organic light-emitting layer according to a vacuum deposition method; and forming an upper electrode over an entire surface of the electron injection/transport layer.

According to further embodiment of the present disclosure, there is provided a method for manufacturing an organic electro luminescence display device including: forming, on a substrate, a plurality of lower electrodes for a corresponding plurality of organic electro luminescence elements; forming a plurality of hole injection/transport layers having at least one of hole injection and hole transport characteristics on the lower electrodes with respect to each of the organic electro luminescence elements according to a coating method; forming a plurality of organic light-emitting layers on the hole injection/transport layers with respect to each of the organic electro luminescence elements according to a coating method; forming an electron injection/transport layer having at least one electron injection and electron transport characteristics over an entire surface of the plurality of organic light-emitting layers according to a vapor deposition method; and

forming an upper electrode over an entire surface of the electron injection/electron transport layer.

In the organic EL display device and its manufacturing method of the present disclosure, the common layer formed by a vacuum deposition method is thicker than individual layers formed by a coating method, so that a variation in layer thickness among the organic EL elements can be reduced. In this way, it is enabled to suppress a difference in luminescent efficiency and a variation in chromaticity among the organic EL elements. More particularly, brightness and color unevennesses in the organic EL display device provided with a plurality of organic EL elements are reduced.

### BRIEF DESCRIPTION OF THE DRAWINGS

FIG. 1 is a schematic view showing an configuration of an organic EL display device according to a first embodiment of this disclosure;

FIG. 2 is a view showing an example of a pixel drive circuit shown in FIG. 1;

FIG. 3 is a sectional view showing a configuration of a display region shown in FIG. 1;

FIG. 4 is a flowchart showing a method for manufacturing an organic EL display device shown in FIG. 1;

FIGS. 5A to 5I are, respectively, sectional views showing the steps of the manufacturing method shown in FIG. 4;

FIG. 6 is a sectional view configuring an organic EL display device according to a second embodiment of the disclosure;

FIG. 7 is a flowchart showing a manufacturing method of an organic EL display device shown in FIG. 6;

FIG. 8 is a plan view showing a schematic configuration of a module including the display device of the above embodiment;

FIG. 9 is a perspective view showing an appearance of Application Example 1 of the display device of the embodiment;

FIGS. 10A and 10B are, respectively, a perspective view showing an appearance of Application Example 2 as viewed from the front side thereof and a perspective view showing an appearance as viewed from the rear side;

FIG. 11 is a perspective view showing an appearance of Application Example 3;

FIG. 12 is a perspective view showing an appearance of Application Example 4;

FIGS. 13A to 13G are, respectively, a front view of Application Example 5 in an open state, a side view, a front view in a closed state, a left side view, a right side view, an top plan view and a bottom view; and

FIGS. 14A and 14B are, respectively, characteristic graphs showing variations in chromaticity in Example and Comparative Example.

### DETAILED DESCRIPTION OF THE PREFERRED EMBODIMENTS

### First Embodiment

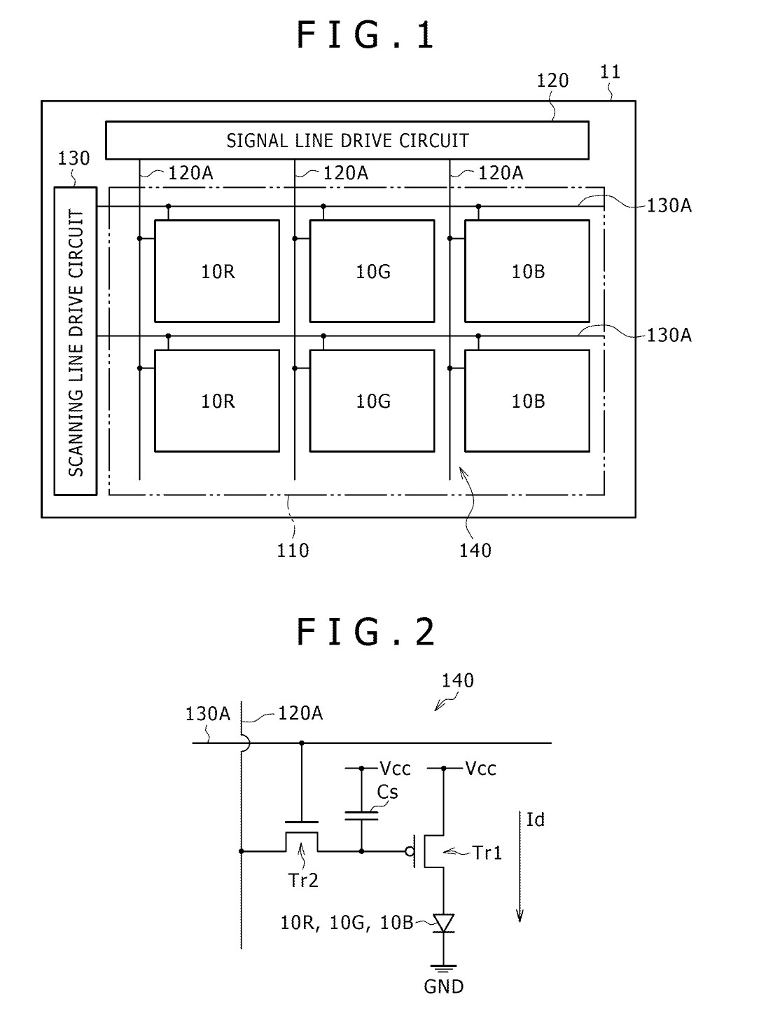

FIG. 1 shows an organic EL display device according to a first embodiment of this disclosure. This organic EL display device is one used as an organic EL television apparatus and includes, for example, a substrate 11, on which a plurality of red organic EL elements 10R, green organic EL elements 10G and blue organic EL elements 10B as will be described hereinafter are arranged in matrices as a display region 110. Around the periphery of the display region 110, there are provided a signal line drive circuit 120 that is a driver for picture display and a scanning line drive circuit 130.

A pixel drive circuit 140 is provided inside the display region 110. FIG. 2 shows an example of the pixel drive circuit 140. The pixel drive circuit 140 is an active drive circuit formed below a lower electrode 14 described hereinafter. More particularly, this pixel drive circuit 140 has a drive transistor Tr1 and a write transistor Tr2, a capacitor (retentive capacity) Cs provided between these transistors Tr1 and TR2, and a red organic EL element 10R (or a green organic EL element 10G or a blue organic EL element 10B) connected in series with the drive transistor Tr1 inbetween a first power supply line (Vcc) and a second power supply line (GND). The drive transistor Tr1 and write transistor Tr2 are each constituted of an ordinary thin film transistor (TFT) and may be, for example, of either an inverted staggered structure (a so-called bottom gate type) or a staggered structure (a top gate type) and is not critically limited in type.

In the pixel drive circuit 140, a plurality of signal lines 120A are arranged along column direction and a plurality of scanning lines 130A are arranged along row direction. The intersection point between each signal line 120A and each scanning line 130A corresponds to one (subpixel) of the red organic EL element 10R, green organic EL element 10G and blue organic EL element 10B. The respective signal lines 120A are connected to the signal line drive circuit 120, and an image signal is fed from this signal line drive circuit 120 via the signal line 120A to a source electrode of the write transistor Tr2. The respective scanning lines 130A are connected to the scanning line drive circuit 130 and scanning signals are successively fed from the scanning line drive circuit 130 via the scanning line 130A to a gate electrode of the write transistor Tr2.

In the display region 110, there are arranged red organic EL elements emitting red light (second organic EL element) 10R, green organic EL elements emitting green light (second organic EL element) 10G and blue organic EL elements emitting blue light (first organic EL element) are successively arranged in matrices as a whole. It will be noted that a combination of adjacent red organic EL element 10R, green organic EL element 10G and blue organic EL element 10B constitutes one pixel.

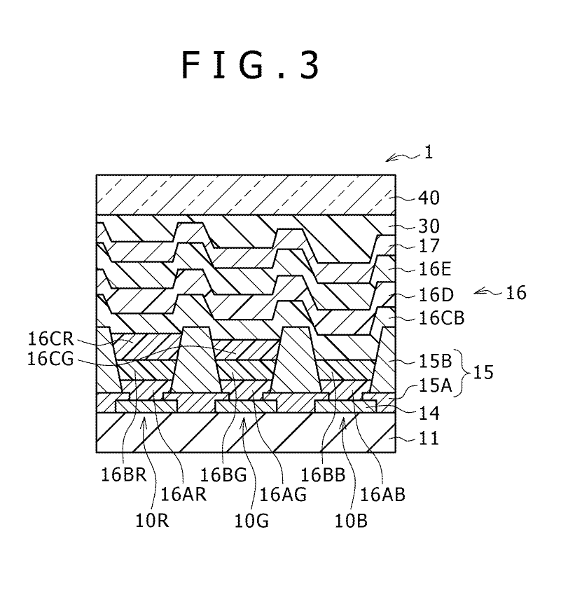

FIG. 3 shows a sectional configuration of the display region 110 shown in FIG. 1. The red organic EL element 10R, green organic EL element 10G, and blue organic EL element 10B, respectively, have structures, which have therebetween the transistor Tr1 of the pixel drive circuit 140 set out above and a flattening insulating film (not shown) and which include, as viewed from the side of the substrate 11, a lower electrode 14 serving as an anode, a partition wall 15, an organic layer 16 including a light-emitting layer 16C described hereinlater, and an upper electrode 17 serving as a cathode, stacked successively in this order.

Such a red organic EL element 10R, green organic EL element 10G, and blue organic EL element 10B are covered with a protective layer 30, and are sealed by bonding a sealing substrate 40 made of glass on the entire surface of the protective layer 30 via an adhesive layer (not shown) made of a thermosetting or UV-curing resin.

The substrate 11 is a support forming, on one main surface side thereof, an array of the red organic EL elements 10R, green organic EL elements 10G, and blue organic EL elements 10B, and may be made of known materials including, for example, quartz, glass, silicon, a metal foil and a resin film or sheet. Of these, quartz and glass are preferred. When using a resin substrate, the materials therefor include methacrylic resins, typical of which is polymethyl methacrylate (PMMA), polyesters including polyethylene terephthalate (PET), polyethylene naphthalate (PEN), polybutylene naphthalate (PBN) and the like, or polycarbonates. In order to suppress water permeability and gas permeability, it is necessary to provide a laminated structure or carry out surface treatment.

The lower electrode 14 is provided on the substrate 11 for each of the red organic EL element 10R, green organic EL element 10G, and blue organic EL element 10B. The lower electrode 14 has a thickness along the lamination direction (hereinafter referred to simply as thickness), for example, of from 10 nm to 1000 nm, and is formed of an elemental substance or an alloy of metal elements such as chromium (Cr), gold (Au), platinum (Pt), nickel (Ni), copper (Cu), tungsten (W) and silver (Ag). The lower electrode 14 may have a laminated structure of a metal film of an elemental metal or an alloy of such metal elementals and a transparent conductive film of an alloy such as indium tin oxide (ITO), InZnO (indium zinc oxide), and an alloy of zinc oxide and aluminum. It will be noted that if the lower electrode 14 is used as an anode, it is desirable that the lower electrode 14 be formed of a material whose hole injectionability is high. In this regard, however, materials, such as an aluminum (Al) alloy, which present a problem on a hole injection barrier ascribed to the presence of a surface oxide film and also to the work function not so great, may also be usable as the lower electrode 14 by provision of an appropriate hole injection layer 16A. With the case of a so-called top-emission type wherein light generated at a light-emitting layer 16C is taken out from the upper electrode 17, described hereinafter, at a side opposite to the substrate 11, the lower electrode 14 makes use, as a mirror, of a conductive material with excellent reflectivity. In this case, the reflectance of the lower electrode is preferably at not less than 40%.

The partition wall 15 is one that ensures insulation between the lower electrode 14 and the upper electrode 17 and forms the emission region in a desired shape. Moreover, the wall 15 also functions as a partition wall when coating is carried out by an inkjet or nozzle coating method in a manufacturing process described hereinafter. The partition wall 15 includes, for example, a lower partition wall 15A made of an inorganic insulating material such as SiO₂ or the like and an upper partition wall 15B formed thereon and made of a photosensitive resin such as a positive photosensitive polybenzoxazole, a positive photosensitive polyimide or the like. The partition wall 15 has an opening corresponding to the emission region. It will be noted that although the organic layer 16 and the upper electrode 17 may be formed not only at the opening, but also over the partition wall 15, light emission occurs only at the opening of the partition wall 15.

The organic layer 16 of the red organic EL element 10R is configured to have a laminated structure including, for example, as stacked in the order from the side of the lower electrode 14, a hole injection layer 16AR, a hole transport layer 16BR, a red light-emitting layer 16CR, a blue light-emitting layer 16CB, an electron transport layer 16D and an electron injection layer 16E. The organic layer 16 of the green organic EL element 10G is configured to have a laminated structure including, for example, as stacked in the order from the side of the lower electrode 14, a hole injection layer 16AG, a hole transport layer 16BG, a green light emitting layer 16CG, a blue light-emitting layer 16CB, an electron transport layer 16D and an electron injection layer 16E. The organic layer 16 of the blue organic EL element 10B is configured to have a laminated structure including, for example, as stacked in the order from the side of the lower electrode 14, a hole injection layer 16AB, a hole transport layer 16BB, a blue light-emitting layer 16CB, an electron transport layer 16D and an electron injection layer 16E. It is to be noted that the layers formed only in the respective color elements among the constituent layers of the organic EL elements 10R, 10G and 10B, i.e. the hole injection layers 16AR, 16AG and 16AB, hole transport layers 16BR, 16BG and 16BB, and red light-emitting layer 16CR and green light-emitting layer 16CG, are taken herein as an individual layer. The layers formed over the entire surface of the respective color organic EL elements, i.e. the blue light-emitting layer 16CB, electron transport layer 16D and electron injection layer 16E, are taken herein as a common layer common to all the elements including the red organic EL element 10R, green organic EL element 10G and blue organic EL element 10B.

The hole injection layers 16AR, 16AG and 16AB are ones that enhance an efficiency of hole injection to the respective emission layers (red light-emitting layer 16CR, green light-emitting layer 16CG and blue light-emitting layer 16CB) and also serve as a buffer layer preventing leakage, and are provided on the lower electrode 14 at each of the red organic EL element 10R, green organic EL element 10G and blue organic EL element 10B.

The thickness of the hole injection layers 16AR, 16AG, and 16AB are preferably at 5 nm to 100 nm, more preferably at 8 nm to 50 nm, for example. The constituent material of the hole injection layers 16AR, 16AG, and 16AB may be properly chosen in relation with the types of materials of the electrode and an adjacent layer. Mention is made of polyaniline, polythiophene, polypyrrole, polyphenylenevinylene, polythienylenevinylene, polyquinoline, polyquinoxaline and derivatives thereof, conductive high molecular weight materials such as polymers containing an aromatic amine structure at the main or side chain thereof, metal phthalocyanines (such as copper phthalocyanine and the like), and carbon.

Where high molecular weight materials are used for the hole injection layers 16AR, 16AG, and 16AB, the weight average molecular weight (Mw) of such a high molecular weight material may be within a range of 10,000 to 300,000, preferably 5,000 to about 200,000. Alternatively, there may be used an oligomer having a molecular weight of about 2,000 to 10,000. In this regard, however, if the molecular weight Mw is less than 5,000, there is concern that when layers are formed subsequently to the hole transport layer, the hole injection layer may be dissolved. When the molecular weight exceeds 300,000, such a material is gelled with concern that a difficulty may be involved in film formation.

Typical conductive high molecular weight materials used as a constituent material for the hole injection layers 16AR, 16AG, and 16AB include, for example, polyaniline, oligoaniline, polydioxythiophenes such as poly(3,4-ethylenedioxythiophene) (PEDOT), and the like. Besides, mention is made of a polymer commercially sold under the name of Nafion (registered tradename), made by H.C Starck, a polymer commercially sold in dissolved form under the commercial name of Liquion (registered tradename), EL Source (registered tradename), made by Nissan Chemical industries, Ltd., conductive polymer Berazol (registered tradename), made by SokenChemical & Engineering Co., Ltd., and the like.

The hole transport layers 16BR and 16BG of the red organic EL element 10R and green organic EL element 10G are ones that enhance an efficiency of hole transport to the red light-emitting layer 16CR and green light-emitting layer 16CG, respectively. The hole transport layers 16BR and 16BG are, respectively, formed on the hole injection layers 16AR and 16AG of the red organic EL element 10R and green organic EL element 10G.

The thickness of the hole transport layers 16BR and 16BG may differ depending on the whole configuration of the elements and is preferably at 10 nm to 200 nm, more preferably at 15 nm to 150 nm, for example. The high molecular weight materials for the hole transport layers 16BR and 16BG are light-emitting materials soluble in organic solvents and including, for example, polyvinylcarbazole, polyfluorene, polyaniline, polysilane and derivatives thereof, polysiloxane derivatives having an aromatic amine at a side or main chain, polythiophene and derivatives thereof, polypyrrole and the like.

Where a high molecular weight material is used for the hole transport layers 16BR and 16BG, the weight average molecular weight (Mw) is preferably at 50,000 to 300,000, more preferably at 100,000 to 200,000. If the molecular weight Mw is less than 50,000, low molecular weight components in the high molecular weight material are left out during the formation of the light-emitting layer 16C, thereby causing dots to be formed in the hole injection layer 16A and the hole transport layer 16B, with concern that the initial performance of the organic EL elements may lower or element degradation may be caused. On the other hand, when the weight average molecular weight exceeds 300,000, the material is gelled with concern that element degradation is caused to occur. It will be noted that the weight average molecular weight (Mw) is a value of a weight average molecular weight converted as polystyrene and determined by gel permeation chromatography (GPC) using a tetrahydrofuran solvent.

When the red light-emitting layer 16CR and green light-emitting layer 16CG are applied with an electric field, electrons and holes are re-combined thereby permitting light emission. The thickness of the red light-emitting layer 16CR and green light-emitting layer 16CG may differ depending on the whole configuration of an element and is preferably, for example, at 10 nm to 200 nm, more preferably at 15 nm to 150 nm. The red light-emitting layer 16CR and green light-emitting layer 16CG are, respectively, formed of a mixed material wherein a low molecular weight material is added to a high molecular weight material (light-emitting). The low molecular weight material means a monomer or an oligomer wherein two to ten monomers are bound together and is preferably one having a weight average molecular weight of not larger than 10,000. It will be noted that low molecular weight materials whose weight average molecular weight exceeds the above range are not necessarily excluded.

Although details will be described hereinafter, the red light-emitting layer 16CR and green light-emitting layer 16CG are, respectively, formed by a coating method such as, for example, an inkjet method. For this purpose, high molecular weight materials and low molecular weight materials are dissolved in at least one of organic solvents including, for example, toluene, xylene, anisole, cyclohexanone, mesitylene (1,3,5-trimethylbenzene), pseudocumene (1,2,4-trimethylbenzene), dihydrobenzofuran, 1,2,3,4-tetramethylbenzene, tetralin, cyclohexylbenzene, 1-methylnaphthalene, p-anisyl alcohol, dimethylnaphthalene, 3-methylbiphenyl, 4-methylbiphenyl, 3-isopropylbiphenyl, monoisopropylnaphthalene and the like, and the resulting mixture solution is used to form the layers.

The constituent high molecular weight materials for the red light-emitting layer 16CR and green light-emitting layer 16CG include, for example, light-emitting high molecular weight materials such as polyfluorene-based high molecular weight material derivatives, polyphenylenevinylene derivatives, polyphenylene derivatives, polyvinyl carbazole derivatives, polythiophene derivatives and the like. In this embodiment, as a light-emitting high molecular weight material layer capable of emitting light from an singlet exciton, mention is made of a high molecular weight material commercially available under the name of ADS111RE (registered tradename, formula (1-1)), made by American Dye Source Inc., for the red light-emitting layer 16CR and a high molecular weight material commercially available under the name of ADS109GE (registered tradename, formula (1-2)), made by the above company, for the green light-emitting layer 16CG. It will be noted that the high molecular weight materials used herein not only are not limited to conjugated high molecular weight materials, but also include pendant non-conjugated high molecular weight materials and dye-mixed type, non-conjugated high molecular weight materials. In addition, there may be further used light-emitting dendrimer-type high molecular weight material materials, which have been being developed recently and which is constituted of a core molecule located at the center thereof and side chains called dendron. The substituent groups contained in the high molecular weight material materials are not critical, and substituent groups having electron transportability and/or hole transportability may be contained, if necessary, in the main skeletons shown in the formulas (1-1) and (1-2). Moreover, as to a light-emitting site, there are known those capable of generating light from a singlet exciton, a triplet exciton or both. The light-emitting layer 16C of this embodiment may contain any of such emission sites.

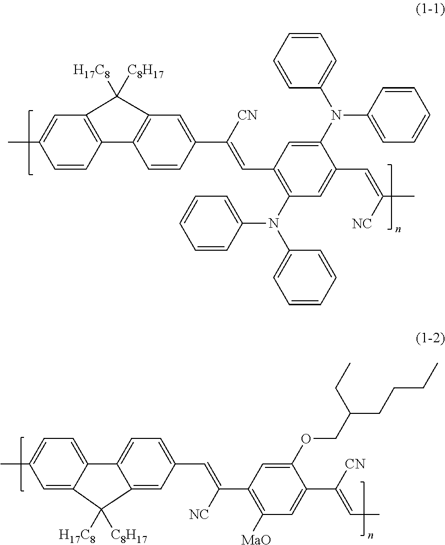

Emission units other than those indicated above include aromatic compounds and heterocyclic compounds such as anthracene, naphthalene, phenanthrene, pyrene, tetracene, coronene, chrysene, fluorescein, perylene, phthaloperylene, naphthaloperylene, perinone, phthaloperinone, naphthaloperinone, diphenylbutadiene, tetraphenylbutadiene, coumarin oxadiazole, aldazine, bisbenzoxazoline, bisstyryl, pyrazine, cyclopentadiene, quinoline-metal complex, aminoquinoline metal complex, benzoquinoline metal complex, imine, diphenylethylene, vinylanthracene, diaminocarbazole, pyran, thiopyrane, polymethine, merocyanine, an imidazole chelated oxinoid compound, quinacridone, rubrene and the like. Moreover, emission units associated with a triplet exciton state may also be used. As such an emission unit associated with a triplet exciton state, there can be mentioned, in most cases, compounds containing metal complexes such as indium metal complexes, but not limited thereto irrespective of whether or not metal complexes are contained. Specific examples of the light-emitting high molecular weight materials capable of generating light from the triplet exciton state include RPP (formula (2-1)) for red phosphorescent material, GPP (formula (2-2)) for green phosphorescent material, and the like.

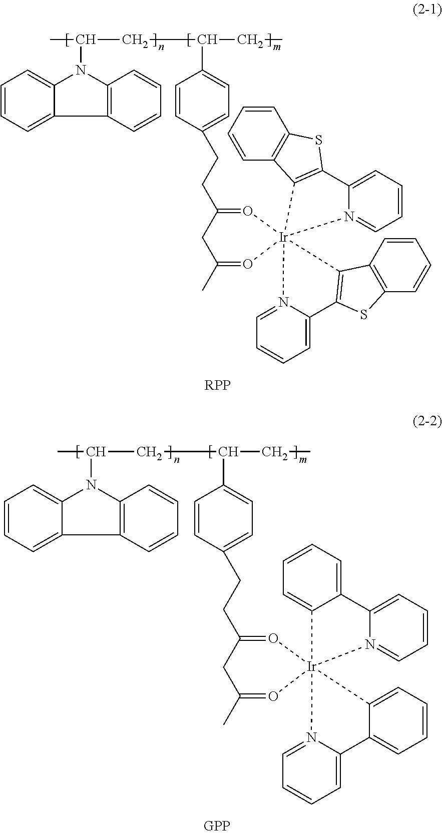

It is preferred to add low molecular weight materials to high molecular weight material materials for the red light-emitting layer 16CR and green light-emitting layer 16CG. In doing so, the efficiencies of injecting holes and electrons from the electron injection layer 16E and electron transport layer 16D to the red light-emitting layer 16CR and green light-emitting layer 16CG are improved. This principle is described below.

Since the blue light-emitting layer 16CB made of a low molecular weight material is formed, as a common layer, over the red light-emitting layer 16CR and green light-emitting layer 16CG each made of a high molecular weight material alone, the energy levels of the red light-emitting layer 16CR and green light-emitting layer 16CG are greatly different from the energy level of the blue light-emitting layer 16CB. Hence, the injection efficiency of holes or electrons between the blue light-emitting layer 16CB and the red light-emitting layer 16CR and green light-emitting layer 16CG is low, with the attendant problem that there cannot be adequately obtained inherent characteristics of the light-emitting layers made of high molecular weight materials as stated hereinbefore. In this embodiment, in order to improve this hole or electron injection characteristic, a low molecular weight material (a monomer or oligomer), which enables a difference between the energy levels of the red light-emitting layer 16CR and green light-emitting layer 16CG and the energy level of the blue light-emitting layer 16CB to be made small, is added to the red light-emitting layer 16CR and green light-emitting layer 16CG. Here, consideration is taken with respect to the relation among the highest occupied molecular orbital (HOMO) levels of the red light-emitting layer 16CR and green light-emitting layer 16CG and the lowest unoccupied molecular orbital (LUMO) levels of the red light-emitting layer 16CR and green light-emitting layer 16CG, and the HOMO (highest occupied molecular orbital) level and the LUMO (lowest unoccupied molecular orbital) level of blue light-emitting layer 16CB, and the HOMO (highest occupied molecular orbital) level and the LUMO (lowest unoccupied molecular orbital) level of a low molecular weight material to be added to the red light-emitting layer 16CR and green light-emitting layer 16CG. Specific examples of the low molecular weight material to be added are those compounds, which are so selected as to have a value deeper than LUMO of each of the red light-emitting layer 16CR or green light-emitting layer 16CG and a value shallower than LUMO of the blue light-emitting layer 16CB, and also to have a value deeper than HOMO of each of the red light-emitting layer 16CR or green light-emitting layer 16CG and a value shallower than HOMO of the blue light-emitting layer 16CB.

The low molecular weight material added to the red light-emitting layer 16CR and green light-emitting layer 16CG means those other than compounds made of molecules of high molecular weight polymers or condensates obtained in such a way that a low molecular weight compound repeatedly undergoes the same or similar chain reaction, and having substantially a single molecular weight. The low molecular weight material does not cause any fresh intermolecular chemical bond when heated and is present as a single molecule. Preferably, the weight average molecular weight (Mw) of low molecular weight compound is not larger than 10,000. Moreover, a ratio in molecular weight between the high molecular weight material and the low molecular weight material is preferably at not less than 10. This is because a material whose molecular weight is smaller to some extent than a material having a large molecular weight, for example, of not less than 50,000 has versatile characteristics, thereby permitting easy control of hole or electron mobility and band gap or solubility in solvent. If a mixing ratio of high molecular weight material:low molecular weight material is at less than 10:1, the effect of addition of the low molecular weight material becomes low. In contrast, when the mixing ratio exceeds 1:2, it becomes difficult to obtain characteristics inherent to a high molecular weight material serving as a light-emitting material.

As stated above, the addition of a low molecular weight material to the red light-emitting layer 16CR and green light-emitting layer 16CG permits easy control of hole or electron carrier balance. This suppresses the electron injectionability and hole transportability into the red light-emitting layer 16CR and the green light-emitting layer 16CG from lowering as will occur upon formation of the blue light-emitting layer 16CB made of a low molecular weight material as will be described hereinafter. More particularly, the red organic EL element 10R and green red EL element 10G are suppressed with regard to the luminescent efficiency, lowering of life, rise in drive voltage and change in luminescent chromaticity.

Such low molecular weight materials are those having hole transportability and including, for example, benzin, styrylamine, triphenylamine, porphyrin, triphenylene, azatriphenylene, tetracyanoquinodimethane, triazole, imidazole, oxadiazole, polyarylalkane, phenylenediamine, arylamine, oxazole, anthracene, fluorenone, hydrazone, stilbene or derivatives thereof, polysilane compounds, vinylcarbazole compounds, and heterocyclic conjugated monomers or oligomers such as of thiophene compounds or aniline compounds.

More specific examples of the material include α-naphtylphenylphenylenediamine, porphyrin, metal tetraphenylporphyrin, metal naphthalocyanine, hexacyanoazatriphenylene, 7,7,8,8-tetracyanoquinodimethane (TCNQ), 7,7,8,8-tetracyano-2,3,5,6-tetrafluoroquinodimethane (F4-TCNQ), tetracyano-4,4,4-tris(3-methylphenylphenylamino)triphenylamine, N,N,N′,N′-tetrakis(p-tolyl)-p-phenylenediamine, N,N,N′,N′-tetraphenyl-4,4′-diaminobiphenyl, N-phenylcarbazole, 4-di-p-tolylaminostilbene, poly(paraphenylenevinylene), poly(thiophenevinylene), poly(2,2′-thienylpyrrole) and the like although not limited thereto.

More preferably, low molecular weight materials represented by the following formulas (3) to (5) are mentioned,

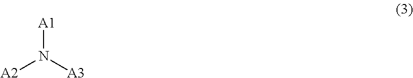

wherein A1 to A3, respectively, represent an aromatic hydrocarbon group, a heterocyclic group or a derivative thereof,

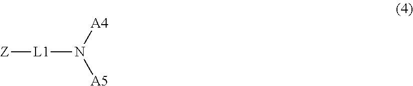

wherein Z represents a nitrogen-containing hydrocarbon group or a derivative thereof, L1 is a group made of one to four divalent aromatic cyclic groups bonded together, particularly, a divalent group linking one to four aromatic rings together, or a derivative thereof, A4 and A5 are, respectively, an aromatic hydrocarbon group or an aromatic heterocyclic group, or a derivative thereof provided that A4 and A5 may join together to form a cyclic structure, and

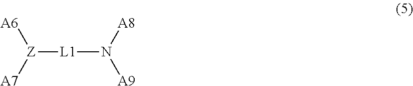

wherein L2 is a group made of two or six divalent aromatic ring groups bonded together, particularly, a divalent group linking two to six aromatic rings, or a derivative thereof, A6 to A9 are, respectively, an aromatic hydrocarbon group or a heterocyclic group, or a group made of one to ten derivatives bonded together.

Specific examples of the compound represented by the formula (3) include those compounds of the formulas (3-1) to (3-48) indicated below.

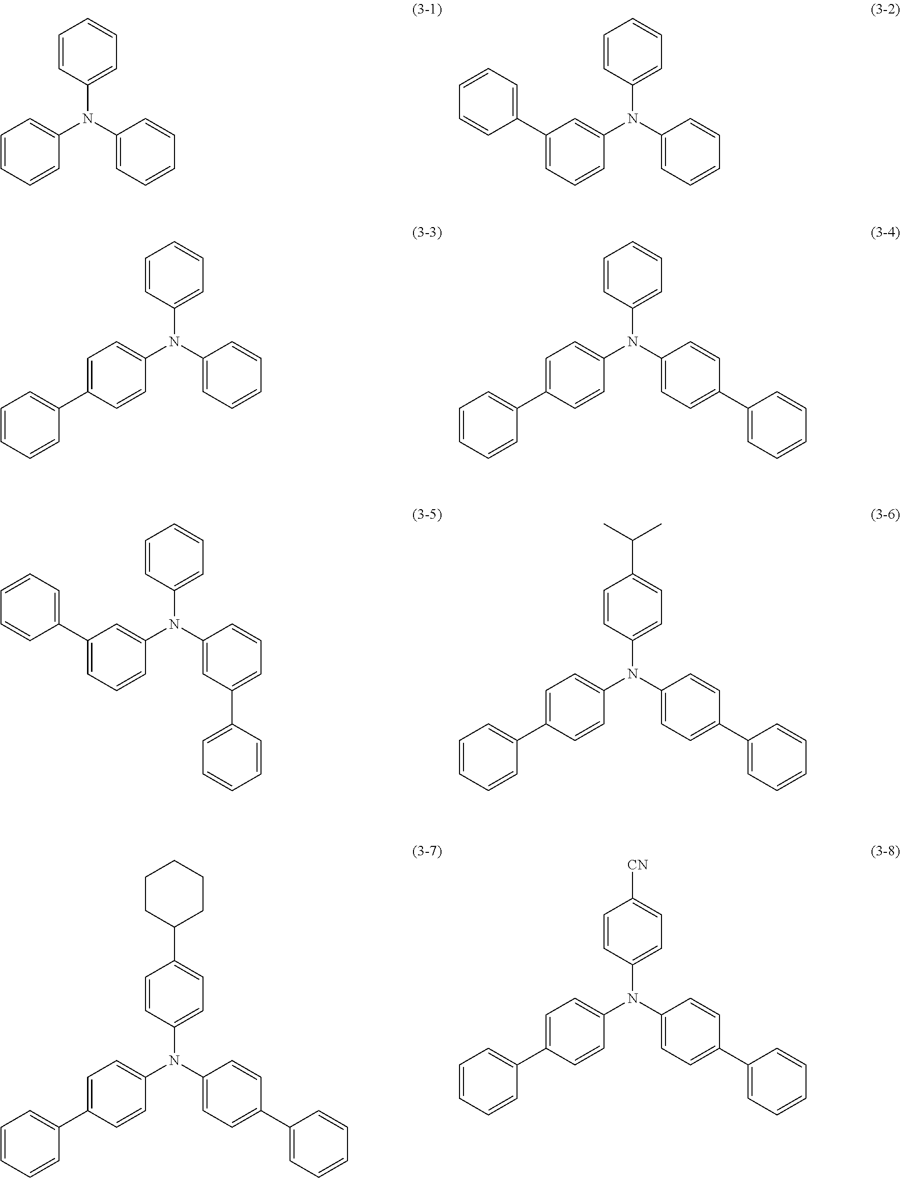

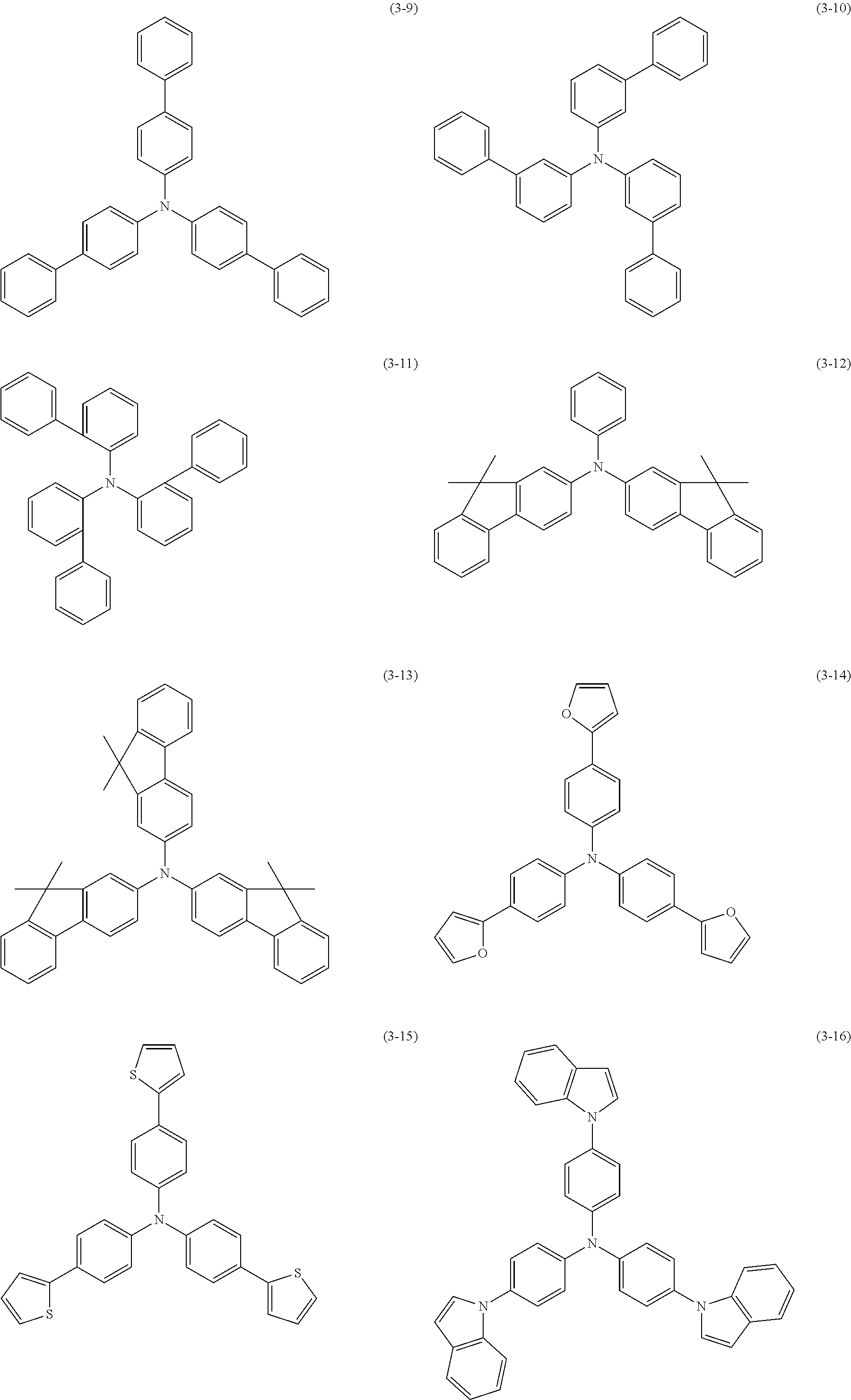

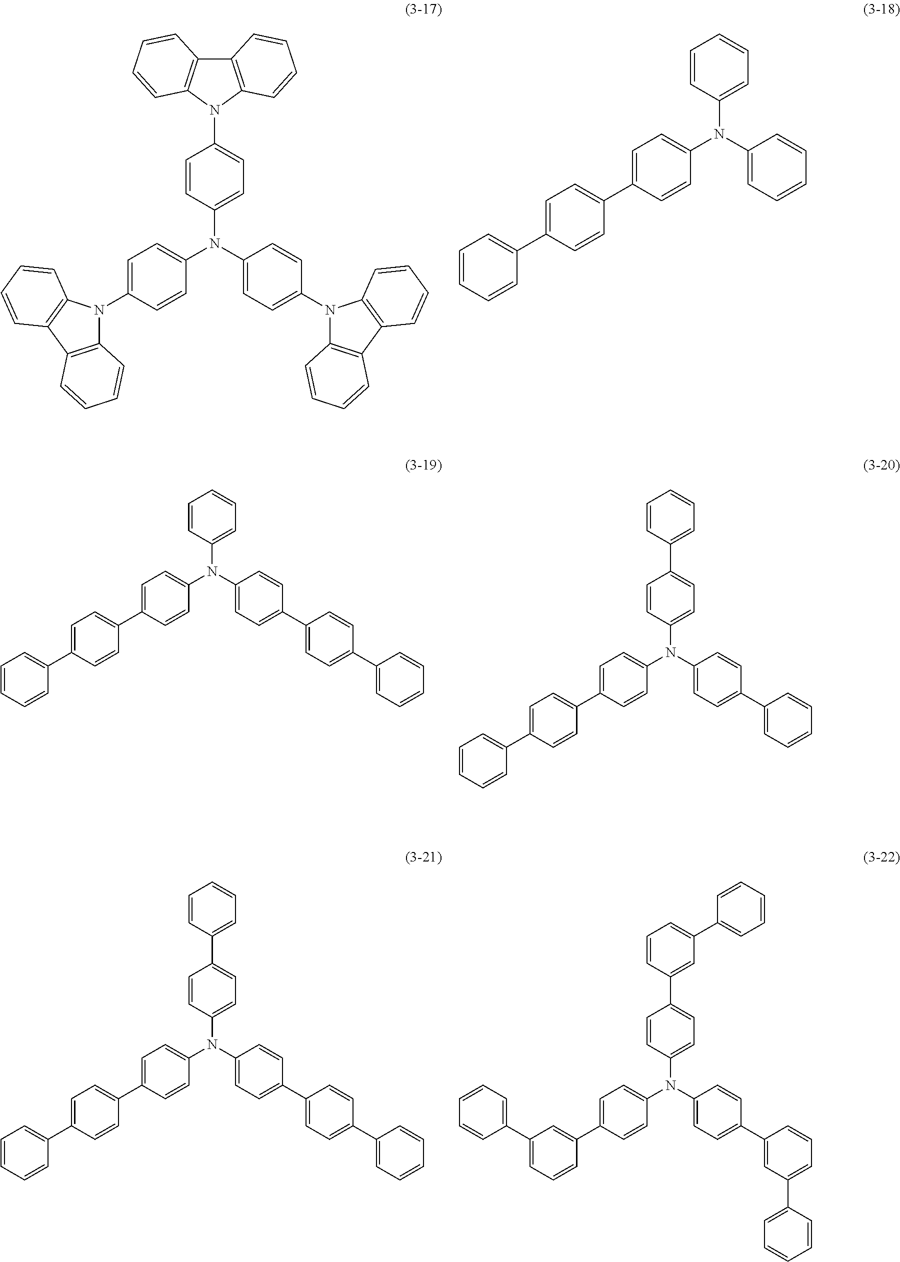

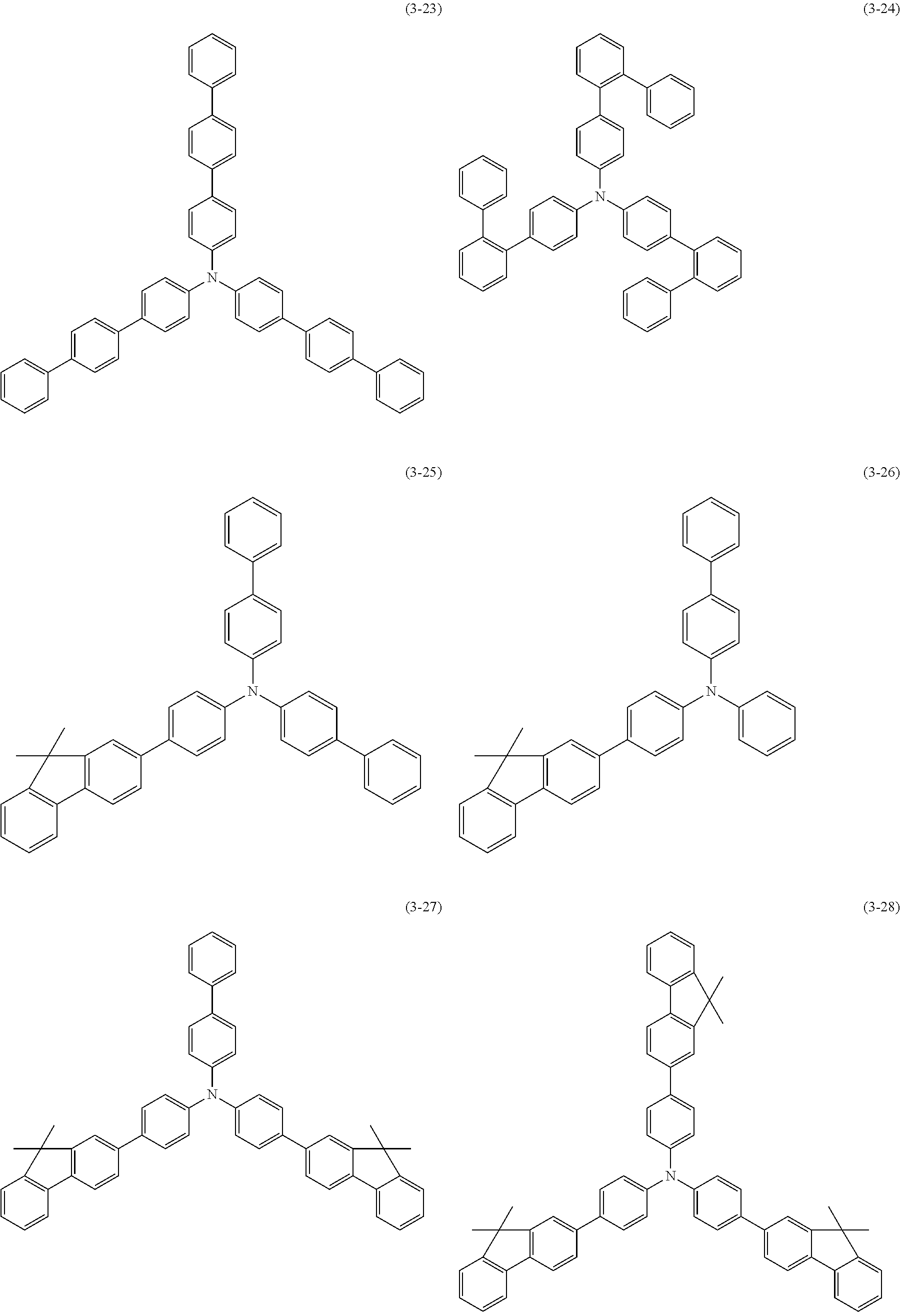

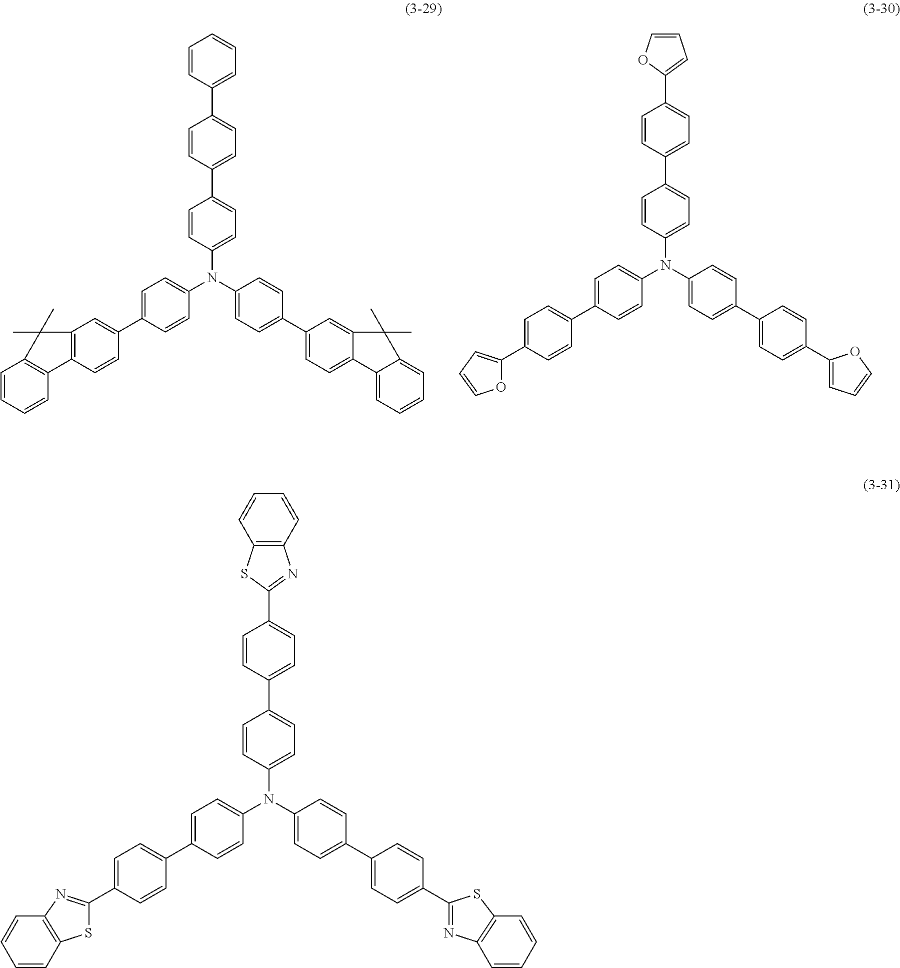

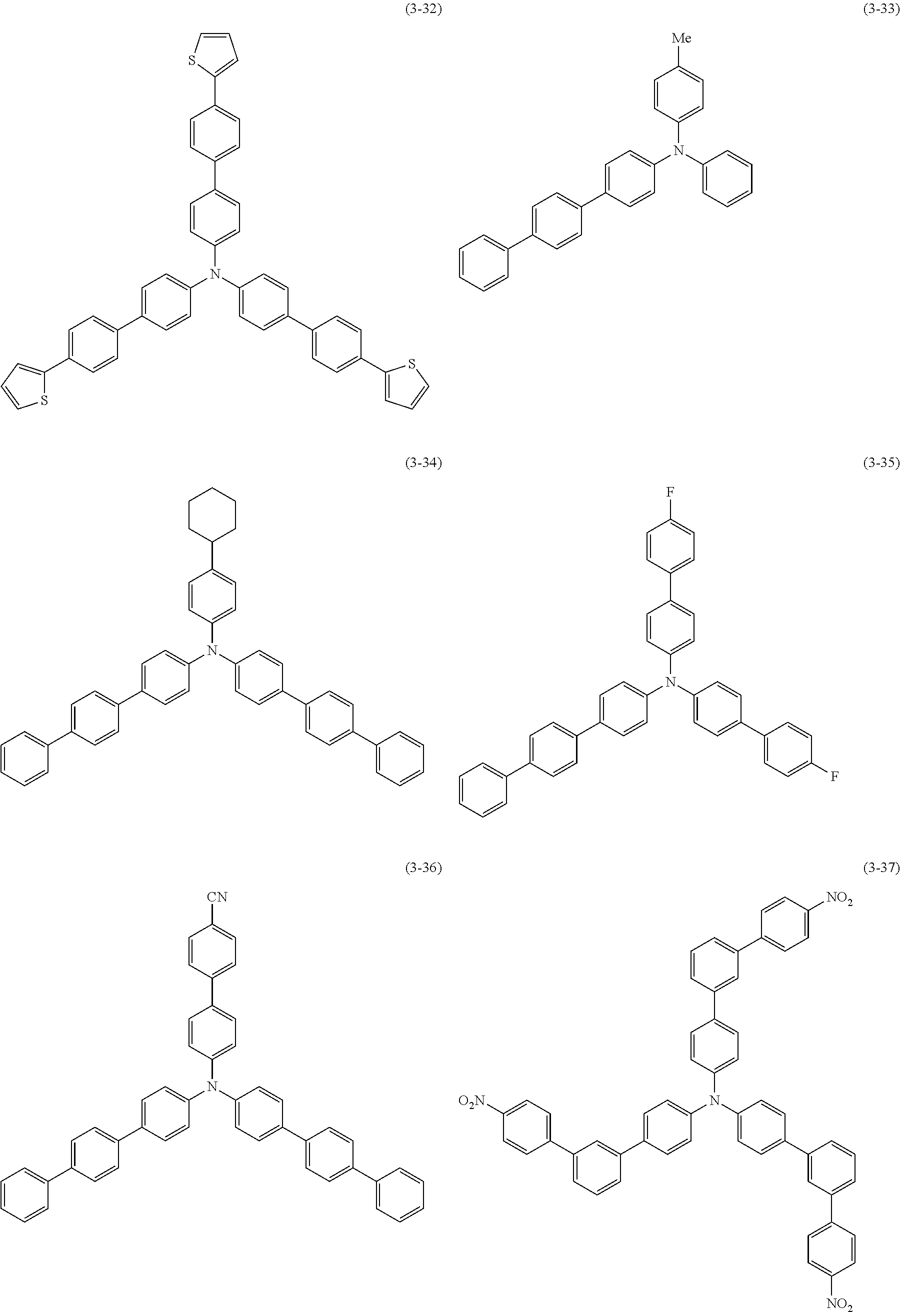

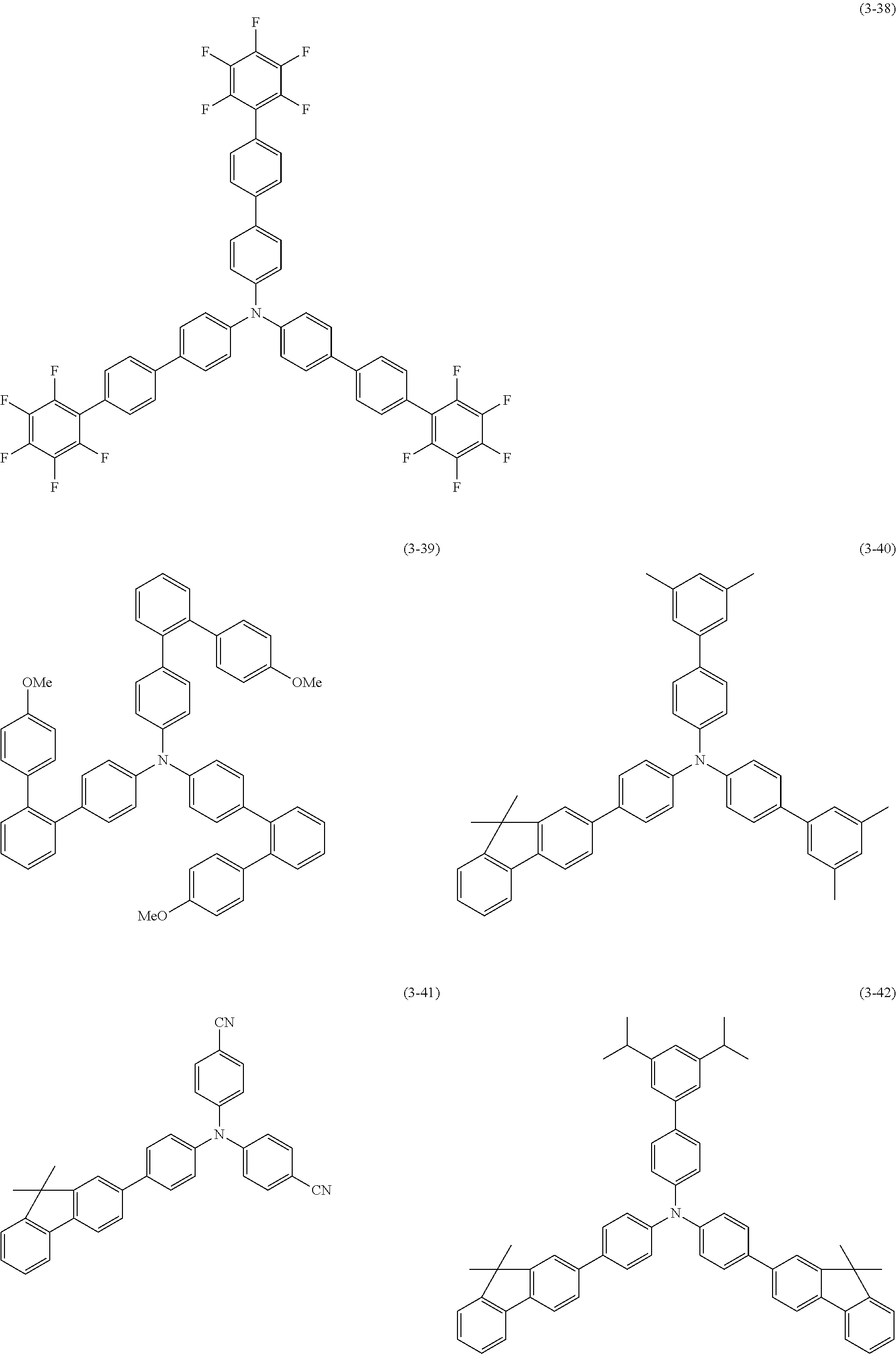

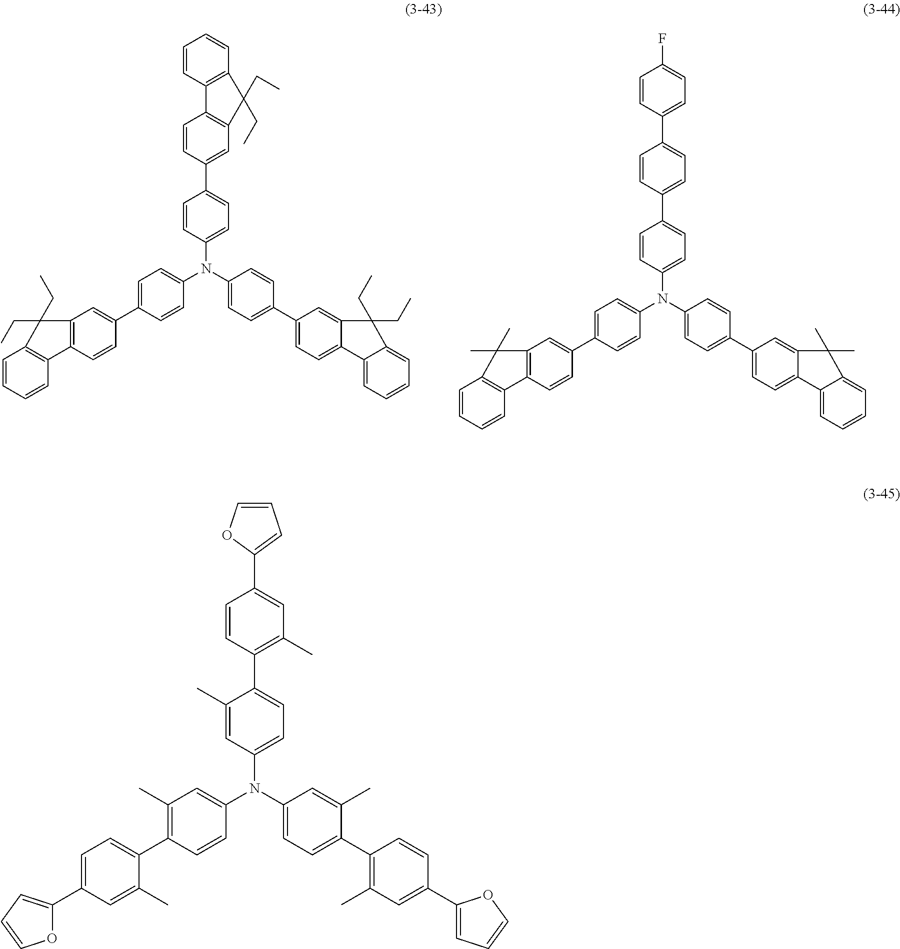

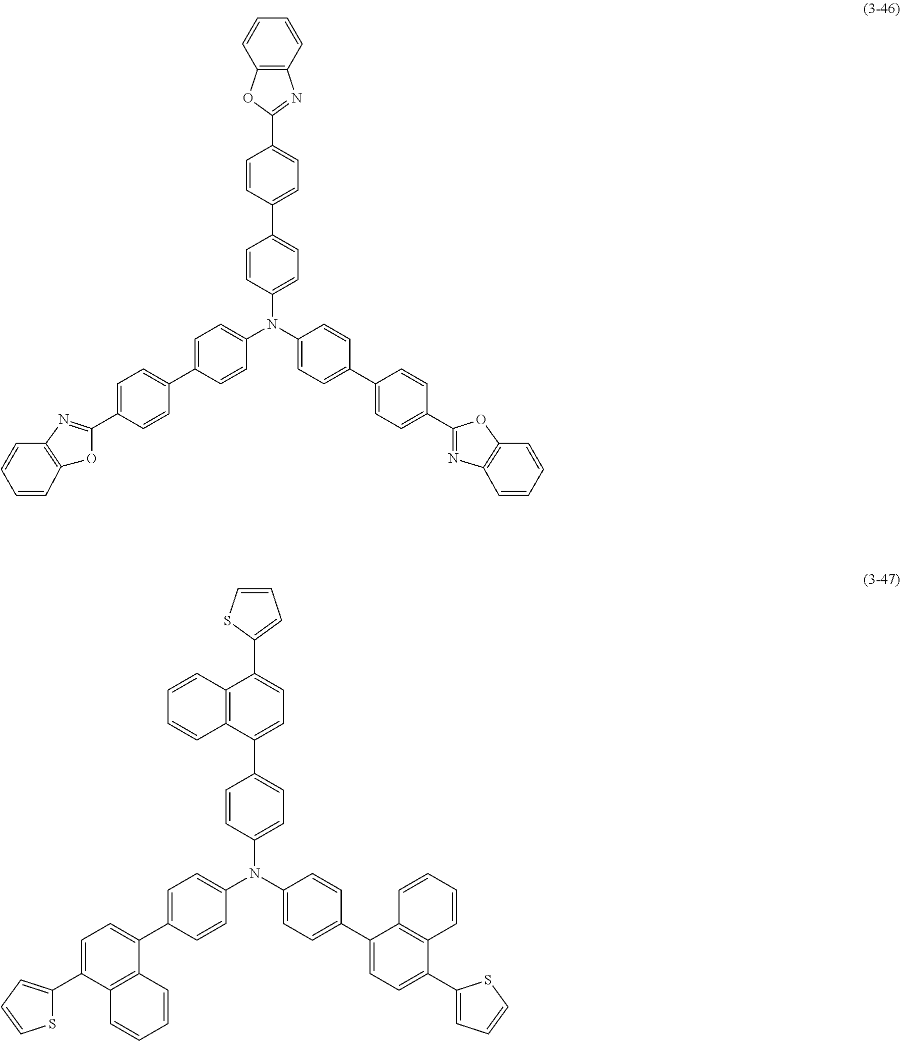

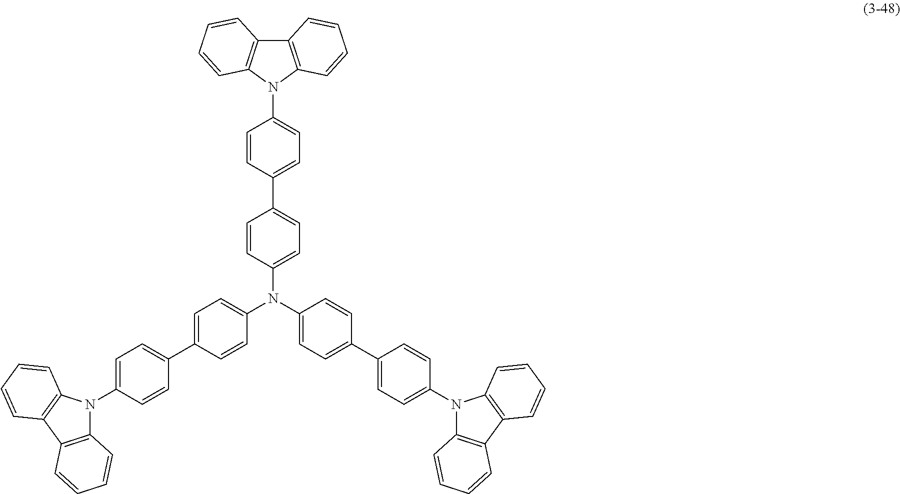

Specific examples of the compound represented by the formula (4) include those compounds of the formulas (4-1) to (4-69). It will be noted that as a nitrogen-containing hydrocarbon group bound to L1, mention is made, for example, of compounds having a carbazole group or an indole group although not limited thereto. For instance, an imidazole group may also be used.

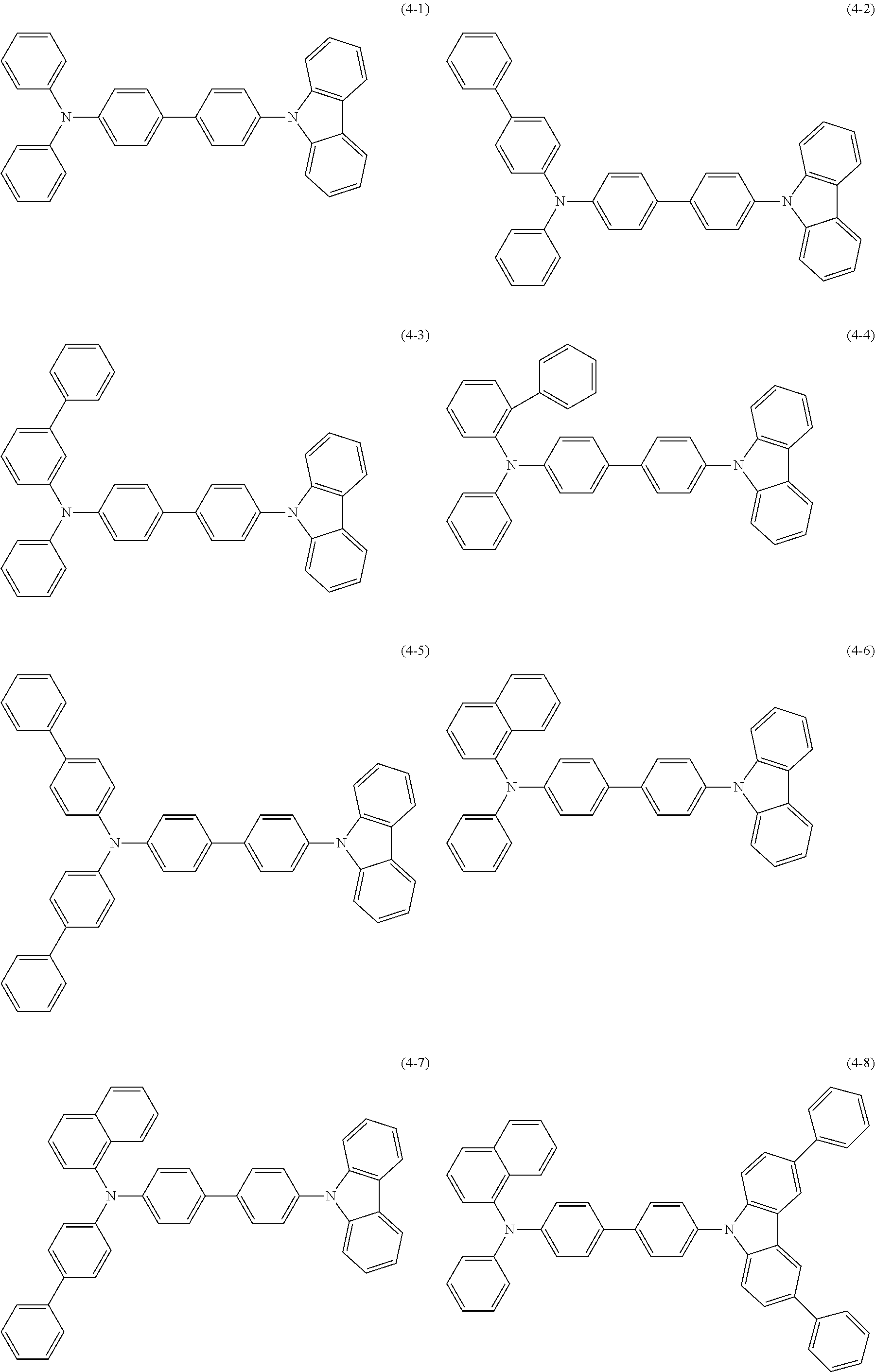

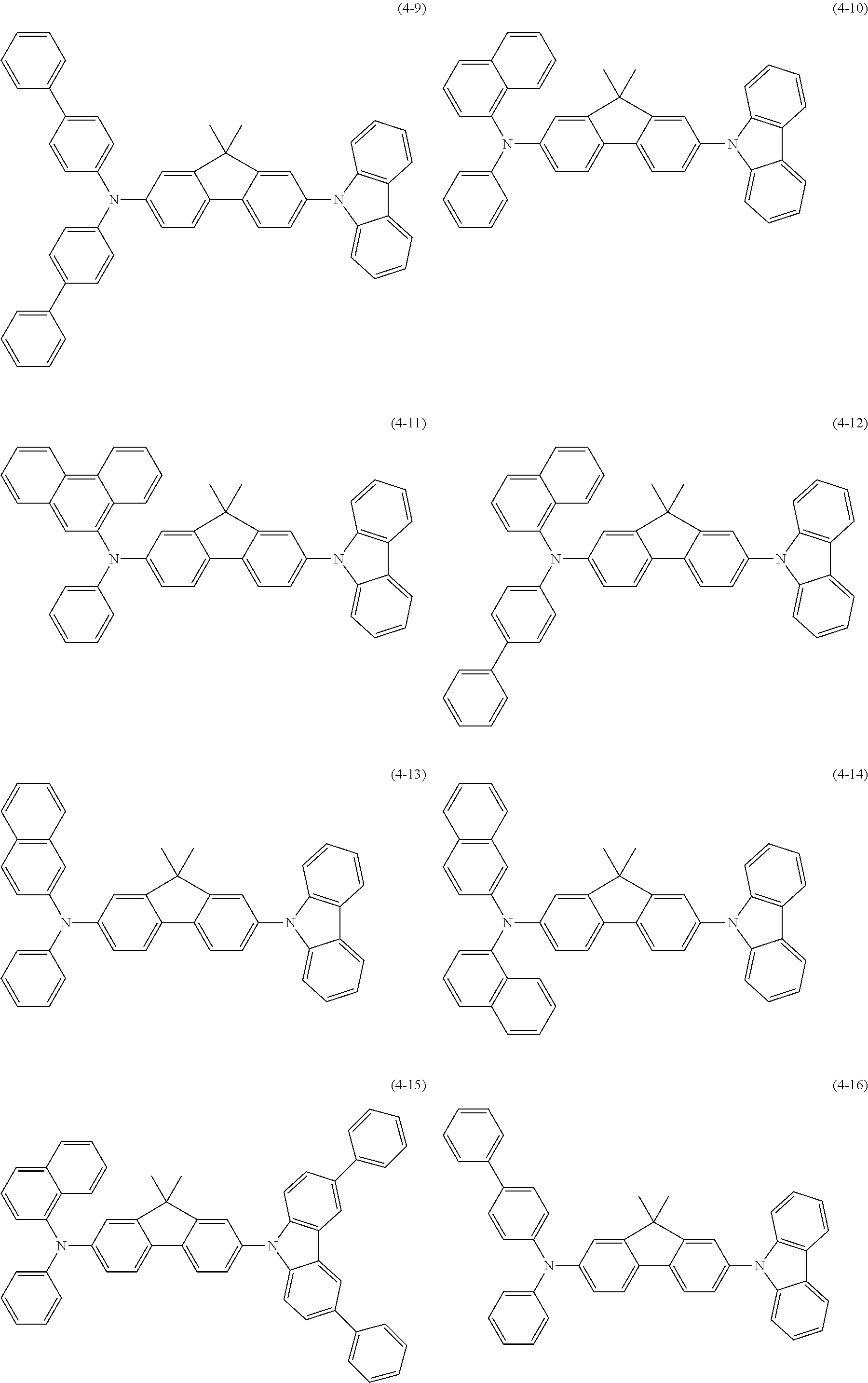

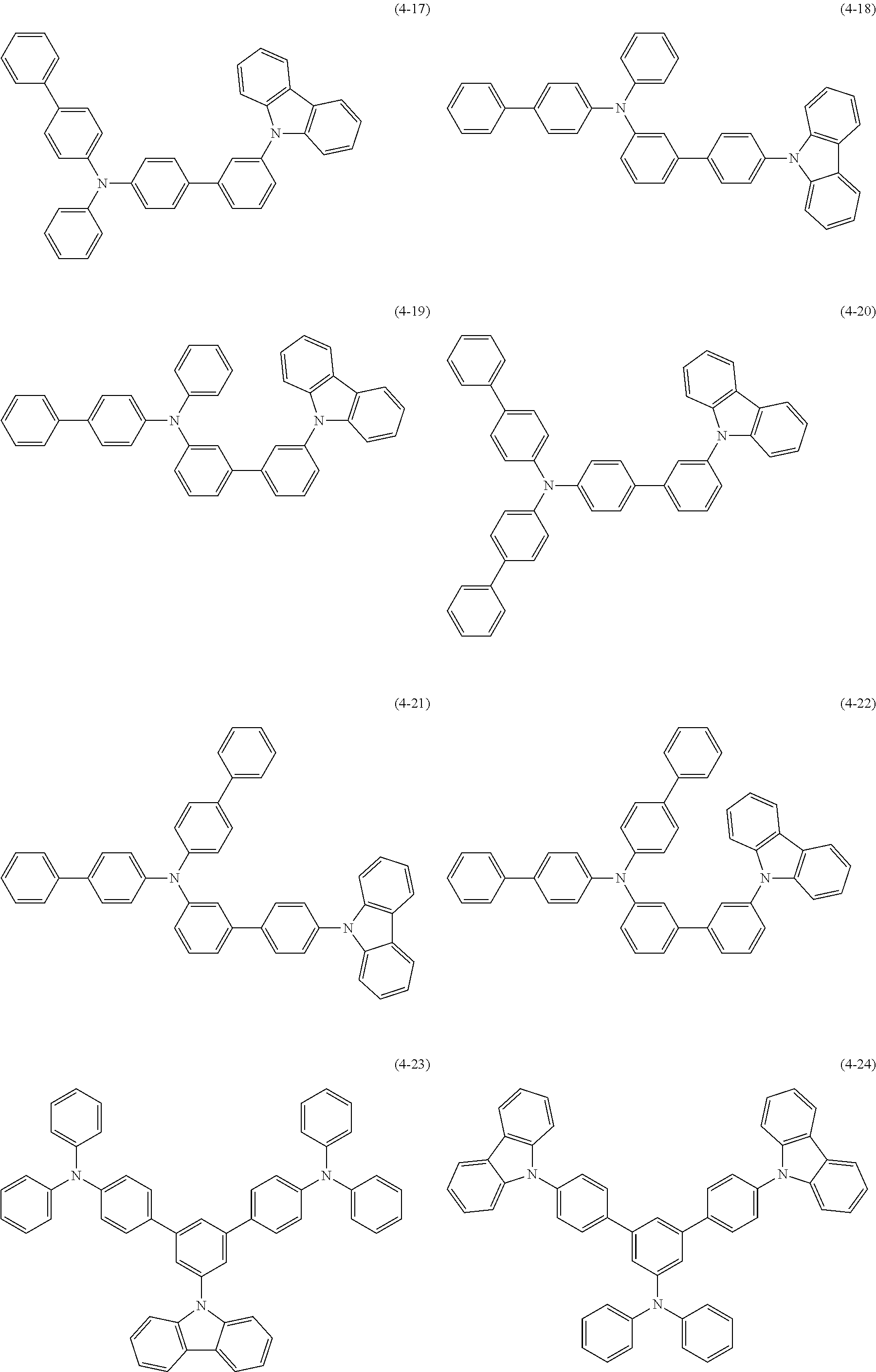

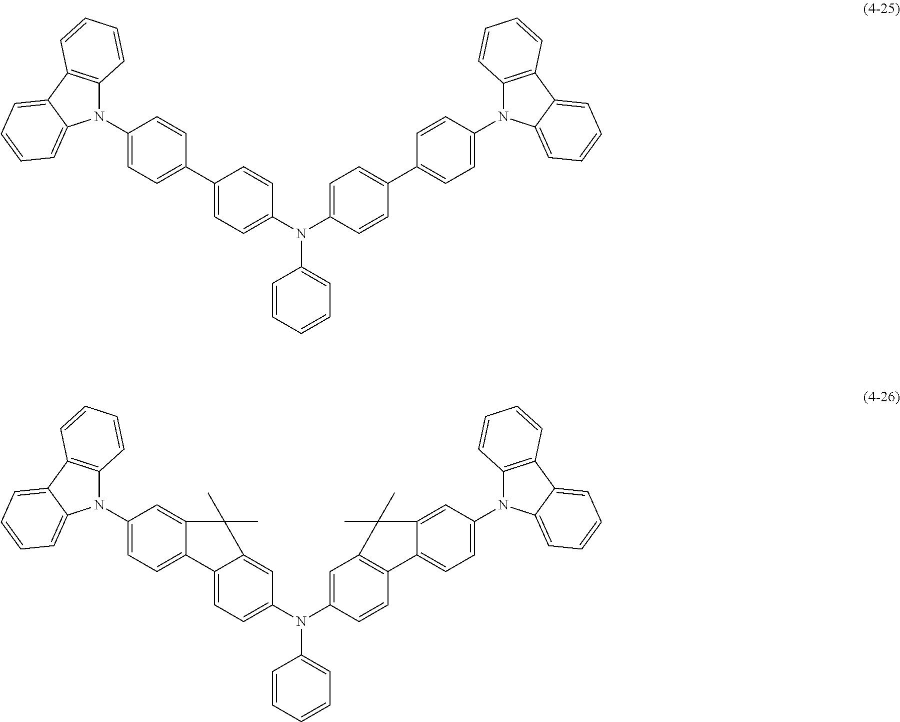

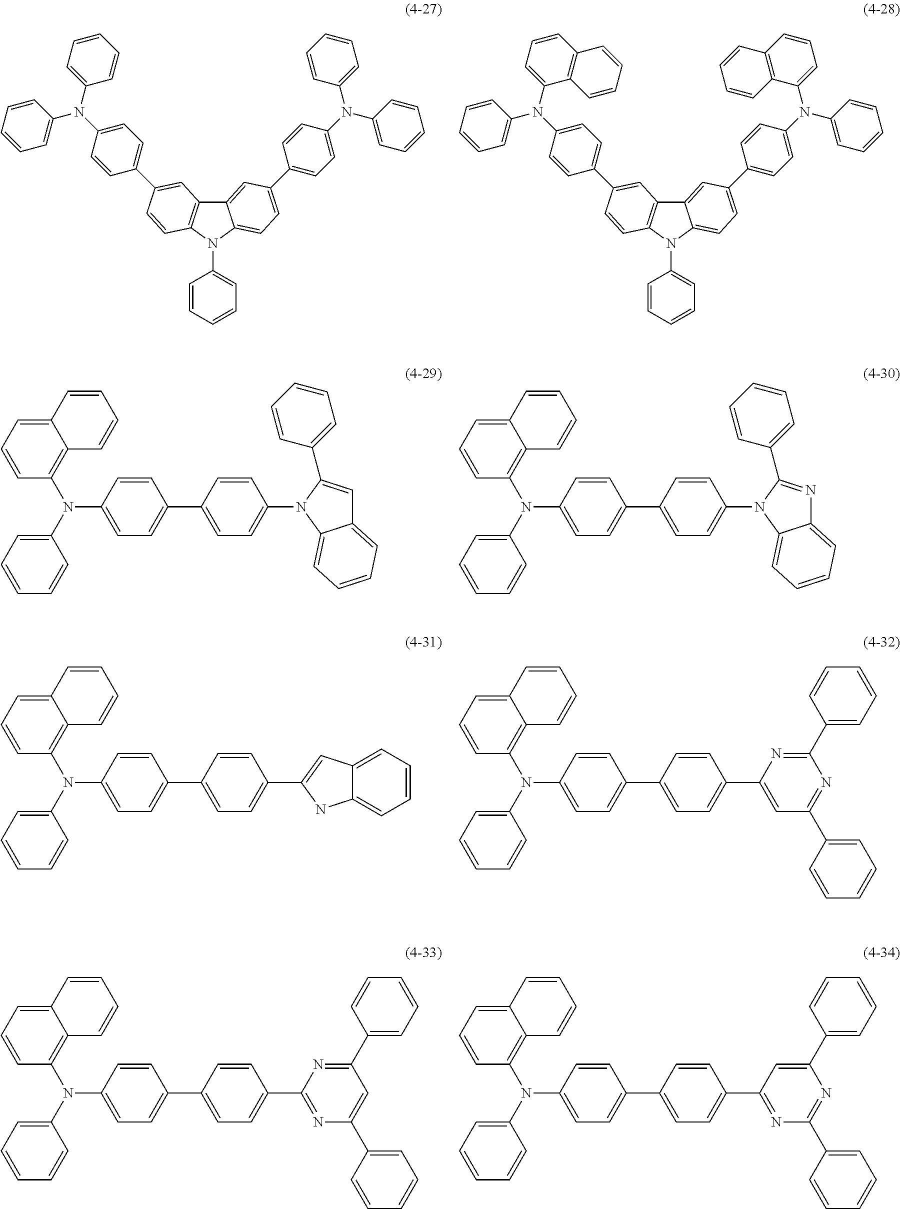

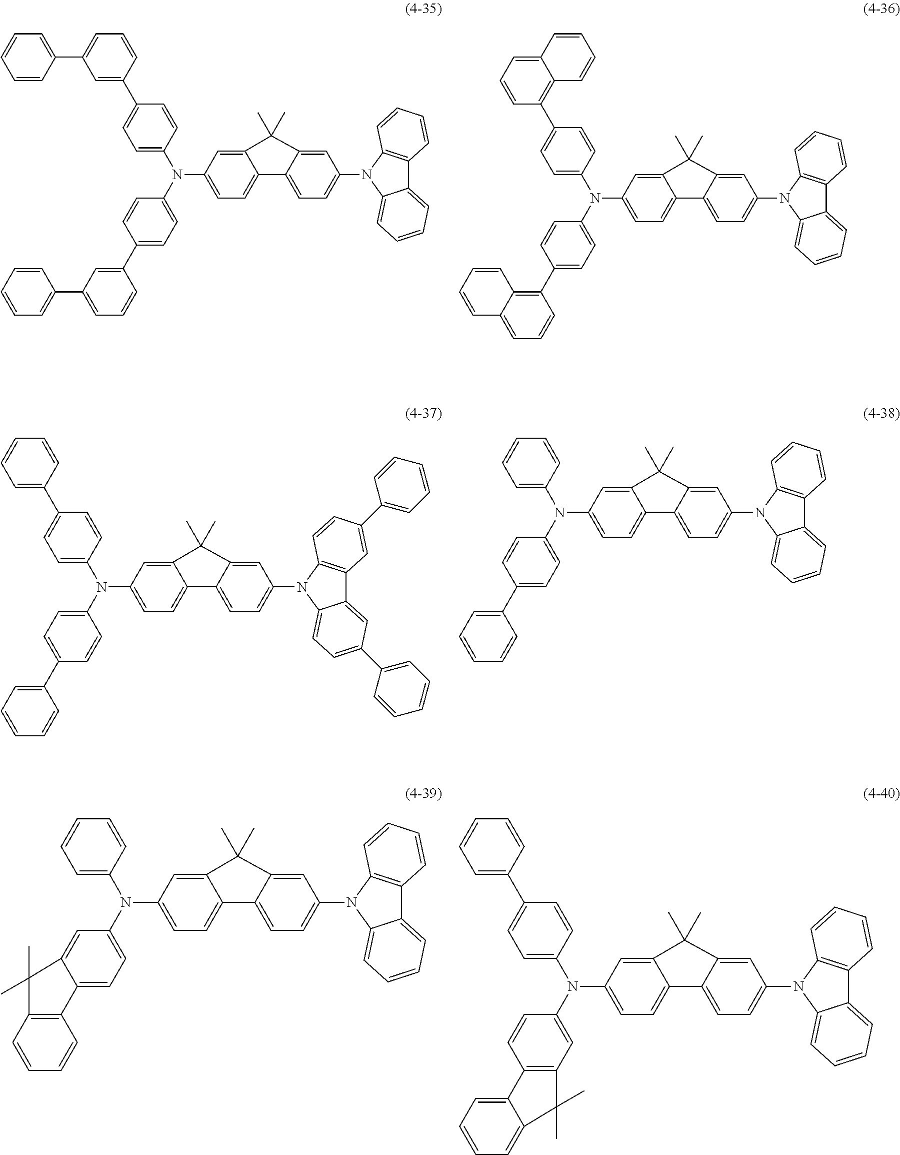

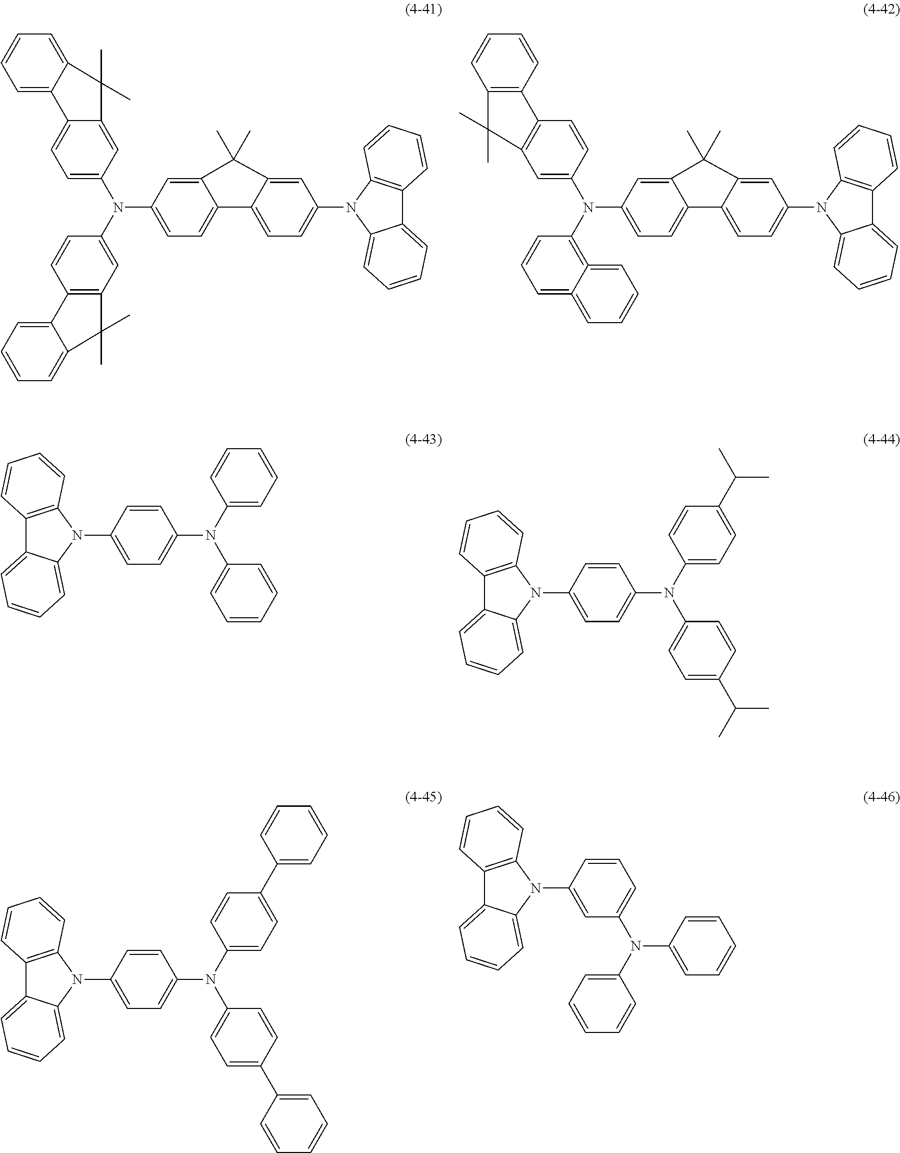

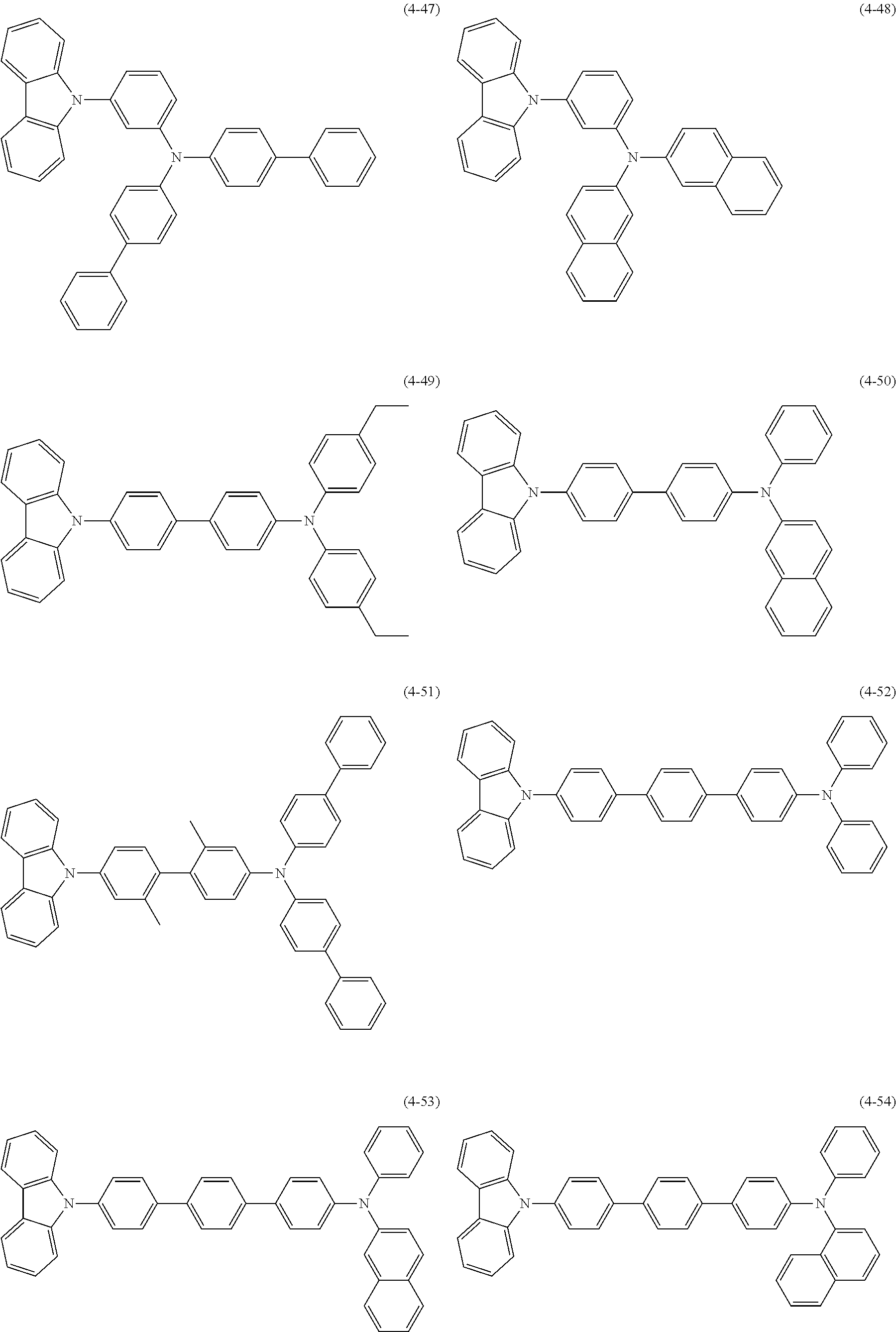

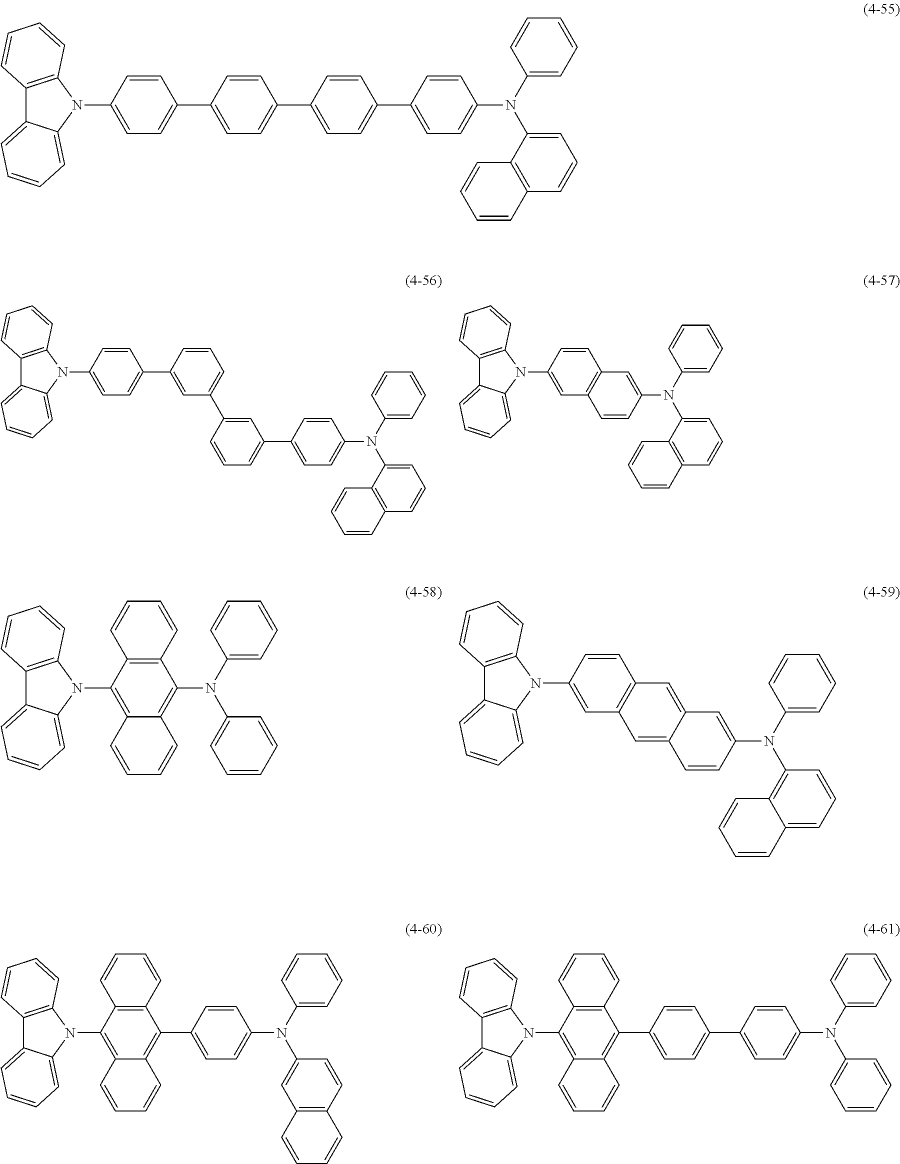

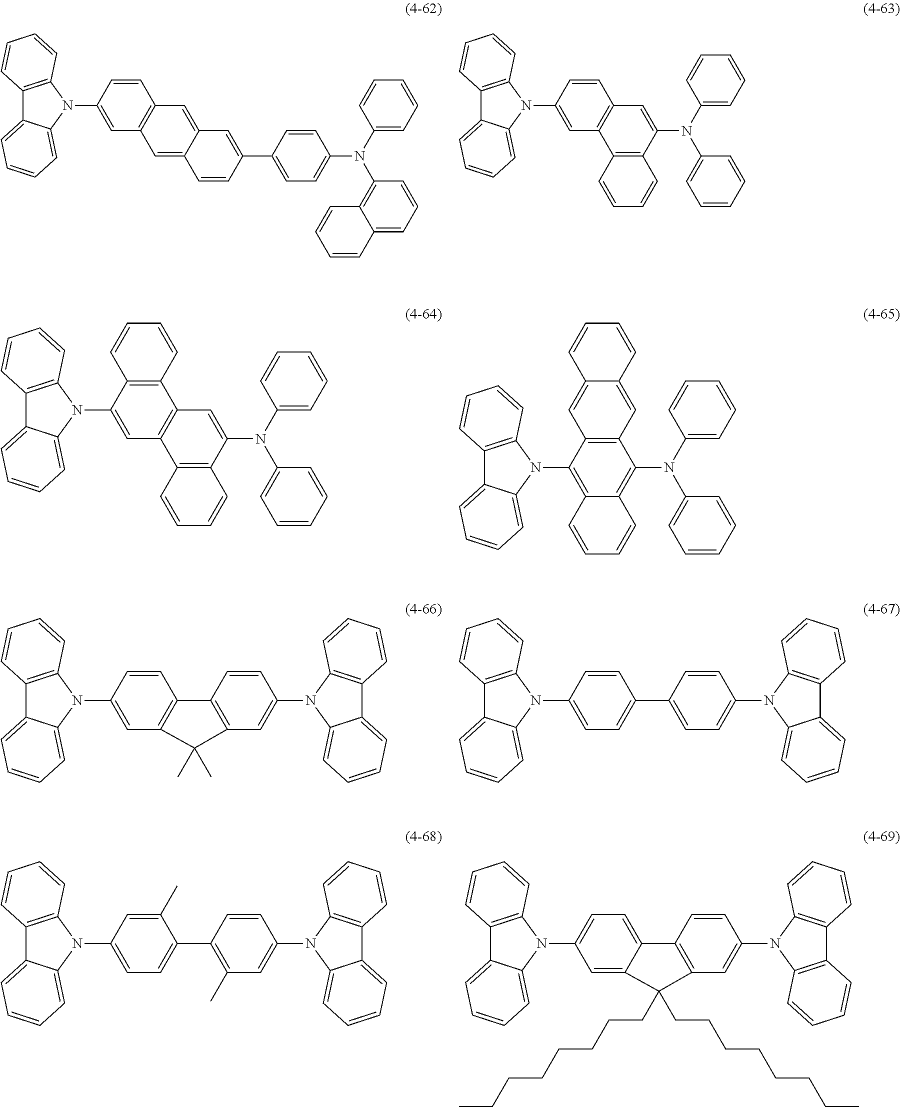

Specific examples of the compound represented by the formula (5) include those compounds of the formulas (5-1) to (5-45).

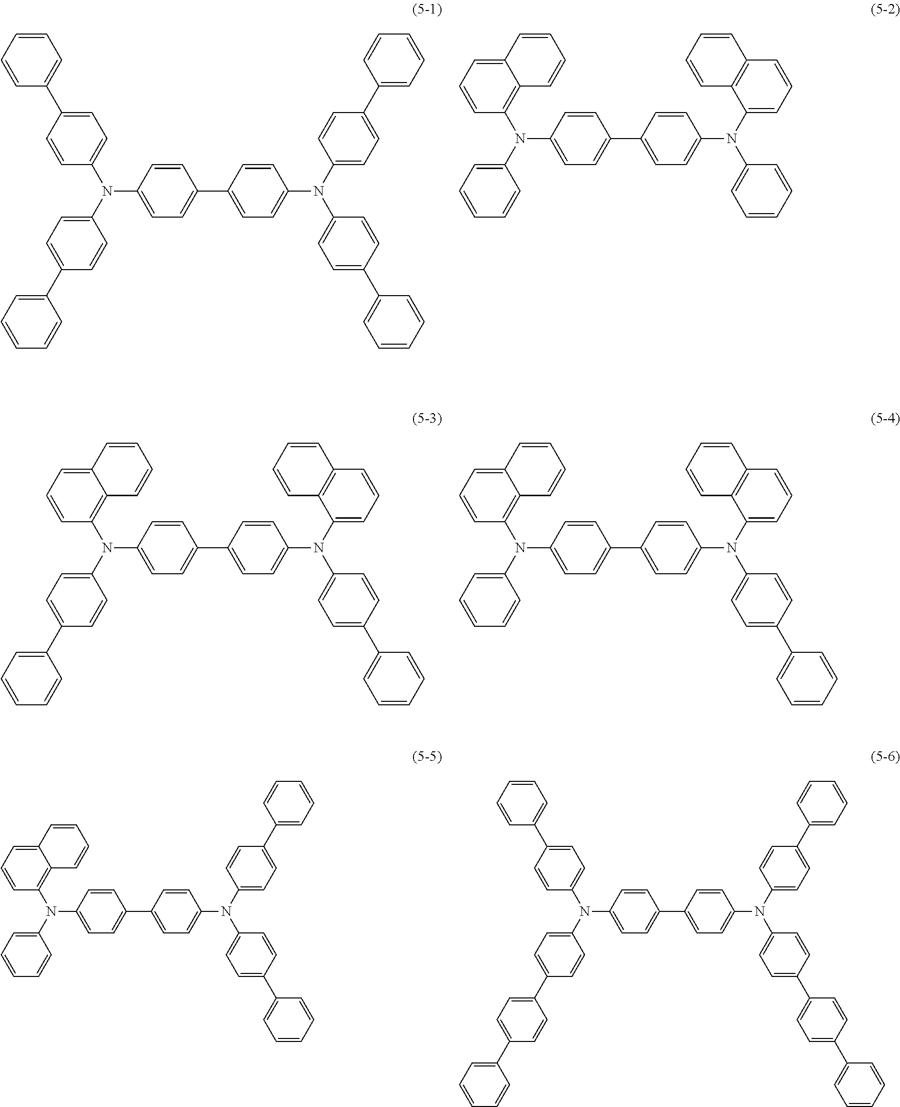

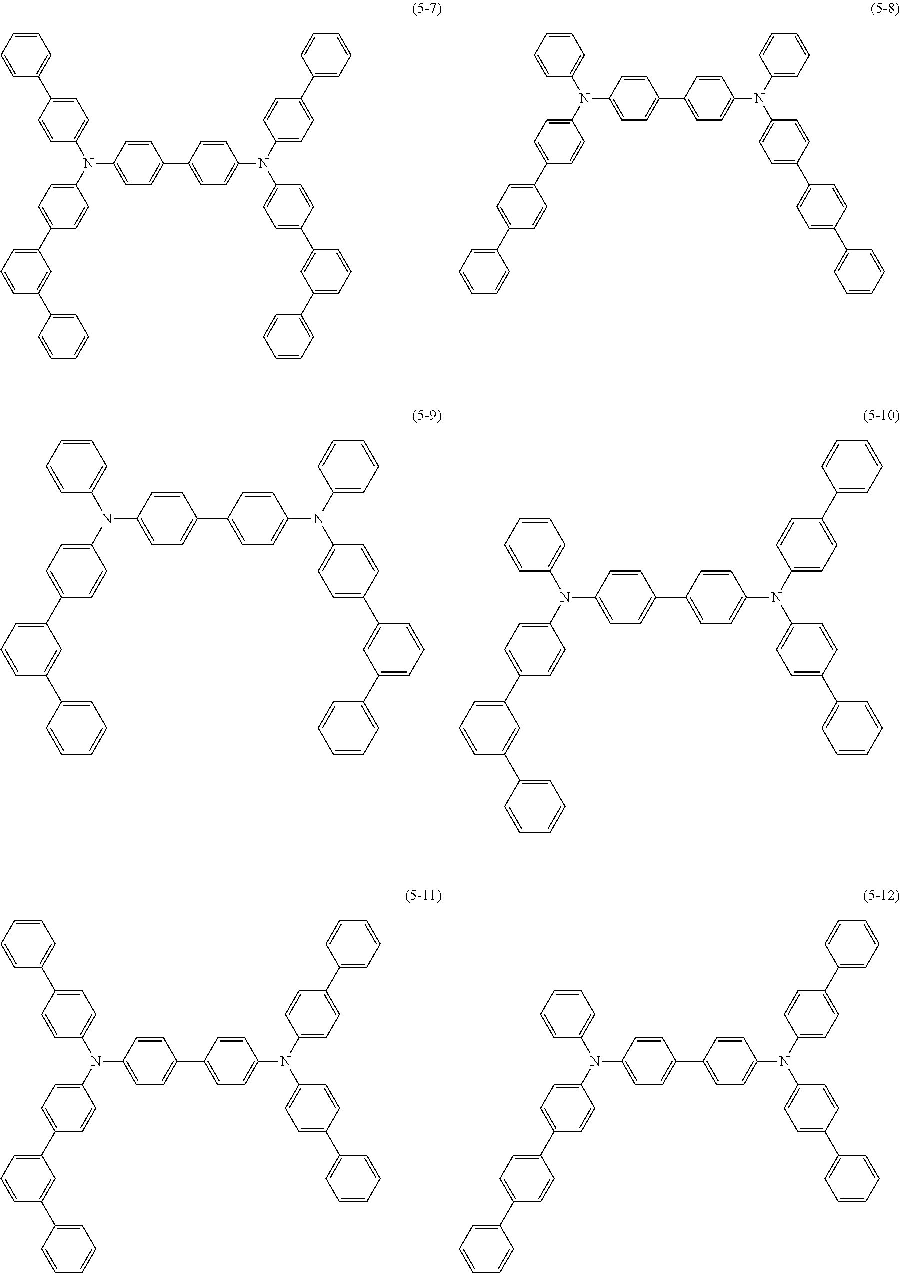

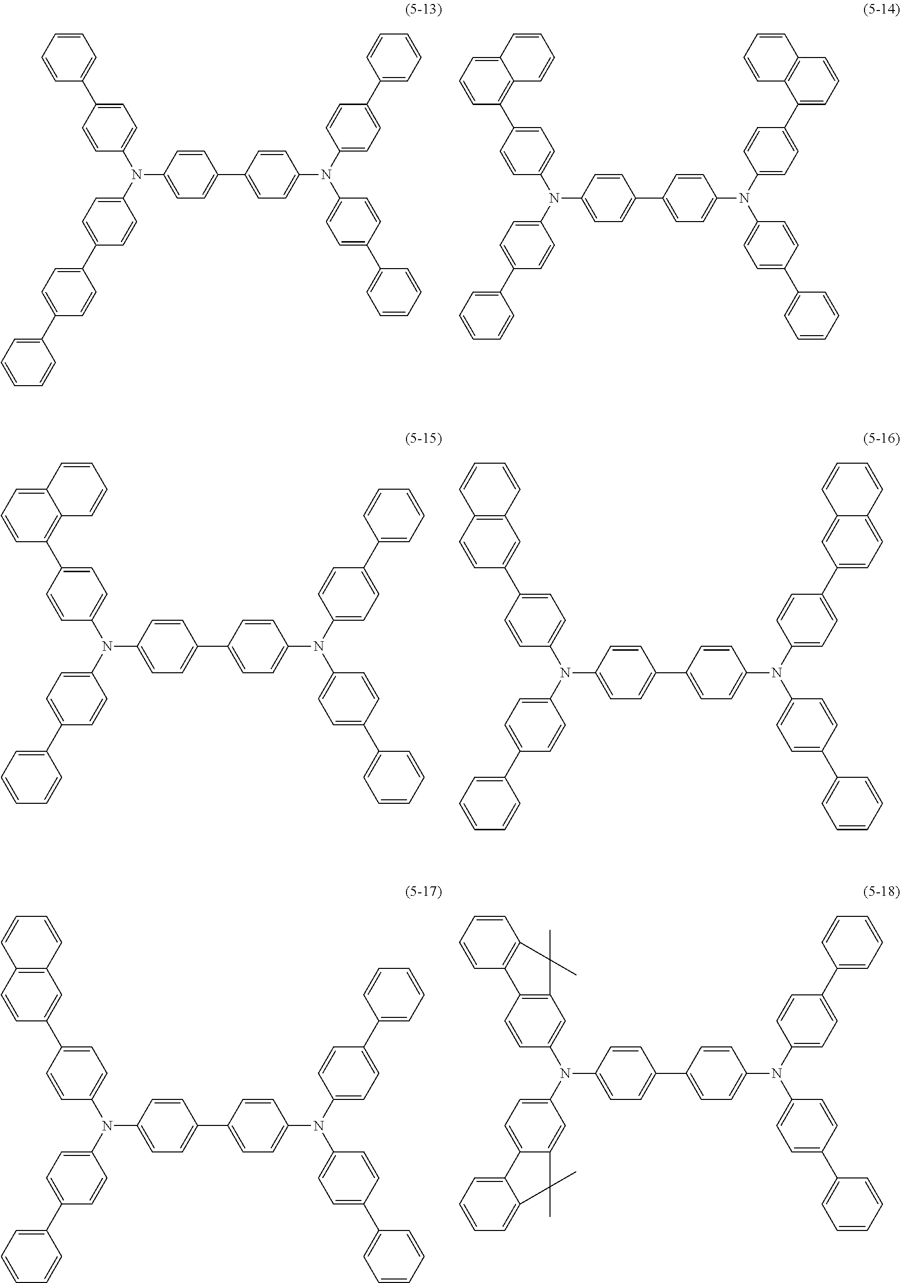

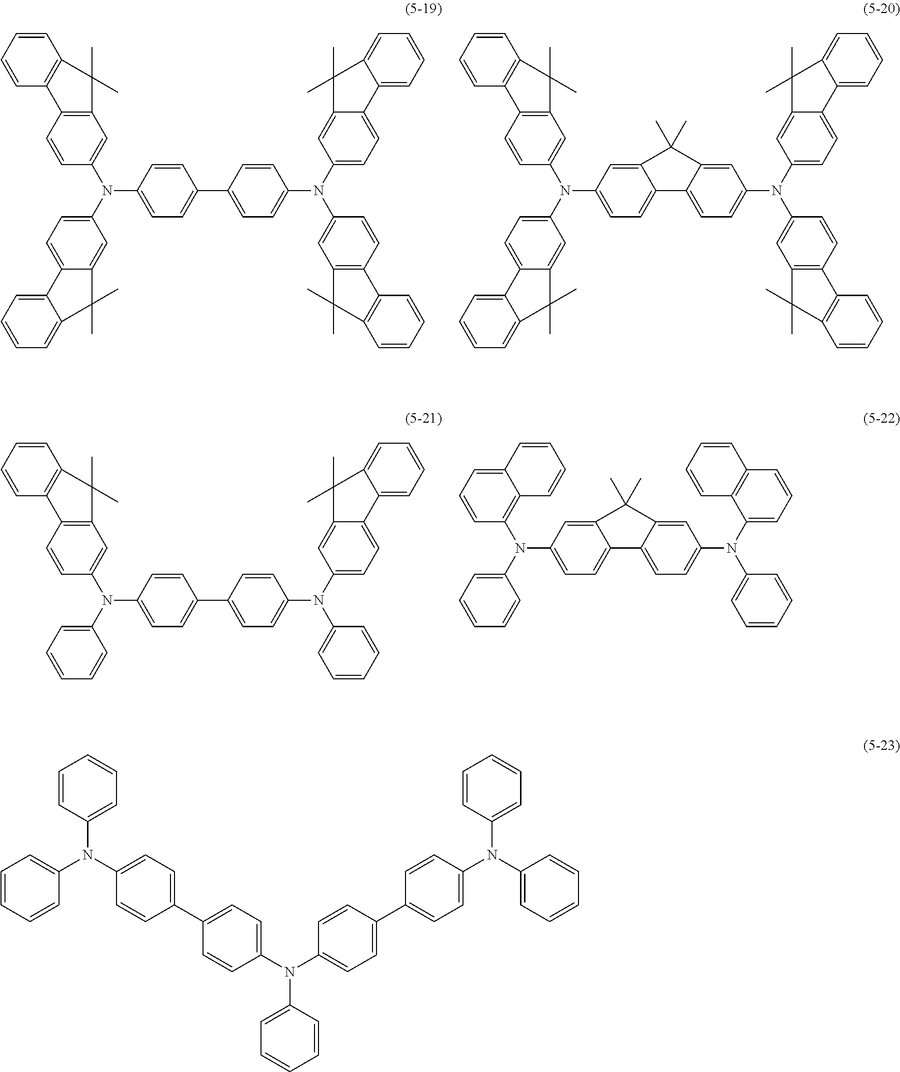

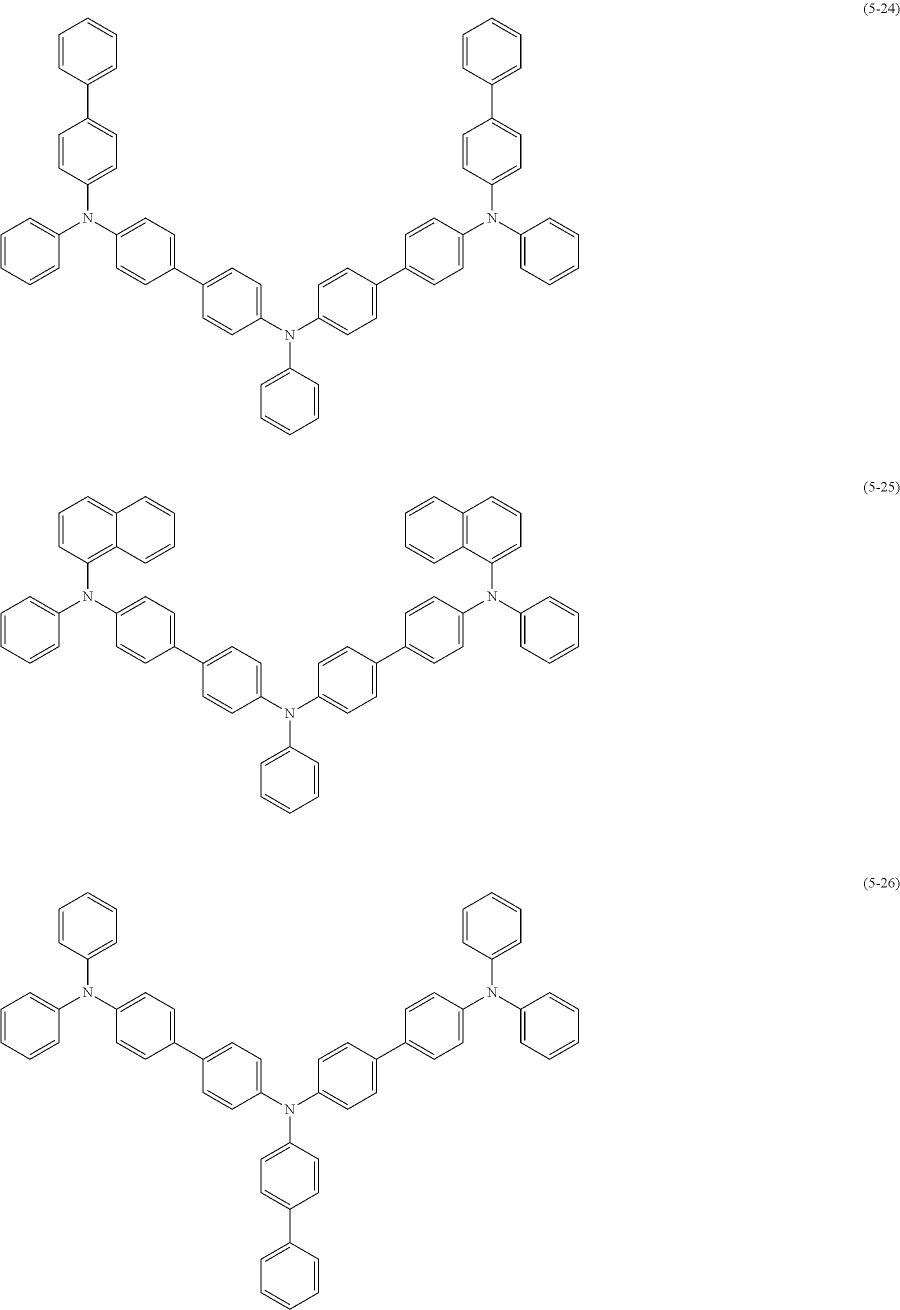

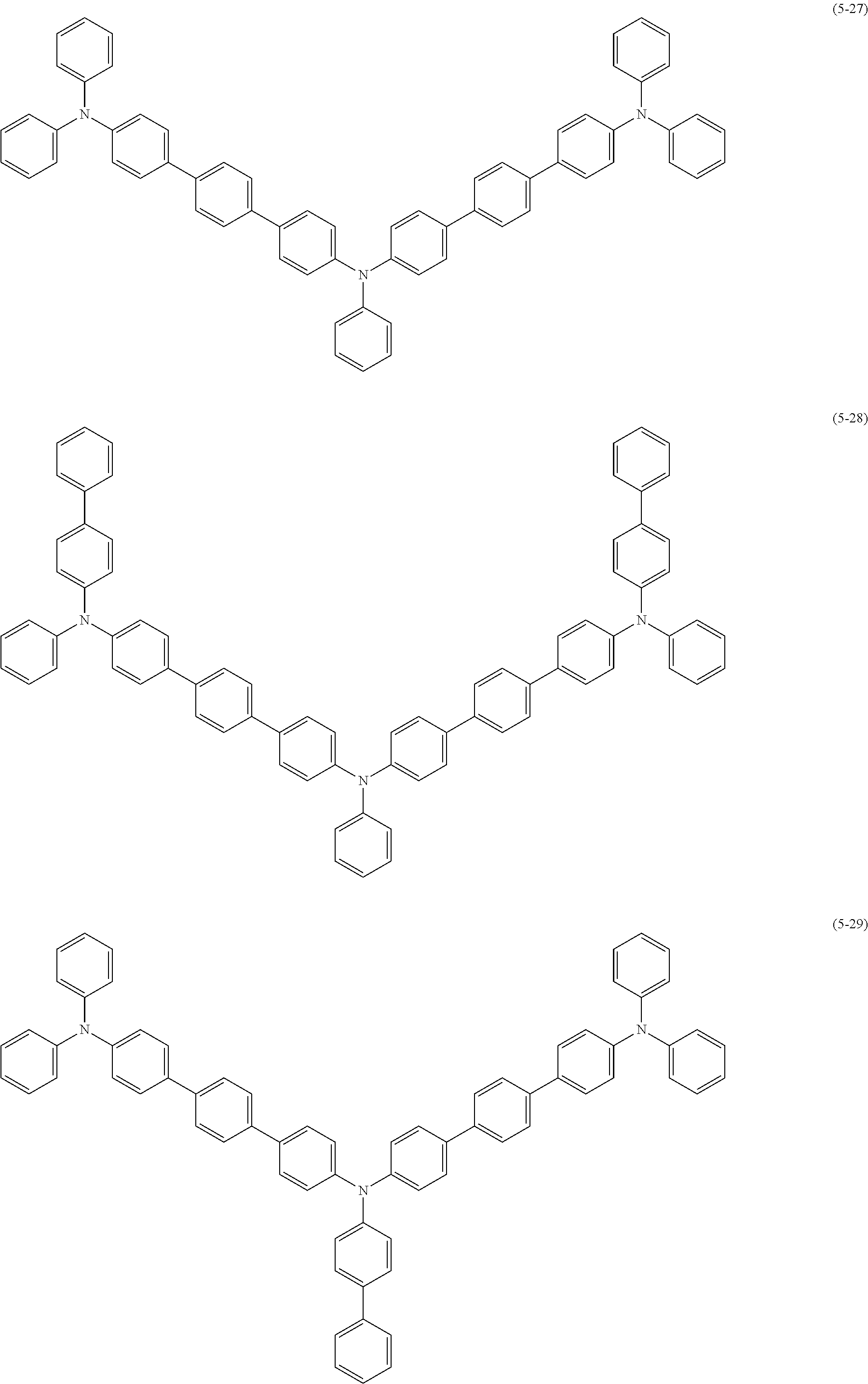

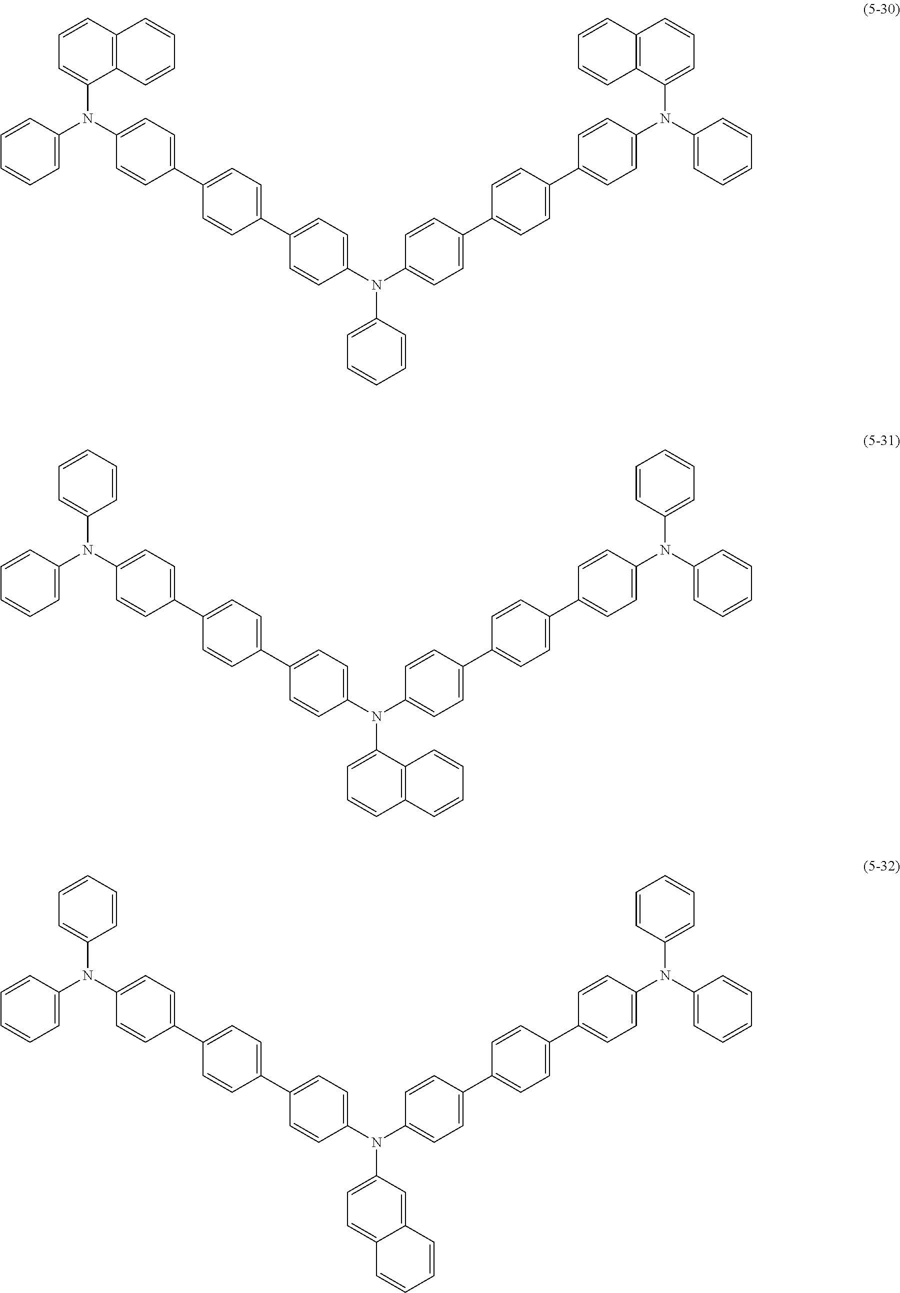

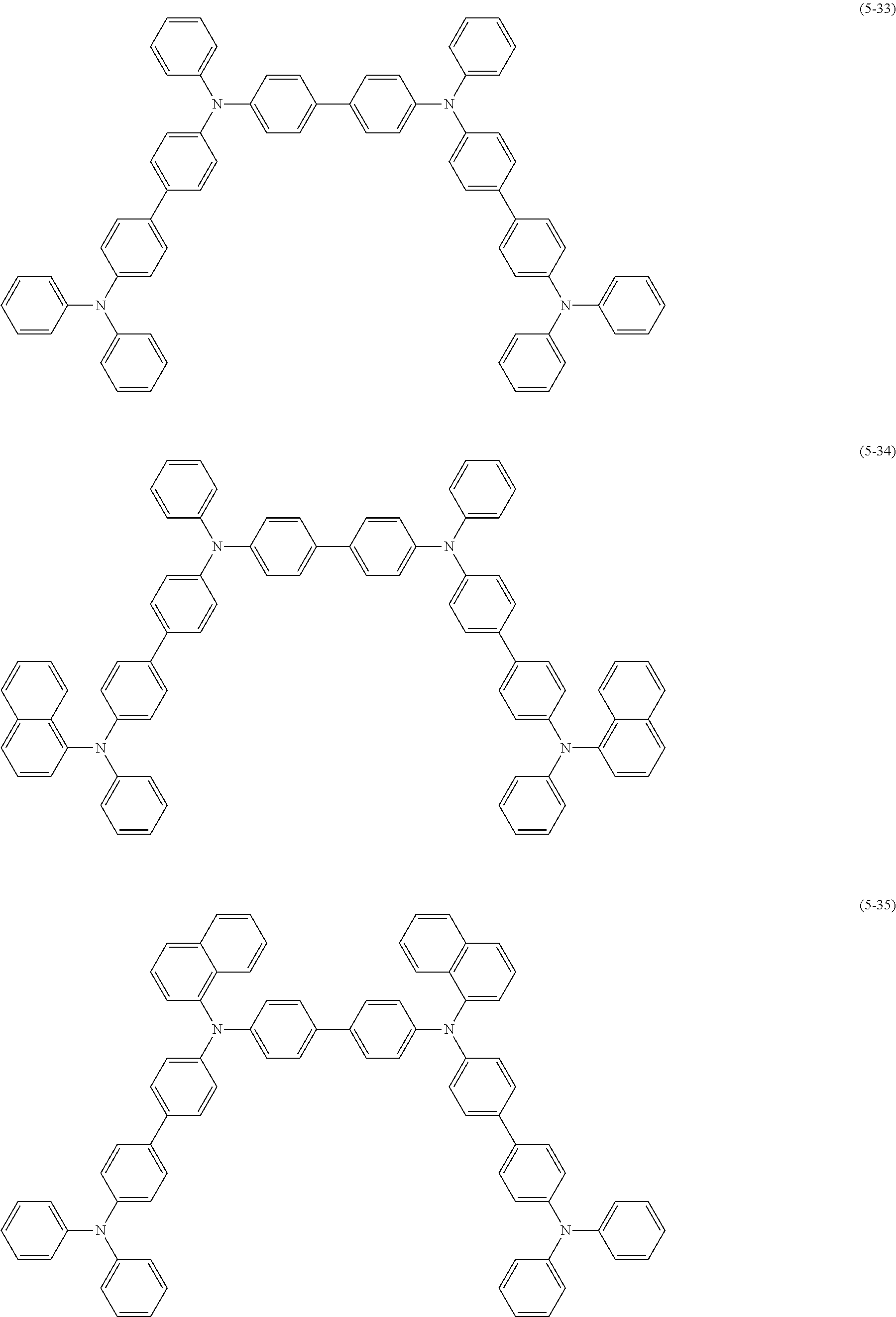

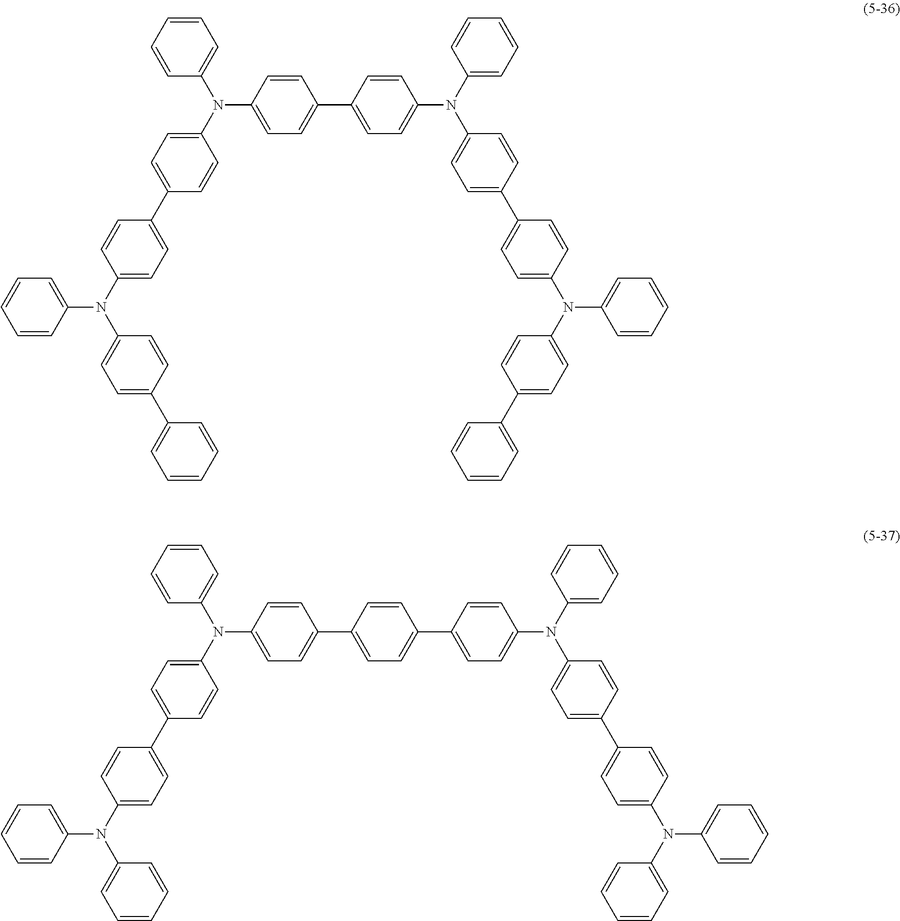

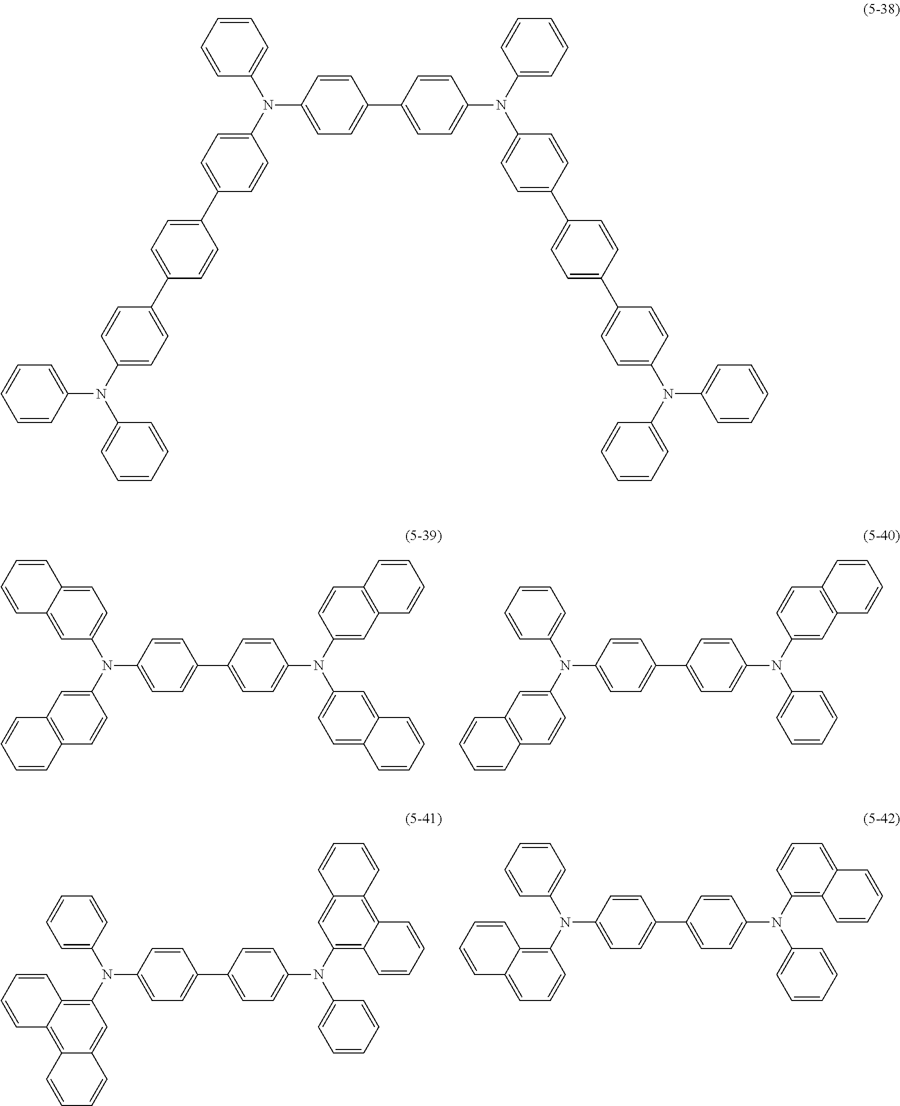

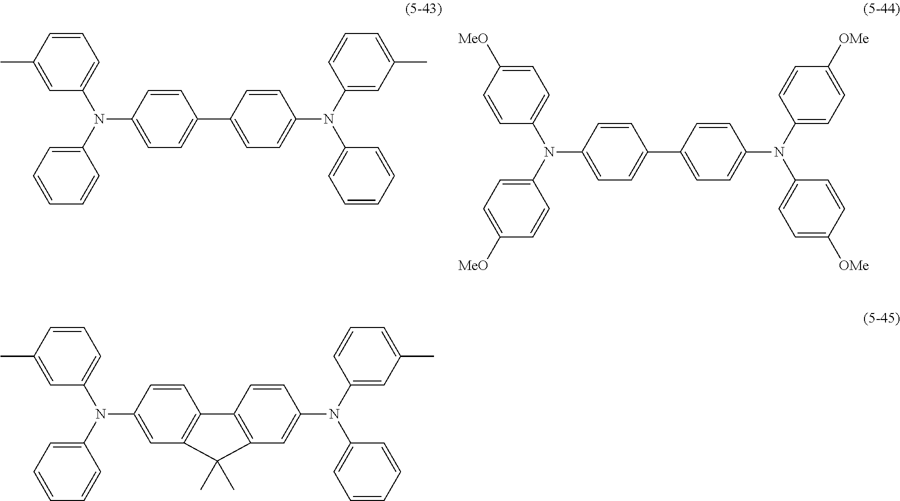

Furthermore, as the low molecular weight material added to the red light-emitting layer 16CR and green light-emitting layer 16CG, there may be used compounds having electron transportability. More particularly, mention is made of those compounds represented by the following formulas (6) to (8) and including a benzoimidazole derivative (formula (6)), a pyridylphenyl derivative (formula (7)) and a bipyridine derivative (formula (8)) although not limited thereto,

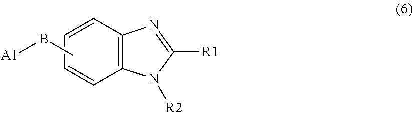

wherein A1 represents a hydrogen atom or halogen atom, an alkyl group having 1 to 20 carbon atoms, or a hydrocarbon group or nitrogen-containing heterocyclic group or a derivative thereof having 6 to 60 carbon atoms and having a polycyclic aromatic hydrocarbon group made of 3 to 40 aromatic rings condensed, B is a single bond, or a divalent aromatic ring group or a derivative thereof, R1 and R2 are independently a hydrogen atom or halogen atom, an alkyl group having 1 to 20 carbon atoms, an aromatic hydrocarbon group having 6 to 60 carbon atoms or nitrogen-containing heterocyclic ring group or an alkoxy group having 1 to 20 carbon atoms, or a derivative thereof,

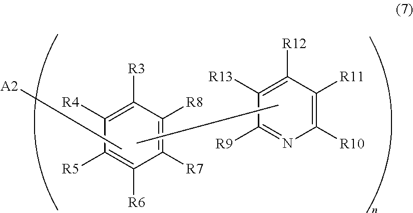

wherein A2 is an n-valent group made of two to five aromatic rings condensed, particularly, an n-valent acene aromatic ring group made of three aromatic rings condensed, or a derivative thereof, R3 to R8 independently represent a hydrogen atom or halogen atom, or a free atomic valence bonding to any one of A2 and R9 to R13, R9 to R13 independently represent a hydrogen atom or halogen atom, or a free atomic valence bonding to any one of R3 to R8, and n is an integer of not smaller than two and n number of pyridylphenyl groups may be the same or different, and

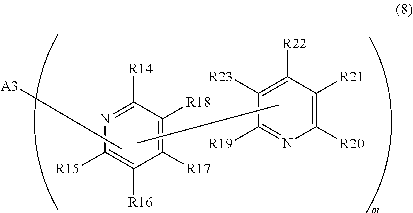

wherein A3 represents an m-valent group made of two to five aromatic rings condensed, particularly, an n-valent acene aromatic group of three aromatic rings condensed or a derivative thereof, R14 to R18 independently represent a hydrogen atom or halogen atom, or a free atomic valence bonding to any one of A3 and R19 to R23, R19 to R23 independently represent a hydrogen atom or halogen atom, or a free atomic valence bonding to any one of R14 to R18, m is an integer of not smaller than two and m number of bipyridyl groups may be the same or different.

Specific examples of the compound represented by the formula (6) include those compounds such as of the following formulas (6-1) to (6-43). It will be noted that Ar(α) corresponds to an benzoimidazole skeleton including R1 and R2 in the formula (6) and B corresponds to B in the formula (6). Ar(1) and Ar(2), respectively, correspond to A1 in the formula (6), and Ar(1) and Ar(2) are bonded to B in this order.

| | Ar (α) | B | Ar (1) | Ar (2) |
|---|---|---|---|---|
| (6-1) | 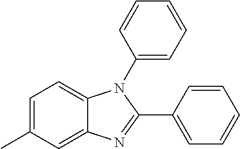 | 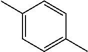 | 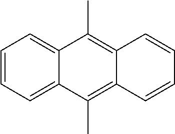 | 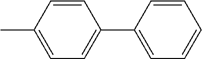 |
| (6-2) | 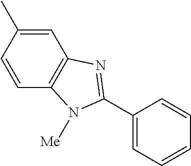 | 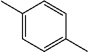 | 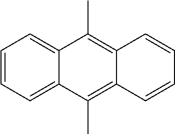 | 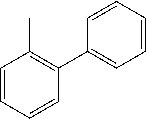 |
| (6-3) | 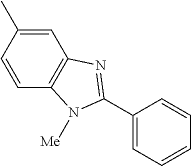 | 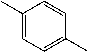 | 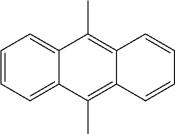 | 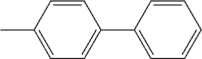 |
| (6-4) | 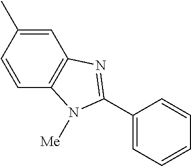 | 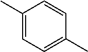 | 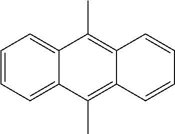 | 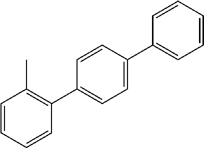 |
| (6-5) | 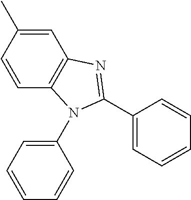 | 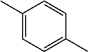 | 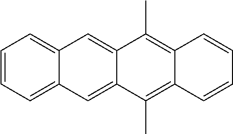 | 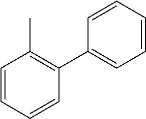 |
| (6-6) | 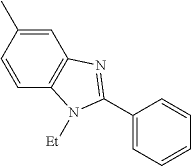 | 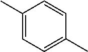 | 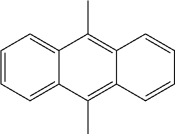 | 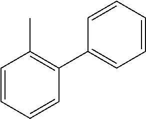 |
| (6-7) | 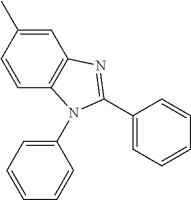 | 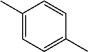 | 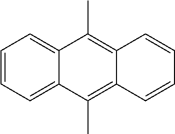 | 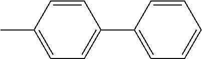 |
| (6-8) | 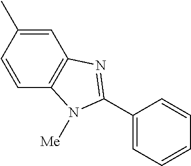 | 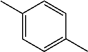 | 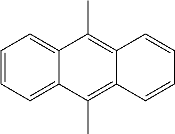 | 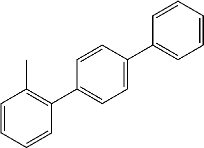 |
| (6-9) | 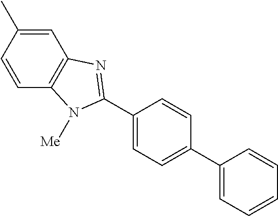 | 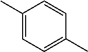 | 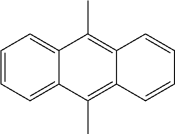 | 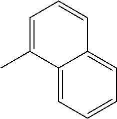 |
| (6-10) | 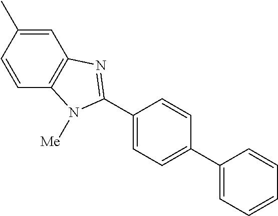 | 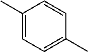 | 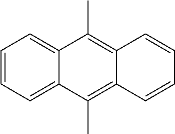 | 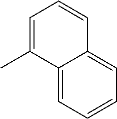 |
| (6-11) | 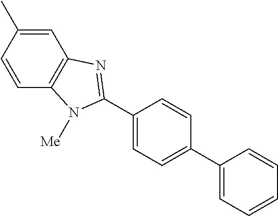 | 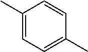 | 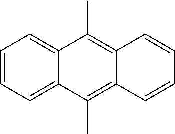 | 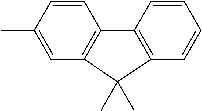 |
| (6-12) | 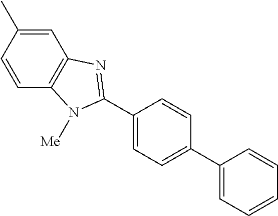 | 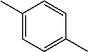 | 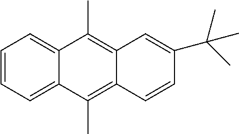 | 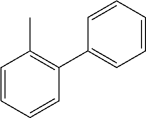 |
| (6-13) | 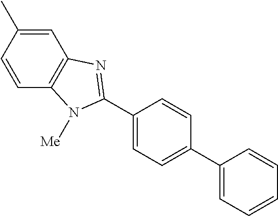 | 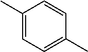 | 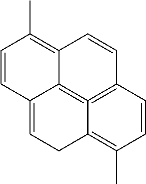 | 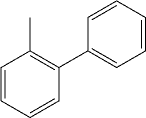 |
| (6-14) | 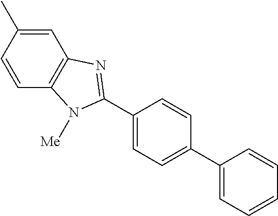 | 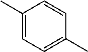 | 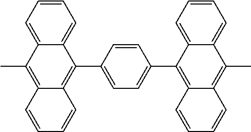 | 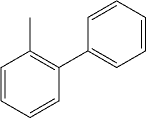 |
| (6-15) | 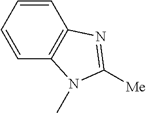 | 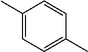 | 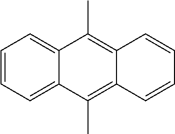 | 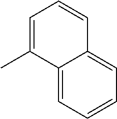 |
| (6-16) | 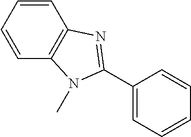 | 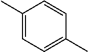 | 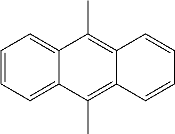 | 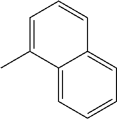 |
| (6-17) | 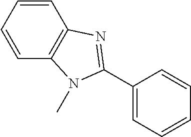 | 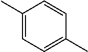 | 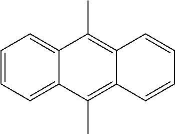 | 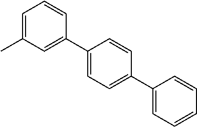 |
| (6-18) | 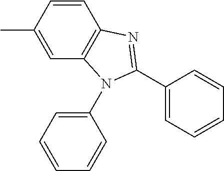 | 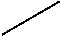 | 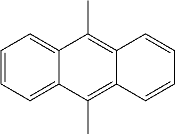 | 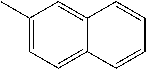 |
| (6-19) | 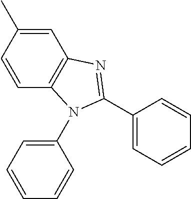 | 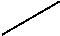 | 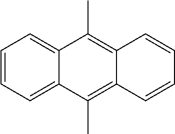 | 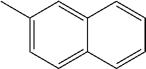 |
| (6-20) | 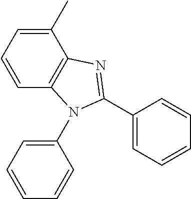 | 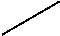 | 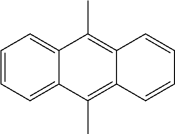 | 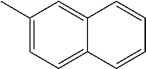 |
| (6-21) | 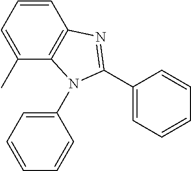 | 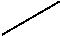 | 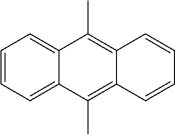 | 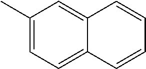 |
| (6-22) | 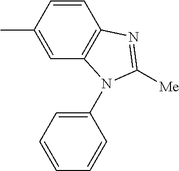 | 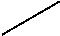 | 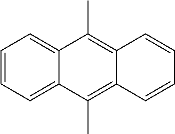 | 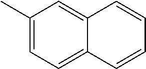 |
| (6-23) | 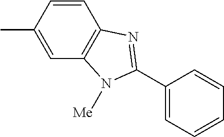 | 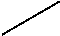 | 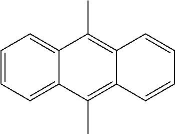 | 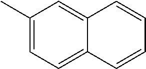 |
| (6-24) | 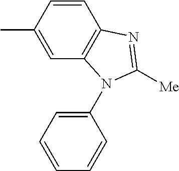 | 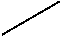 | 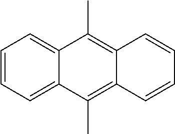 | 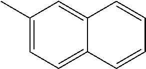 |
| (6-25) | 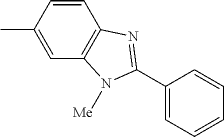 | 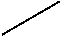 | 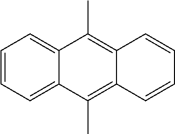 | 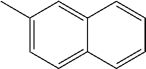 |
| (6-26) | 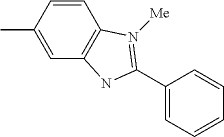 | 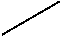 | 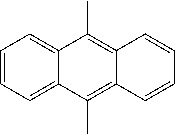 | 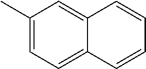 |
| (6-27) | 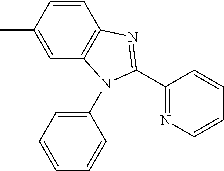 | 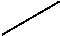 | 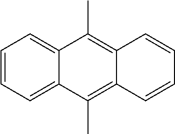 | 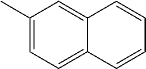 |
| (6-28) | 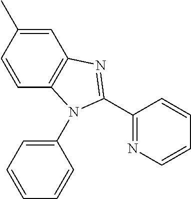 | 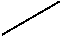 | 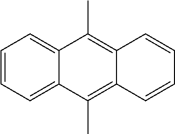 | 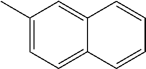 |
| (6-29) | 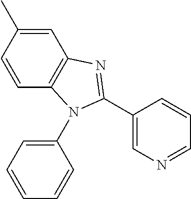 | 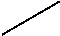 | 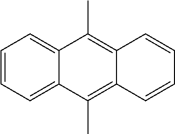 | 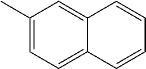 |
| (6-30) | 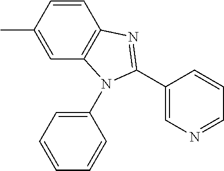 | 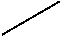 | 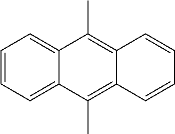 | 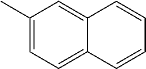 |
| (6-31) | 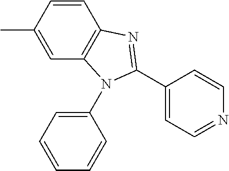 | 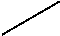 | 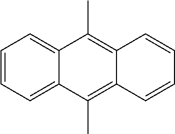 | 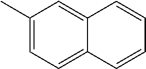 |
| (6-32) | 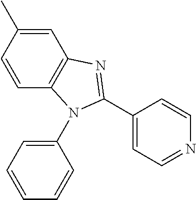 | 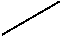 | 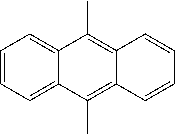 | 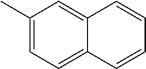 |
| (6-33) | 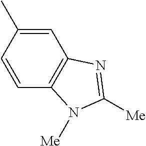 | 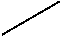 | 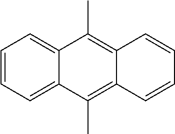 | 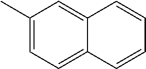 |
| (6-34) | 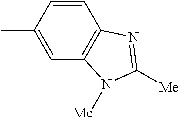 | 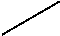 | 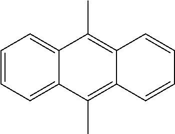 | 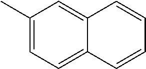 |
| (6-35) | 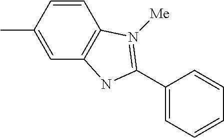 | 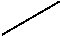 | 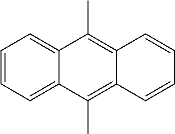 | 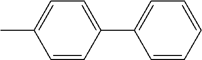 |
| (6-36) | 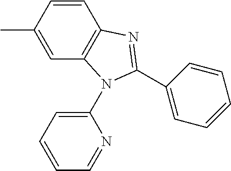 | 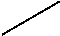 | 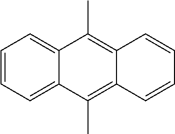 | 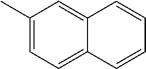 |
| (6-37) | 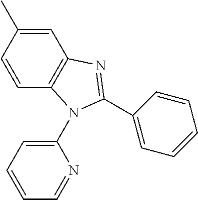 | 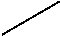 | 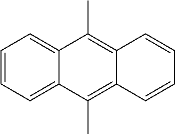 | 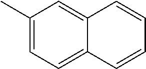 |
| (6-38) | 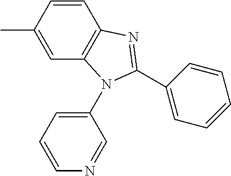 | 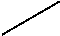 | 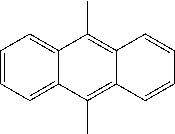 | 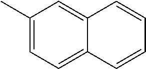 |
| (6-39) | 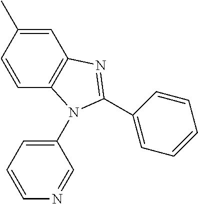 | 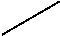 | 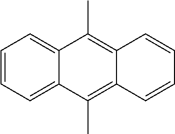 | 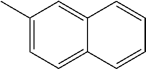 |
| (6-40) | 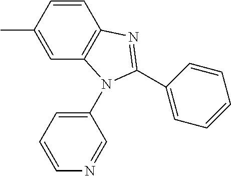 | 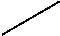 | 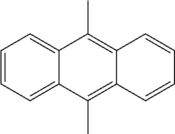 | 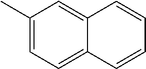 |
| (6-41) | 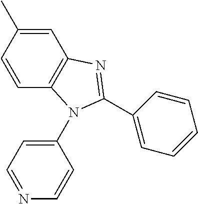 | 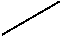 | 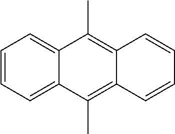 | 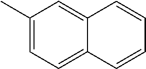 |
| (6-42) | 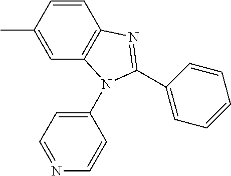 | 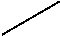 | 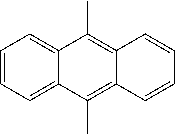 | 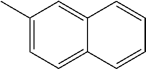 |
| (6-43) | 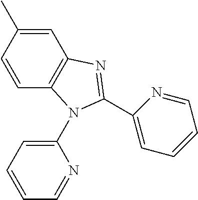 | 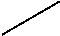 | 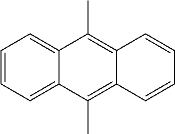 | 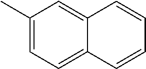 |

Specific examples of the compound represented by the formula (7) include those compounds such as of the following formulas (7-1) to (7-81).

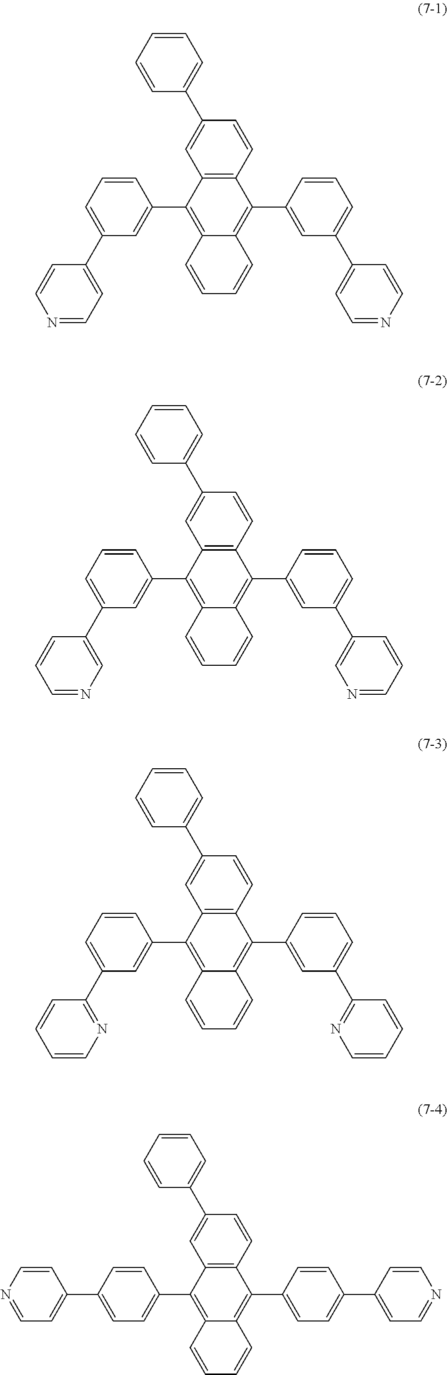

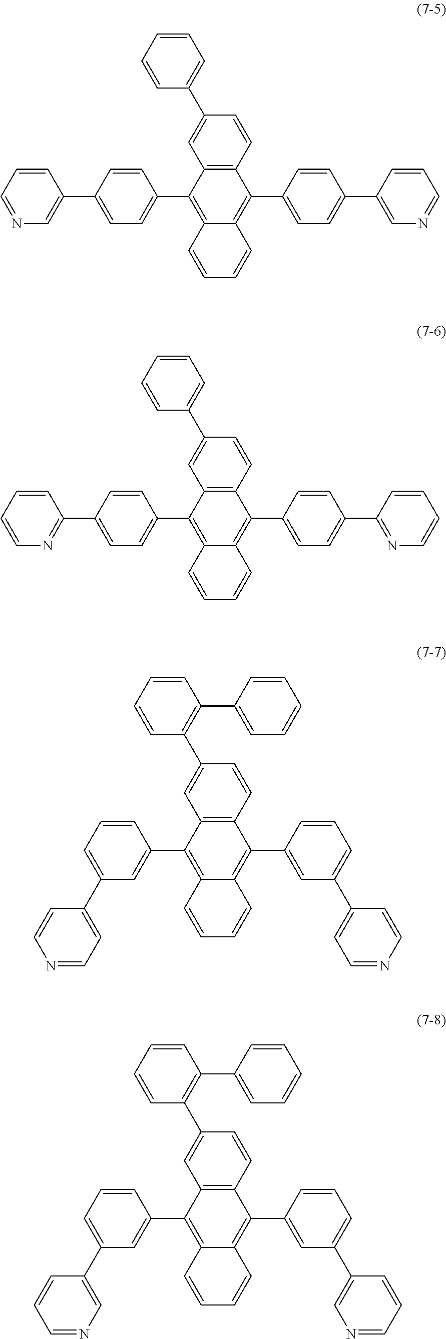

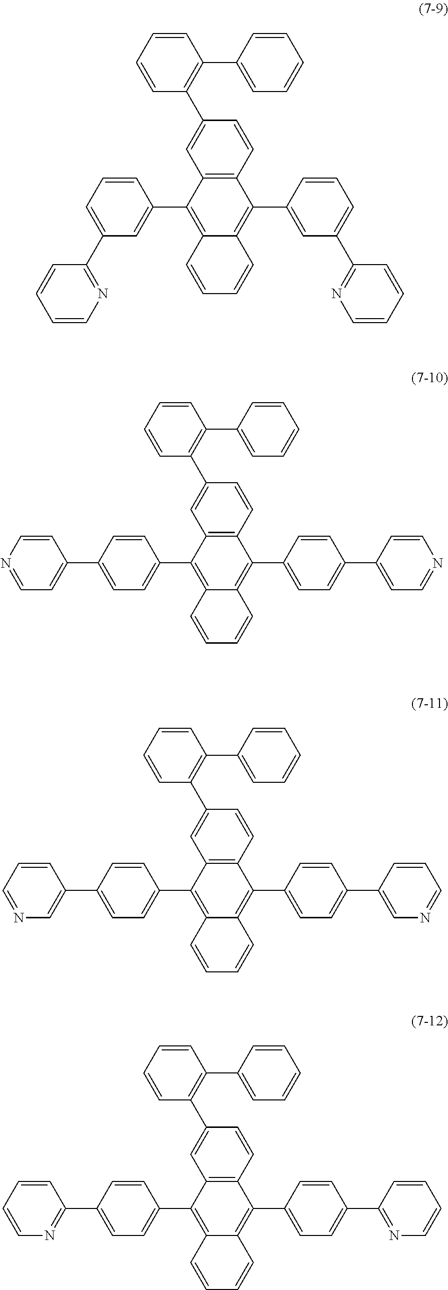

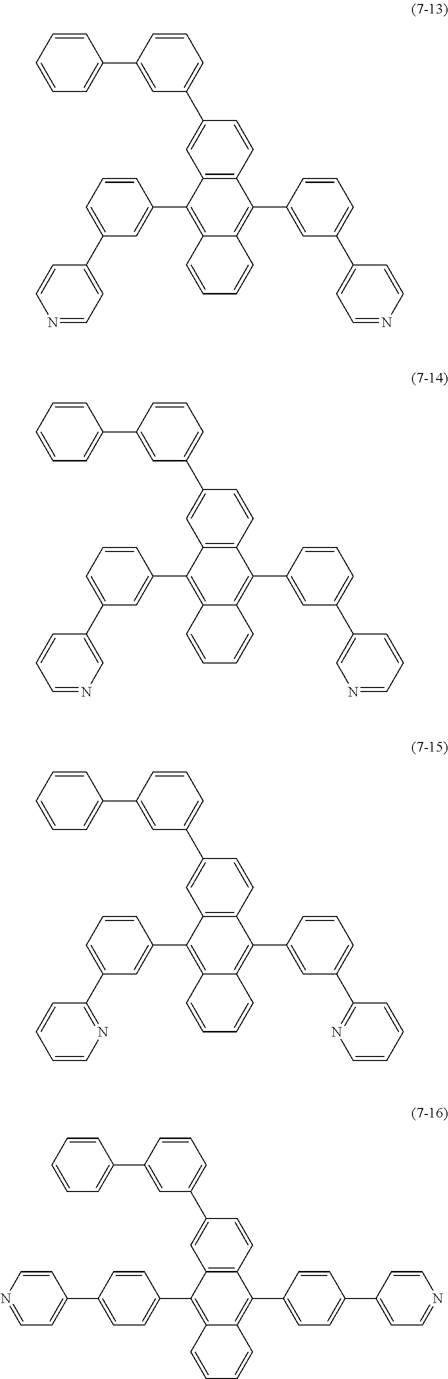

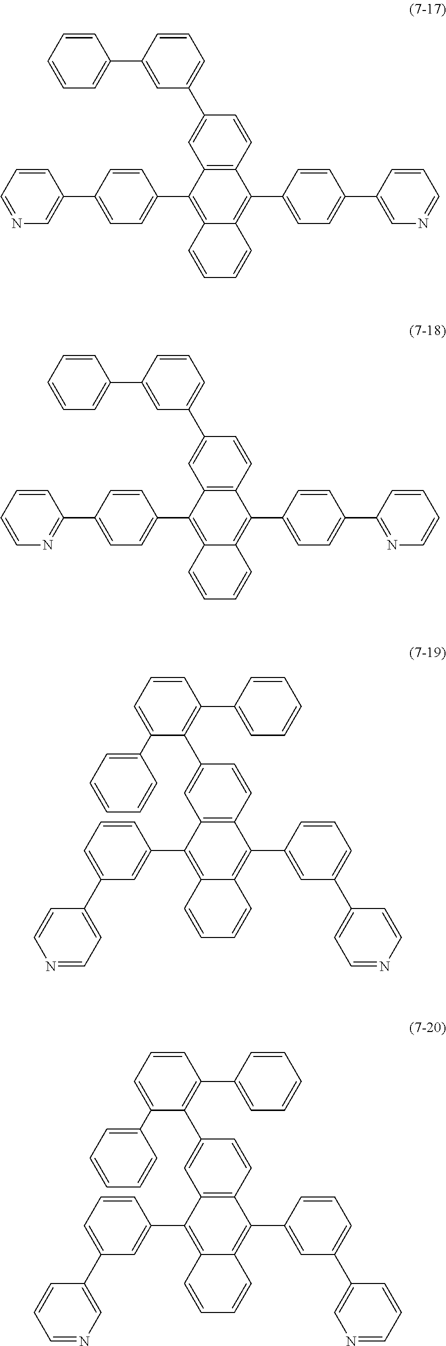

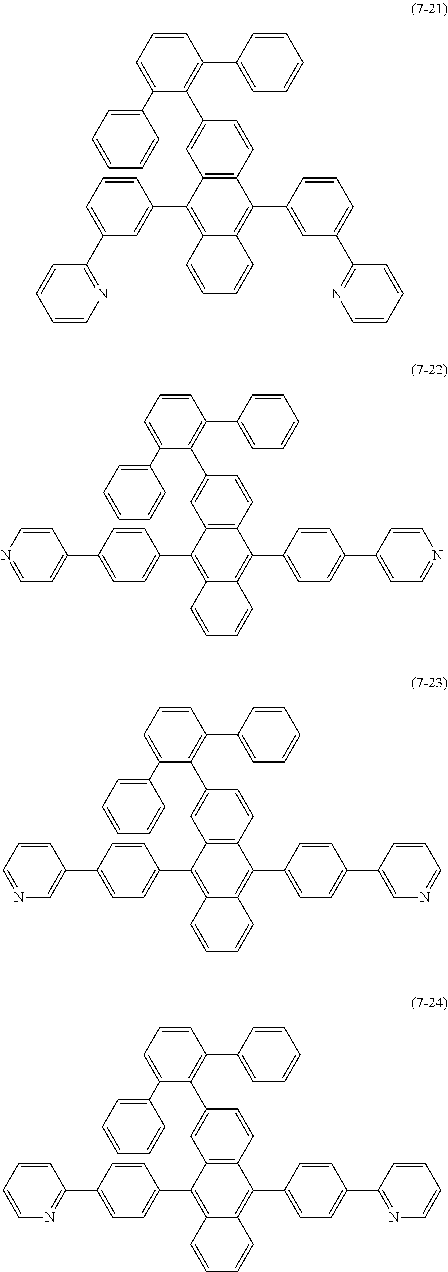

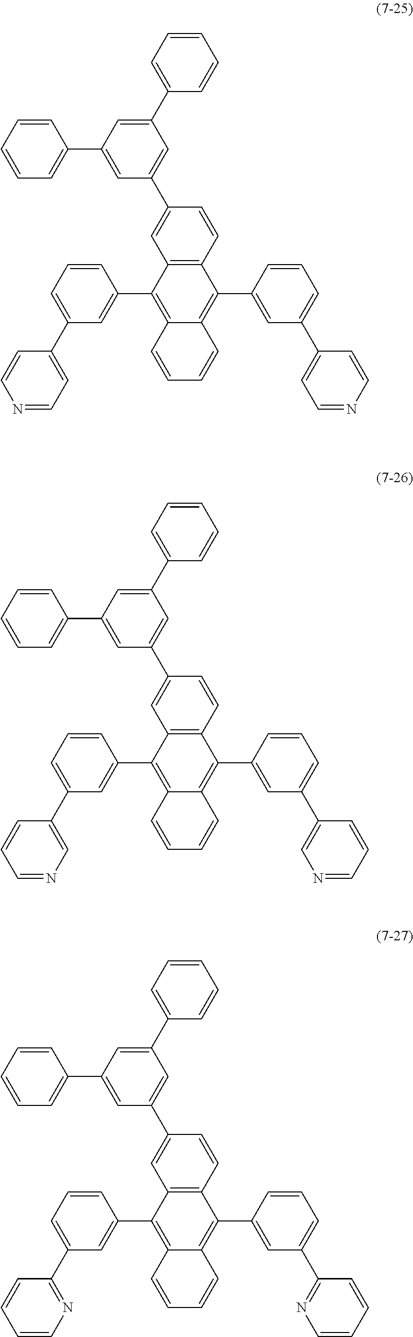

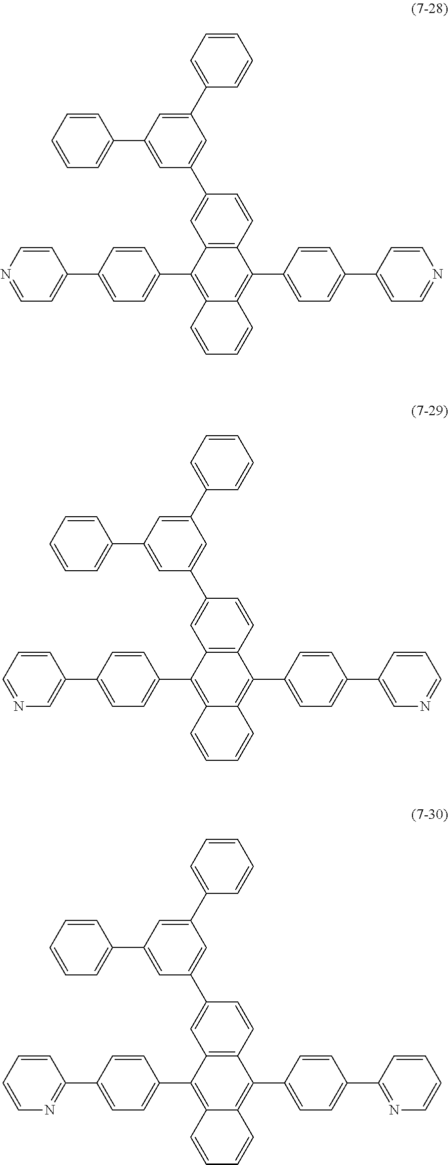

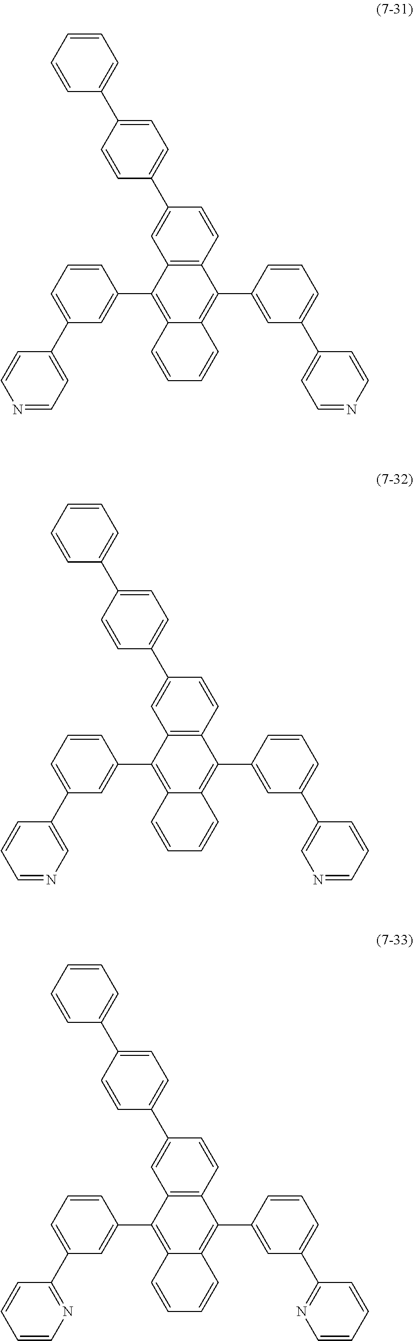

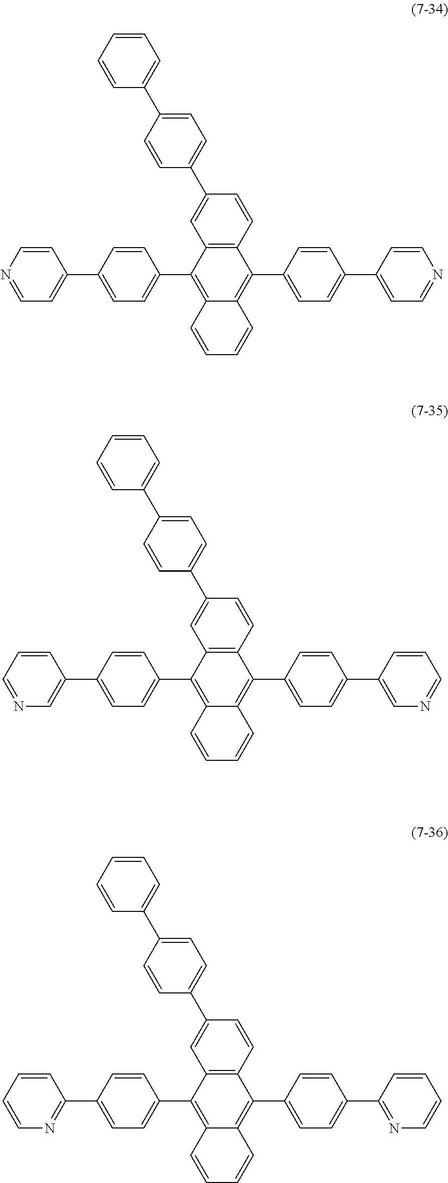

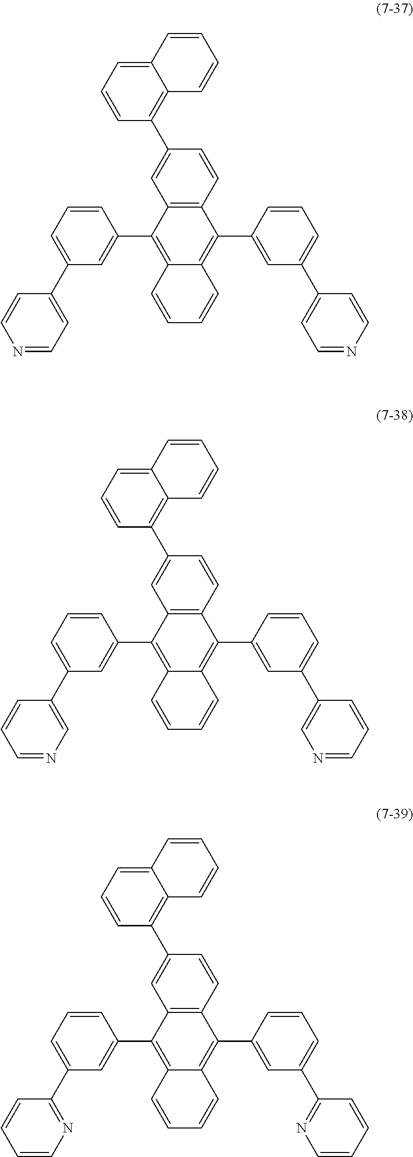

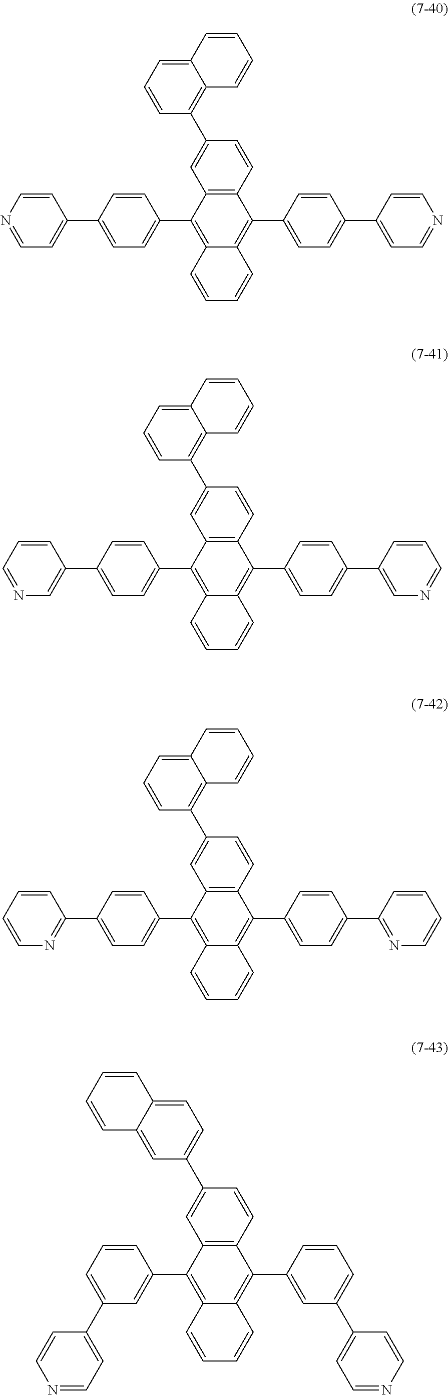

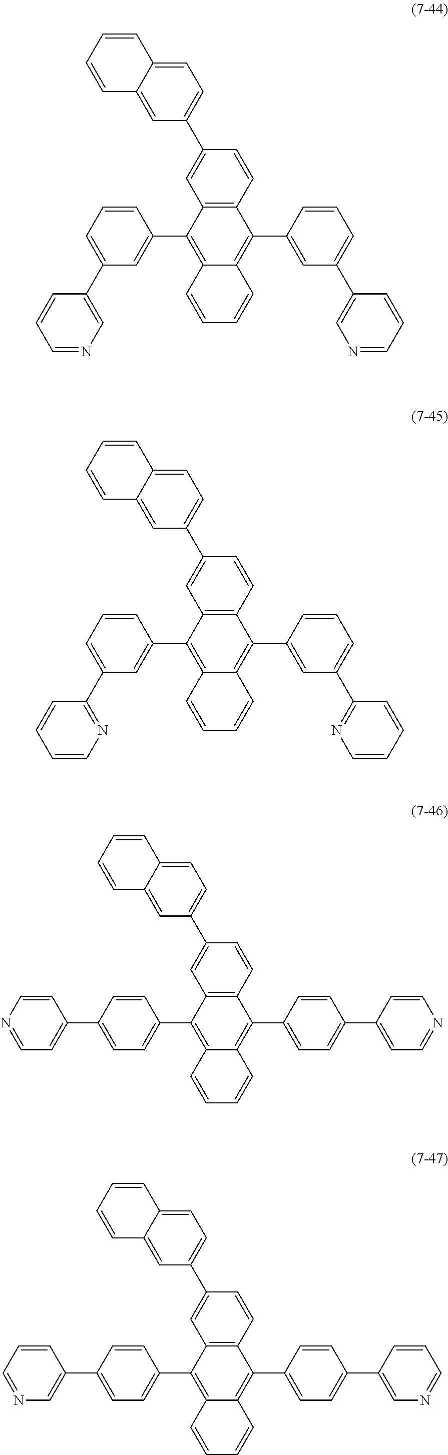

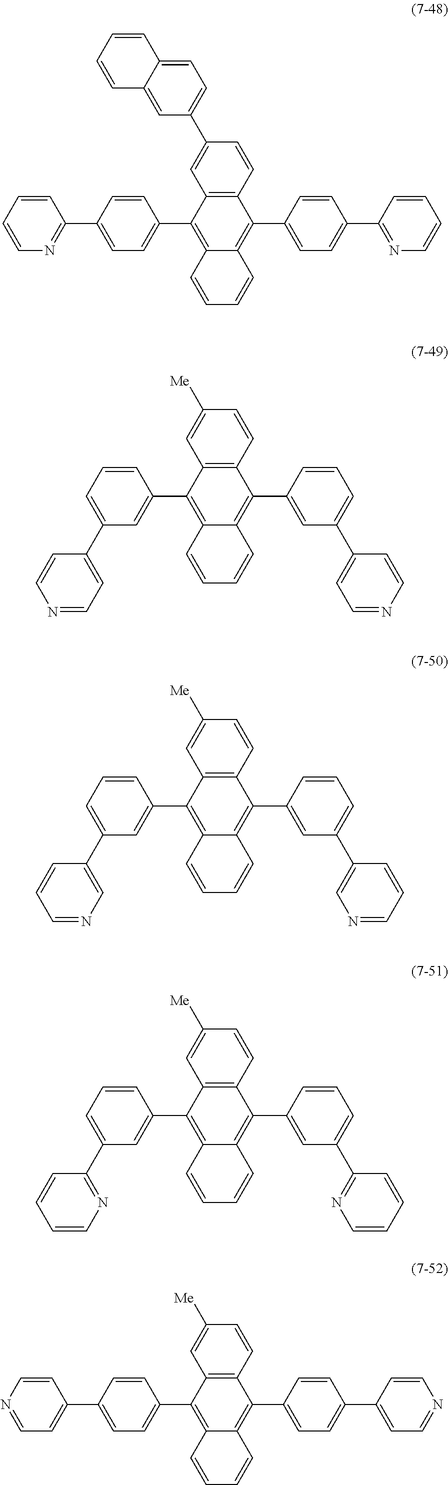

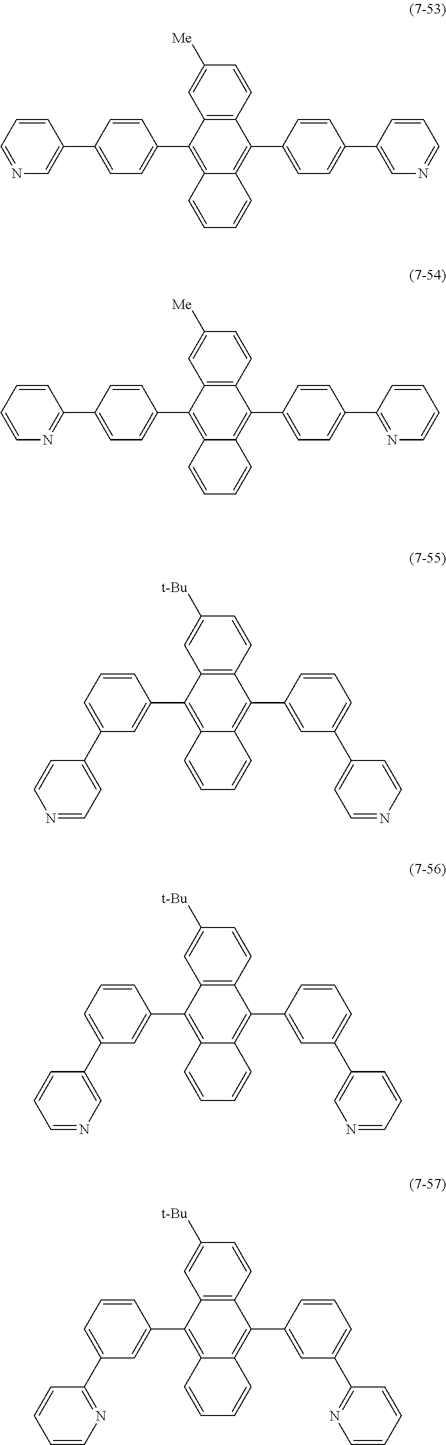

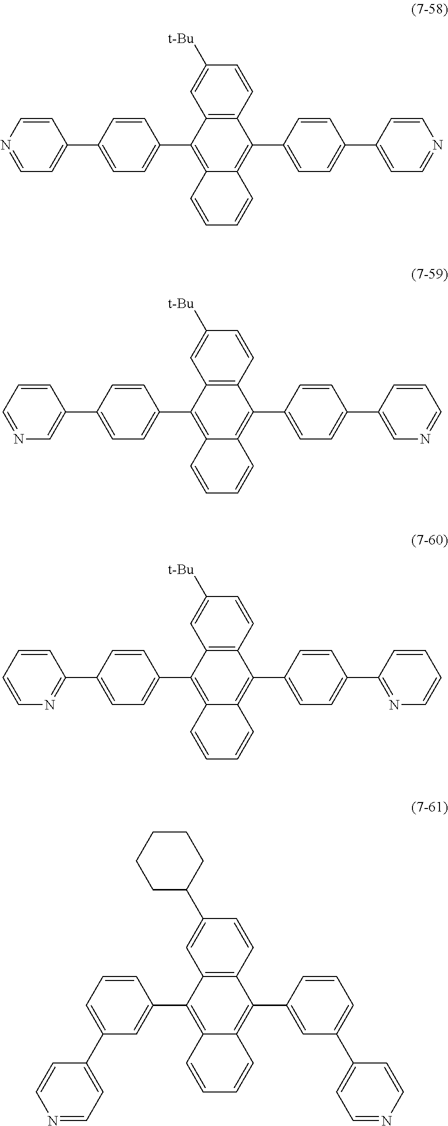

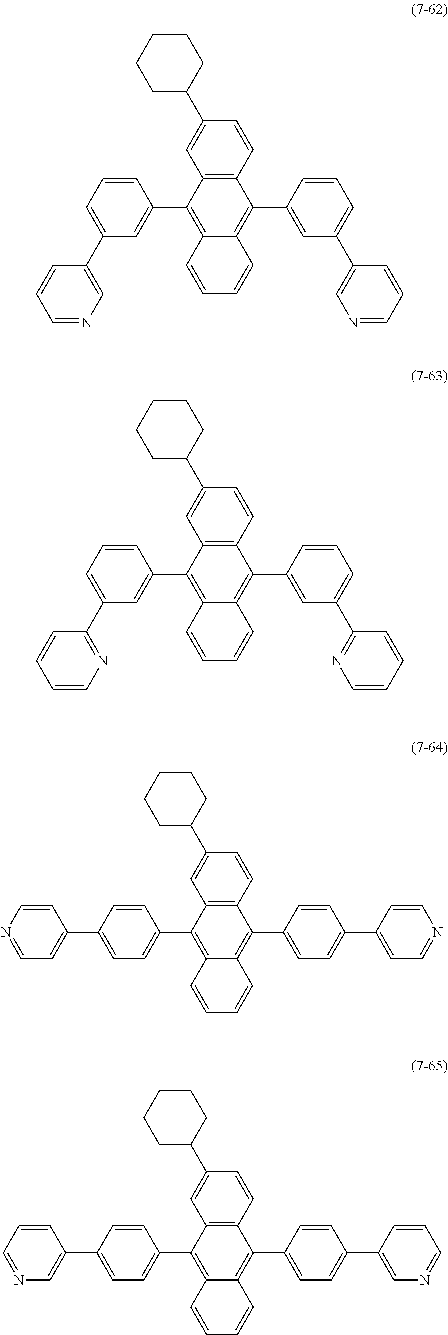

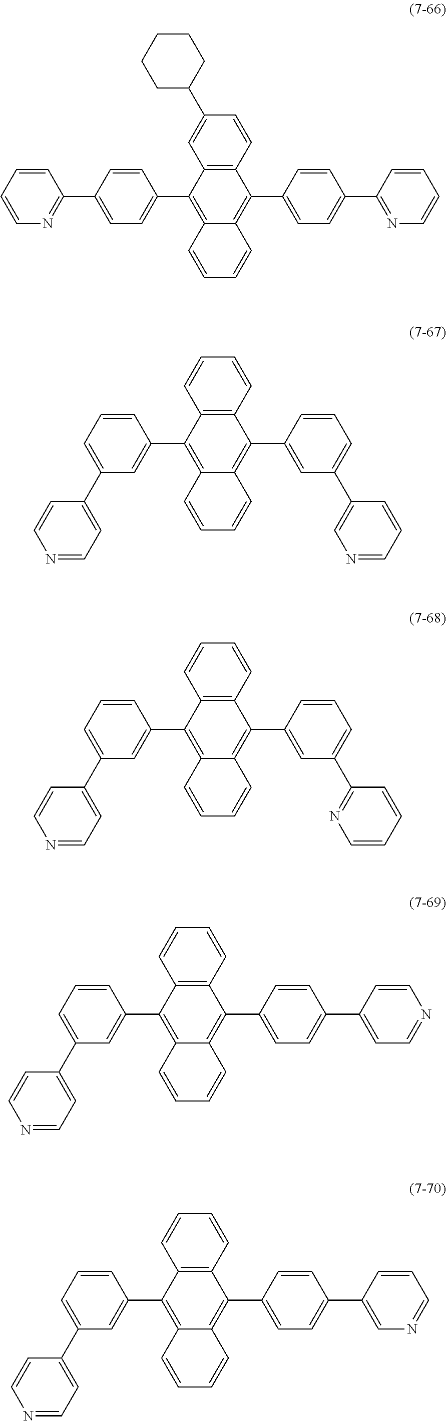

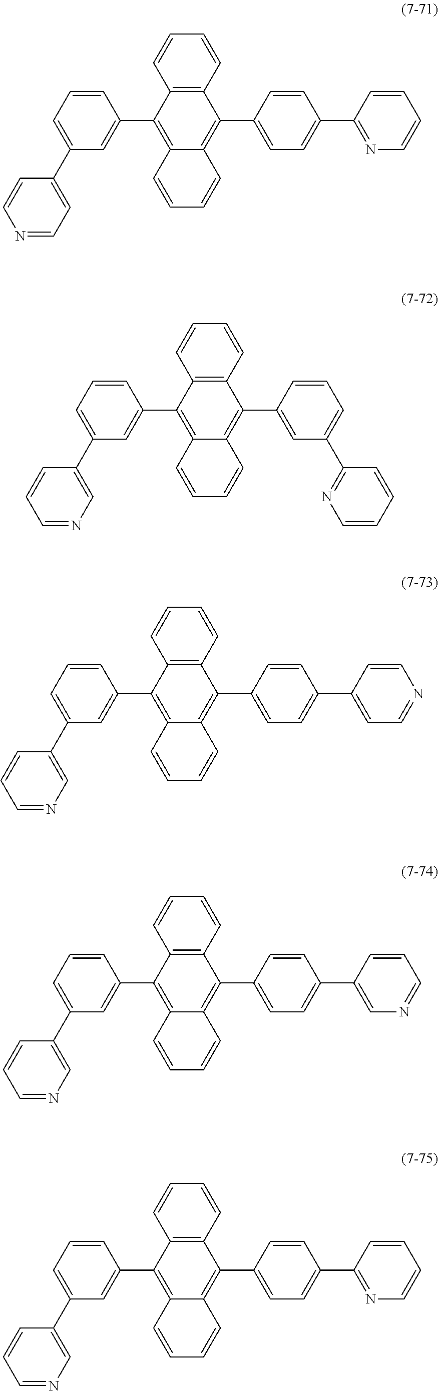

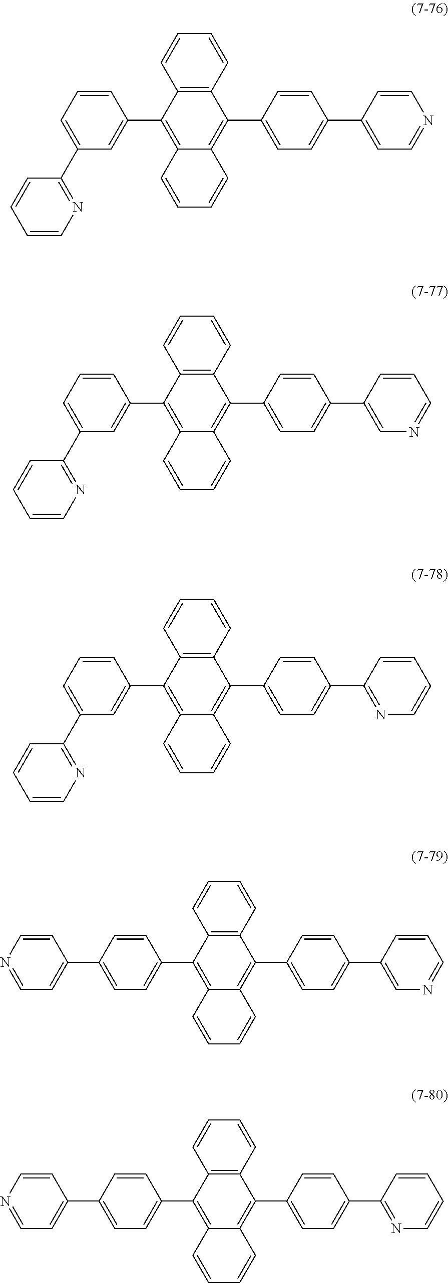

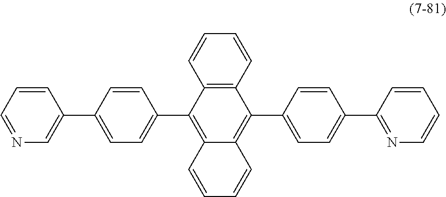

Specific examples of the compound represented by the formula (8) include the compounds such as of the following compounds (8-1) to (8-17).

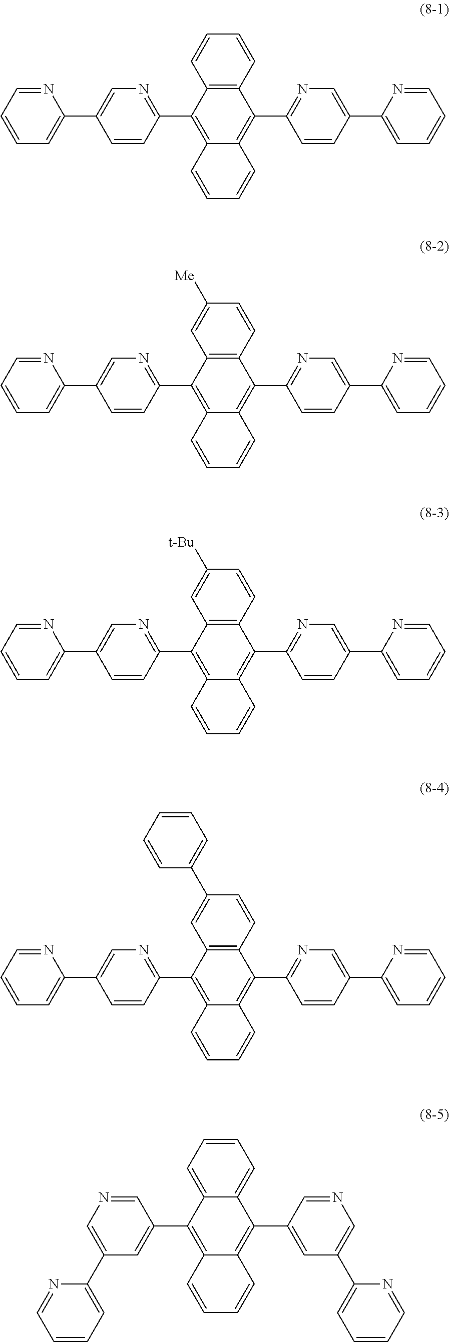

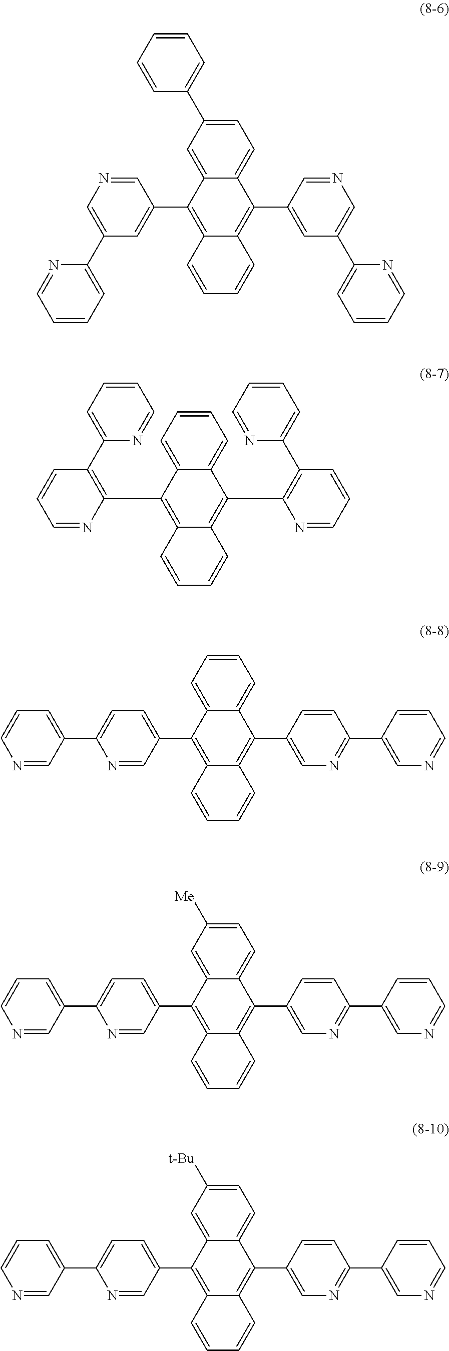

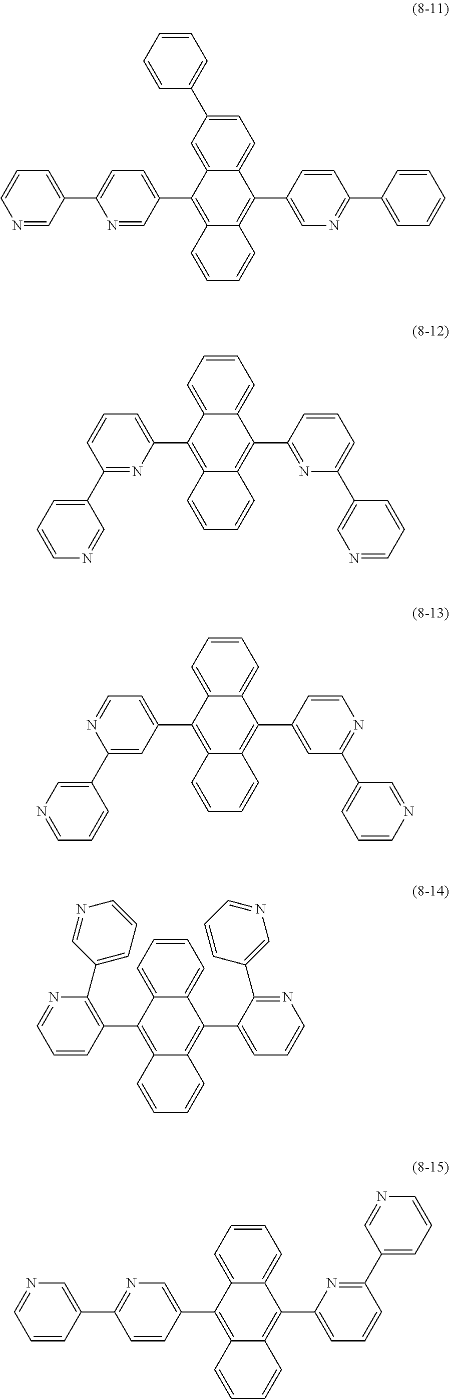

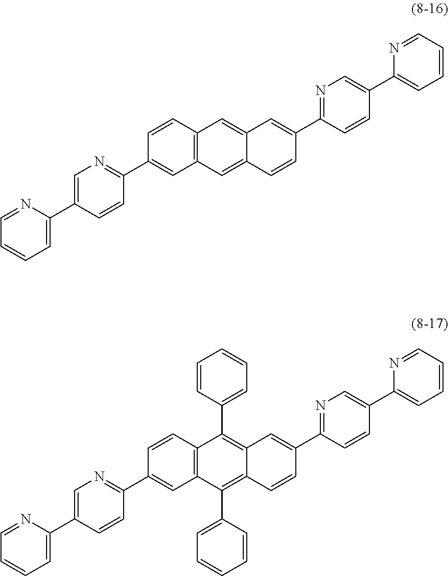

The low molecular weight materials added to the red light-emitting layer 16CR and green light-emitting layer 16CG include, aside from the compounds represented by the foregoing formulas (6) to (8), pyrazole derivatives represented by the following formula (9), for example,

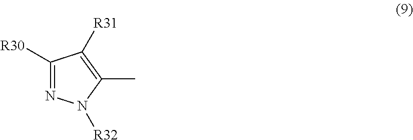

wherein R30 to R32 independently represent a hydrogen atom, an aromatic hydrocarbon group made of one to three aromatic rings condensed or a derivative thereof, an aromatic hydrocarbon group made of one to three aromatic rings that have a hydrocarbon group having one to six carbon atoms and are condensed, or a derivative thereof, or an aromatic hydrocarbon group made of one to three aromatic rings that have an aromatic hydrocarbon group having 6 to 12 carbon atoms and are condensed, or a derivative thereof.

The group represented by R30 to R32 in the compound represented by the formula (9) and having an aromatic hydrocarbon group includes, for example, a phenyl group, a 2-methylphenyl group, a 3-methylphenyl group, a 4-methylphenyl group, a 2,4-dimethylphenayl group, a 3,4-dimethylphenyl group, a 2,4,5-trimethylphenyl group, a 4-ethylphenyl group, a 4-tert-butylphenyl group, a 1-naphthyl group, a 2-naphthyl group, a 1-anthracenyl group, a 2-anthracenyl group, a 9-anthracenyl group, a 9-phenanthrenyl group and the like although not limited thereto. It will be noted that R30 to R32 may be the same or different.

Specific examples of the compound represented by the formula (9) include those compounds of the following formulas (9-1) to (9-5) containing two to smaller than four pyrazole structures in the same molecule.

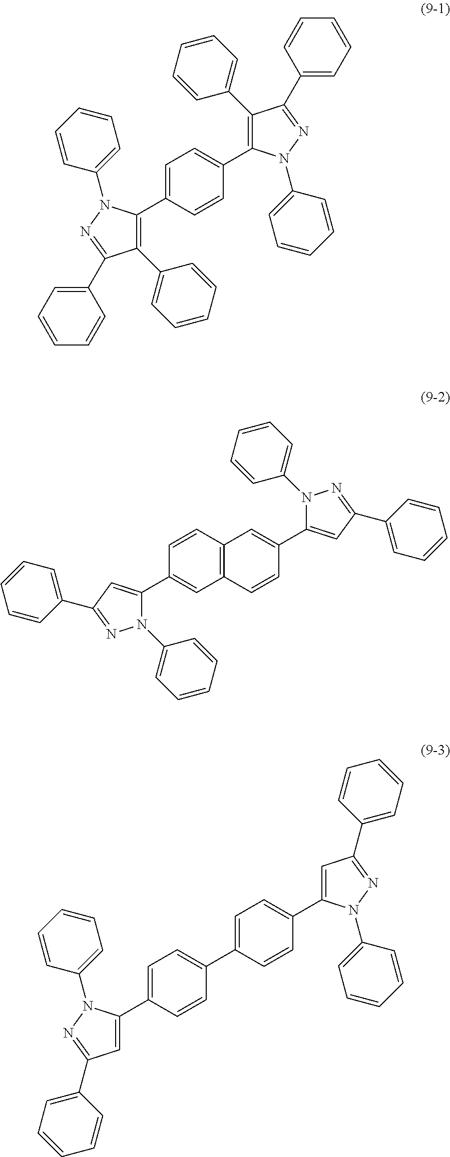

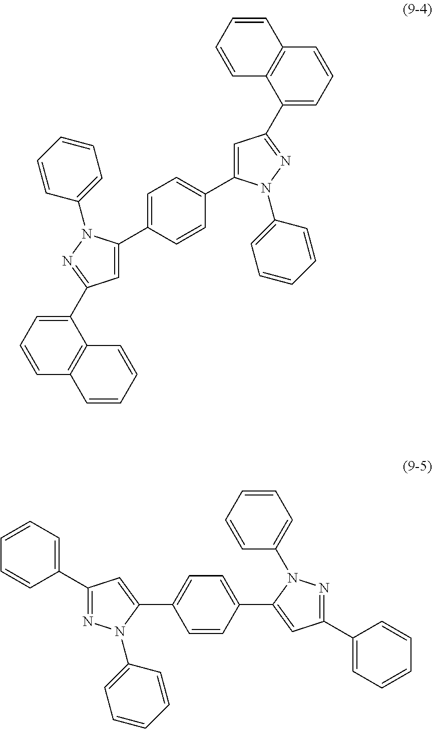

Further, there may also be used phosphorescent materials. Specific examples include metal complexes containing at least one metal element such as beryllium (Be), boron (B), zinc (Zn), cadmium (Cd), magnesium (Mg), gold (Au), silver (Ag), palladium (Pd), platinum (Pt), aluminum (Al), gadolinium (Ga), yttrium (Y), scandium (Sc), ruthenium (Ru), rhodium (Rh), osmium (Os), iridium (Ir) and the like. More specifically, those compounds represented by the formulas (10-1) to (10-29) are mentioned although not limited thereto.

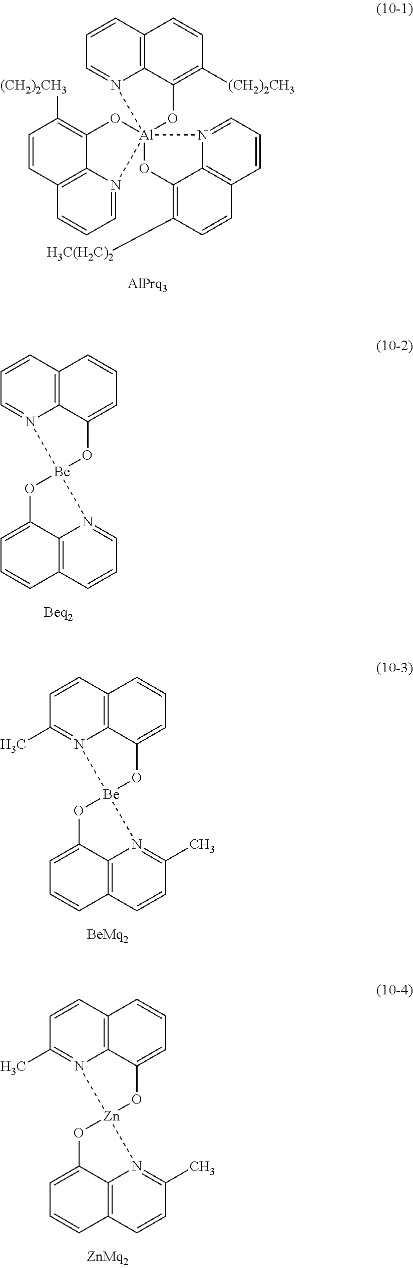

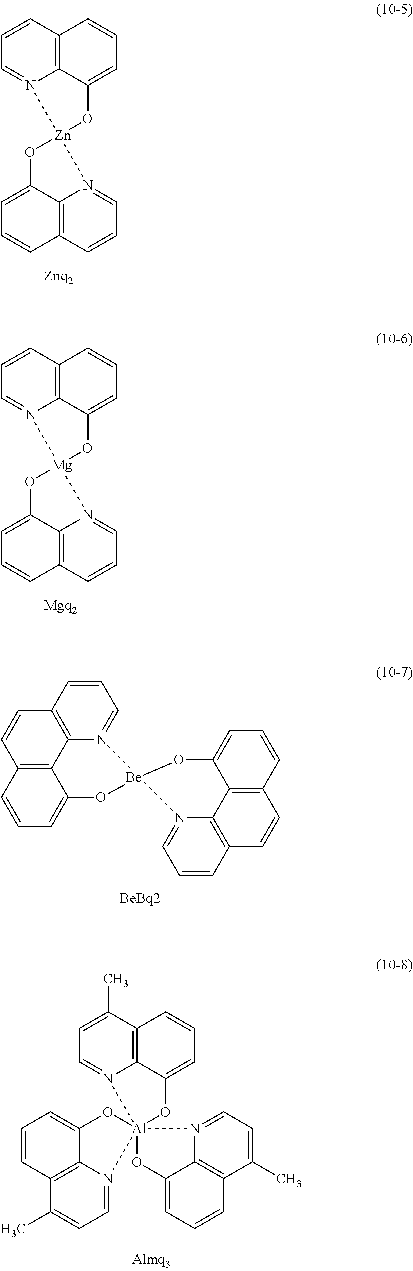

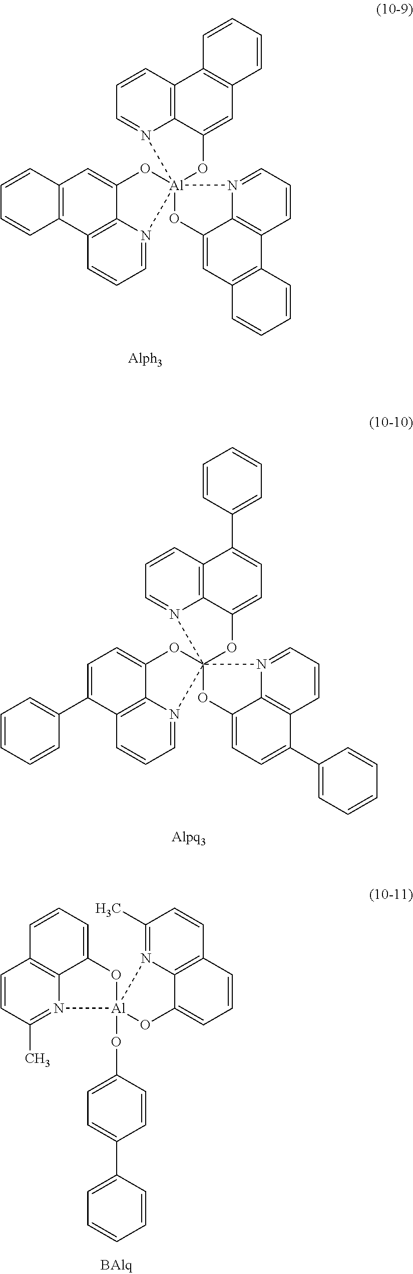

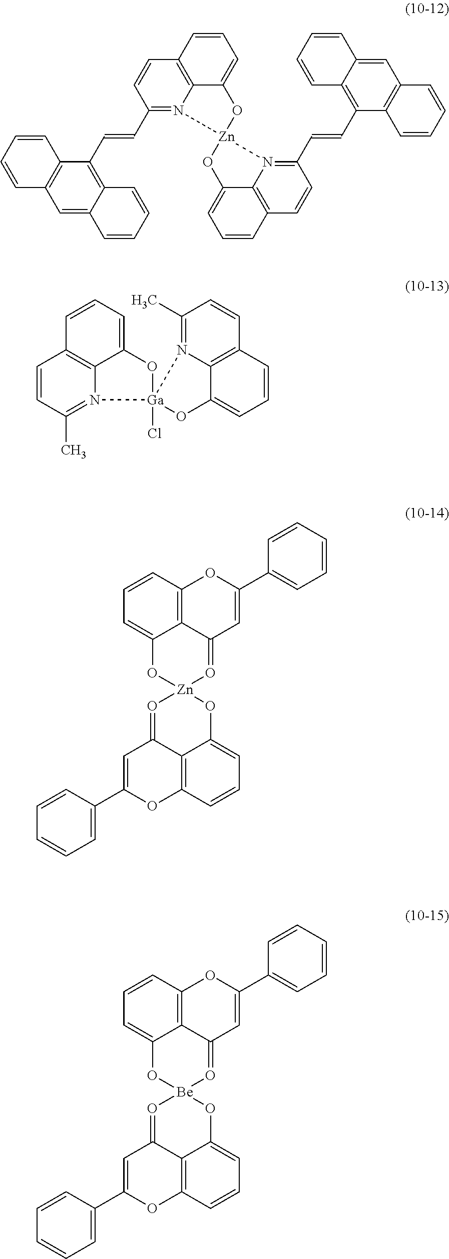

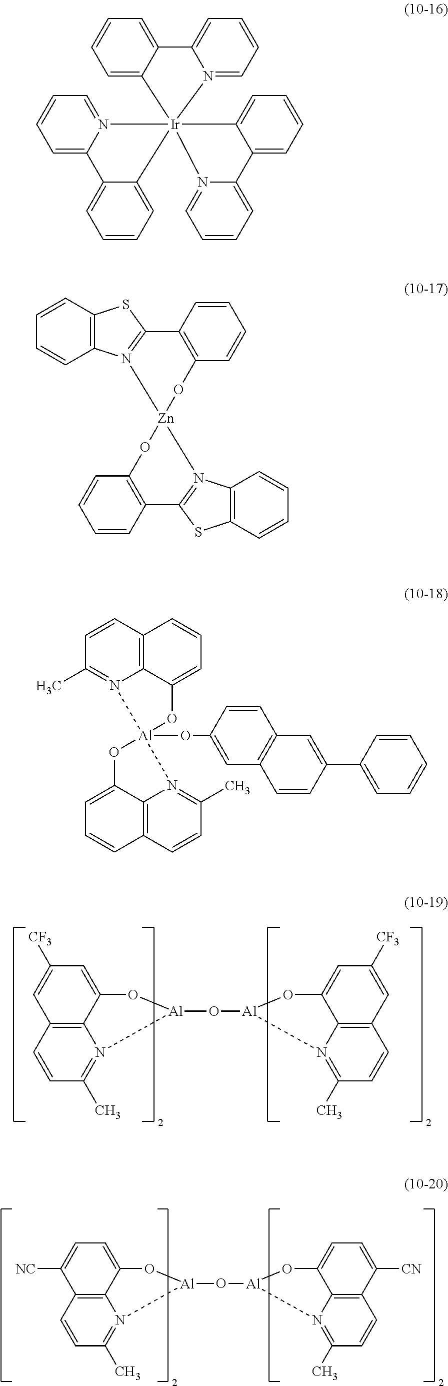

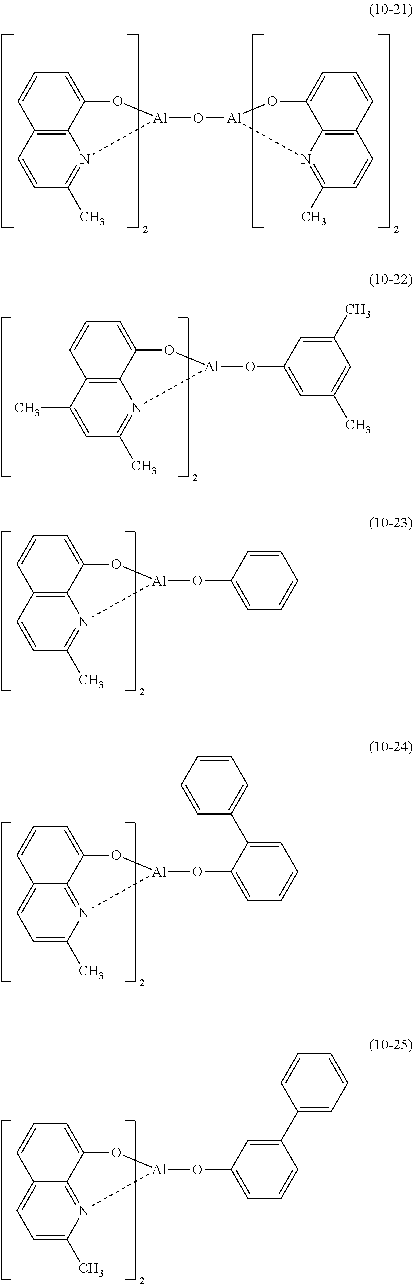

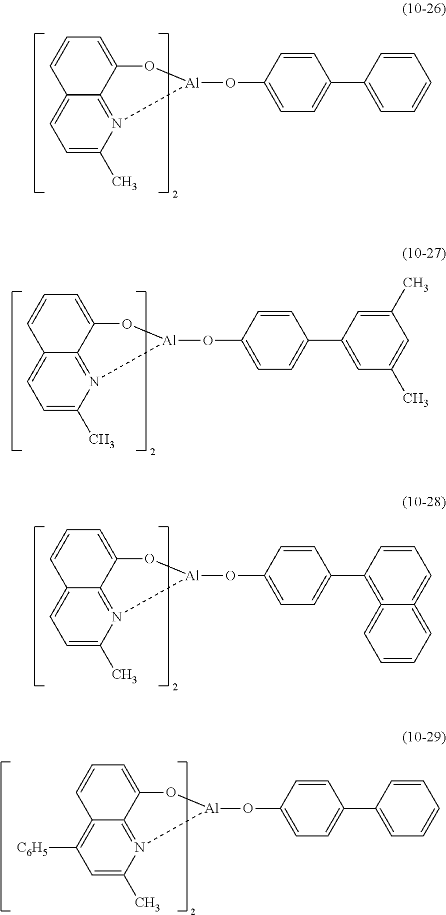

It is to be noted that the low molecular weight materials added to the red light-emitting layer 16CR, green light-emitting layer 16CG and blue light-emitting layer 16CB may be used not only singly, but also in admixture of a plurality thereof.

The hole transport layer 16BB of the blue organic EL element 10B is one that enhances the hole transport efficiency to the blue light-emitting layer 16C and is formed on the hole injection layer 16AB. Although depending on the entire configuration of element, the thickness of the hole transport layer 16BB is preferably, for example, at 10 nm to 200 nm, more preferably at 15 nm to 150 nm.

The hole transport layer 16BB may be made of either a low molecular weight material (i.e. a monomer or oligomer) or a high molecular weight material. The monomer selected among the low molecular weight materials used herein is one other than compounds such as polymers or condensates of low molecular weight compounds similar to low molecular weight materials added to the red light-emitting layer 16CR and green light-emitting layer 16CG, and has a single molecular weight and exists as a single molecule. An oligomer means one wherein a plurality of monomer molecules are bound together with a weight average molecular weight (Mw) being at not larger than 50,000. Moreover, like high molecular weight materials used as the hole transport layers 16BR and 16BG, the weight average molecular weight of the high molecular weight material may be within a range of 50,000 to 300,000, preferably about 100,000 to 200,000. It will be noted that the low molecular weight material and high molecular weight material used for the hole transport layer 16BB may be a mixture of two or more materials whose molecular weights and weight average molecular weights differ from one another.

The low molecular weight materials used as the hole transport layer 16BB include, for example, benzin, styrylamine, triphenylamine, porphyrin, triphenylene, azatriphenylene, tetracyanoquinodimethane, triazole, imidazole, oxadiazole, polyarylalkane, phenylenediamine, arylamine, oxazole, anthracene, fluorenone, hydrazone, stilbene or derivatives thereof, polysilane compounds, vinylcarbazole compounds, and heterocyclic conjugated monomers, oligomers or polymers such as of thiophene compounds or aniline compounds.

More specific examples of the material include a-naphthylphenylphenylenediamine, porphyrin, metal tetraphenylporphyrin, metal naphthalocyanine, hexacyanoazatriphenylene, 7,7,8,8-tetracyanoquinodimethane (TCNQ), 7,7,8,8-tetracyano-2,3,5,6-tetrafluoroquinodimethane (F4-TCNQ), tetracyano-4,4,4-tris(3-methylphenylphenylamino)triphenylamine, N,N,N′,N′-tetrakis(p-tolyl)-p-phenylenediamine, N,N,N′,N′-tetraphenyl-4,4′-diaminobiphenyl, N-phenylcarbazole, 4-di-p-tolylaminostilbene, poly(paraphenylenevinylene), poly(thiophenevinylene), poly(2,2′-thienylpyrrole) and the like although not limited thereto.

Further, the hole transport layer 16BB is preferably formed of the low molecular weight material represented by any of the foregoing formulas (1) to (3). Specific examples include the compounds represented by the foregoing formulas (1-1) to (1-48), (2-1) to (2-69) and (3-1) to (3-49).

The high molecular weight material should be properly selected in association with the relation with the types of materials for electrode and adjacent layers. To this end, there can be used light-emitting materials soluble in organic solvent, including, for example, polyvinylcarbazole, polyfluorene, polyaniline, polysilane and derivatives thereof, polysiloxane derivatives having an aromatic amine at a side or main chain thereof, polythiophene and derivatives thereof, polypyrrole, and the like.

More preferably, mention is made of a high molecular weight material that is good at adhesion to an adjacent organic layer, is soluble in organic solvent, and is represented by the formula (11),

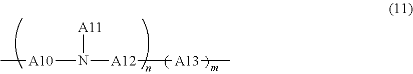

wherein A10 to A13 independently represent a group made of one to ten aromatic hydrocarbon groups or derivatives thereof bonded together, or a group made of 1 to 15 heterocyclic groups or derivatives thereof bonded together, n and m are, respectively, an integer of 0 to 10,000 provided that n+m is an integer of 10 to 20,000.

The n moieties and m moieties are arranged in an arbitrary sequential order. For instance, there may be used any of a random polymer, an alternate copolymer, a periodic copolymer and a block copolymer. Moreover, it is preferred that n and m are, respectively, an integer of 5 to 5,000, more preferably 10 to 3,000. Additionally, n+m is preferably an integer of 10 to 10,000, more preferably 20 to 6,000.

Specific examples of the aromatic hydrocarbon group in A10 to A13 of the above formula (11) include benzene, fluorene, naphthalene, anthracene or derivatives thereof, phenylenevinylene derivatives, styryl derivatives and the like. Specific examples of the heterocyclic group include thiophene, pyridine, pyrrole, carbazole or derivatives thereof.

Where A10 to A13 of the formula (11) have a substituent group, such substituent groups include, for example, a linear or branched alkyl group or alkenyl group having 1 to 12 carbon atoms. Specific examples preferably include a methyl group, an ethyl group, a propyl group, an isopropyl group, a butyl group, an isobutyl group, a sec-butyl group, a tert-butyl group, a pentyl group, a hexyl group, a heptyl group, an octyl group, a nonyl group, a decyl group, an undecyl group, a dodecyl group, a vinyl group, an allyl group and the like.

Specific examples of the compound represented by the formula (11) preferably include those compounds represented by the following formulas (11-1) to (11-3), i.e. poly[(9,9-dioctylfluorenyl-2,7-diyl)-co-(4,4′-(N-(4-sec-butylphenyl))diphenylamine)] (TFB, formula (11-1)), poly[(9,9-dioctylfluorenyl-2,7-diyl)-alt-co-(N,N′-bis{4-butylphenyl}-benzidine-N,N′-{1,4-diphenylene})] (formula (11-2)), and poly[(9,9-dioctylfluorenyl-2,7-diyl) (PFO, formula (11-3)) although not limited thereto.

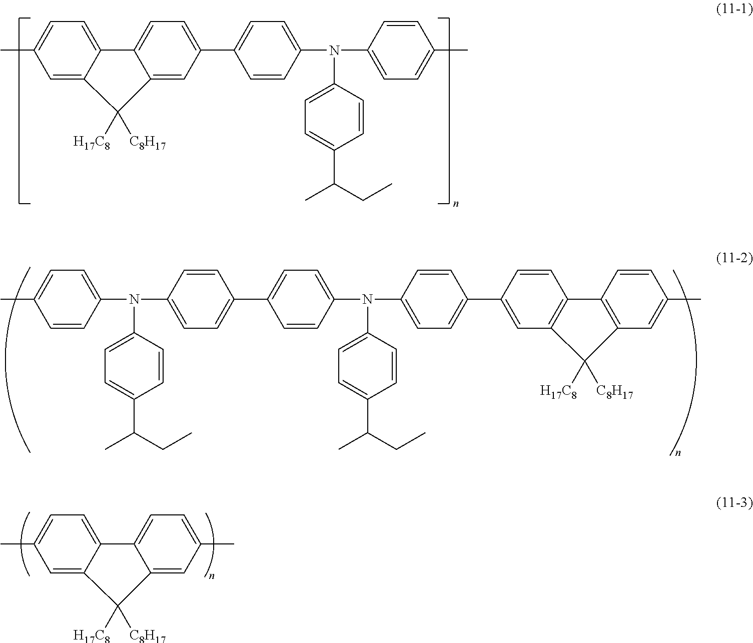

The blue light-emitting layer 16CB is one wherein when an electric filed is applied thereto, the re-combination of electrons and holes occurs, thereby generating light and the entire surface of which is covered by the electron transport layer 16D. The blue light-emitting layer 16CB is formed of a host material of an anthracene compound doped with a guest material of a blue or green fluorescent dye, and generates blue or green light.

The host material used in the blue light-emitting layer 16CB is preferably a compound represented by the formula (12),

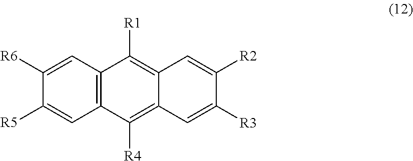

wherein R1 and R6 independently represent a hydrogen atom, a halogen atom, a hydroxyl group, or a group having an alkyl group, alkenyl group or carbonyl group having not larger than 20 carbon atoms, a group having a carbonyl ester group, a group having an alkoxyl group, a group having a cyano group, a group having a nitro group or derivatives thereof, or a group having a silyl group having not larger than 30 carbon atoms, a group having an aryl group, a group having a heterocyclic group, a group having an amino group or derivatives thereof.

The group having an aryl group and represented as R1 to R6 in the compound represented by the formula (12) includes, for example, a phenyl group, a 1-naphthyl group, a 2-naphthyl group, a fluorenyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 1-glycenyl group, a 6-glycenyl group, a 2-fluoranthenyl group, a 3-fluoranthenyl, a 2-biphenylyl group, a 3-biphenylyl group, a 4-biphenylyl group, an o-tolyl group, an m-tolyl group, a p-tolyl group, a p-t-butylphenyl group and the like.

The group having a heterocyclic group and represented by R1 to R6 includes a five-membered or six-membered aromatic ring group containing, as a heteroatom, oxygen atom (O), nitrogen atom (N) or sulfur atom (S), for which mention is made of a condensed polycyclic aromatic ring group having 2 to 20 carbon atoms. Such heterocyclic rings include, for example, a thienyl group, a furyl group, a pyrrolyl group, a pyridyl group, a quinolyl group, a quinoxalyl group, an imidazopyridyl group, and a benzothiazole group. Typical examples include a 1-pyrrolyl group, a 2-pyrrolyl group, a 3-pyrrolyl group, a pyradinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acrydinyl group, a 2-acrydinyl group, a 3-acrydinyl group, a 4-acrydinyl group, a 9-acrydinyl group and the like. The group having an amino group, represented by R1 to R6, may be any of an alkylamino group, an arylamino group, and an aralkylamino group. These preferably have an aliphatic hydrocarbon group having one to six carbon atoms and/or one to four aromatic ring groups. Such a group includes a dimethylamino group, a diethylamino group, a dibutylamine group, a diphenylamino group, a ditolylamino group, a bisbiphenylamino group or a dinaphthylamino group. It will be noted that the above substituent group may form a condensed ring made of two or more substituent groups, and a derivative thereof may also be used.

Specific examples of the compound represented by the formula (12) include those compounds such as of the following formulas (12-1) to (12-51).

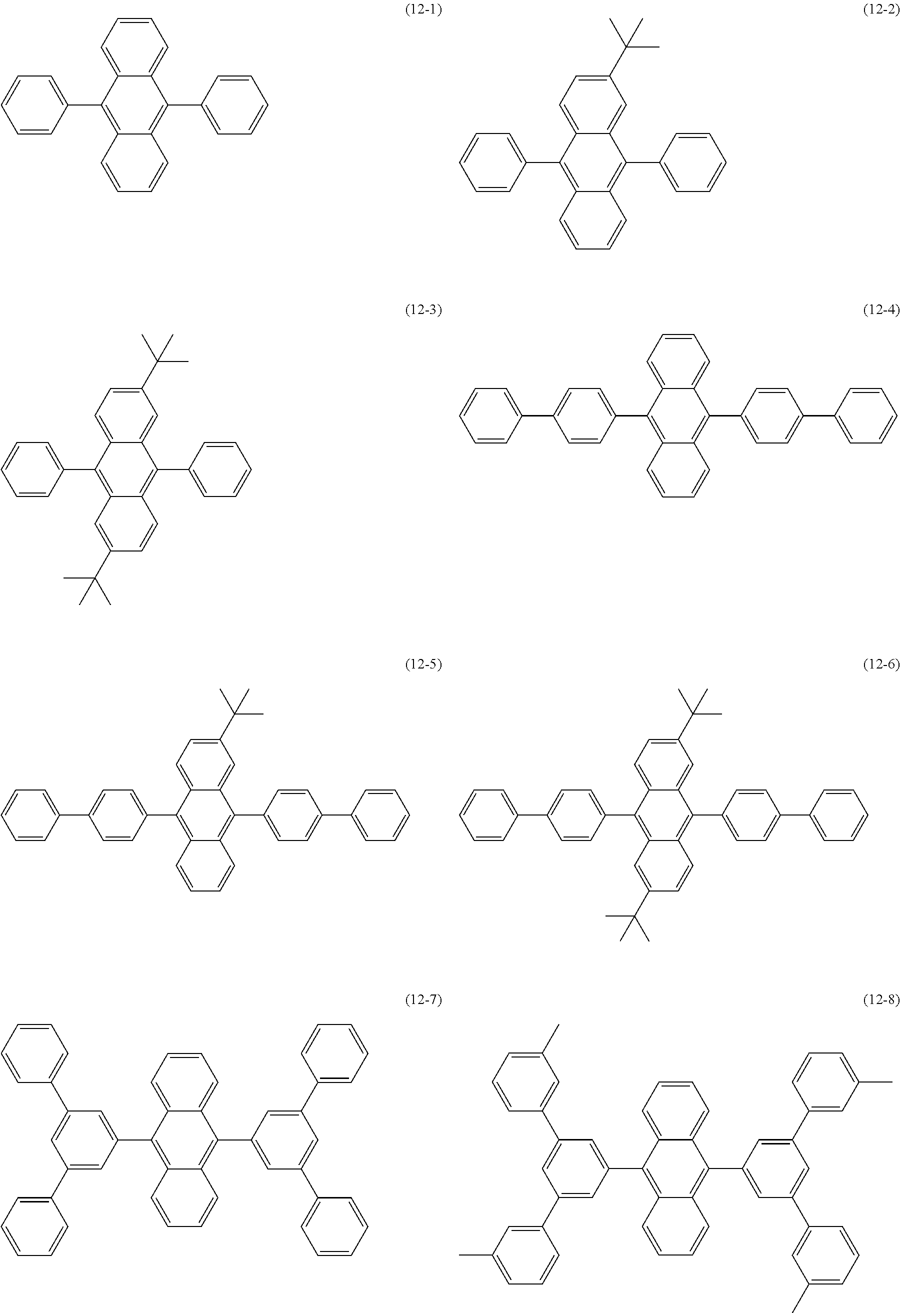

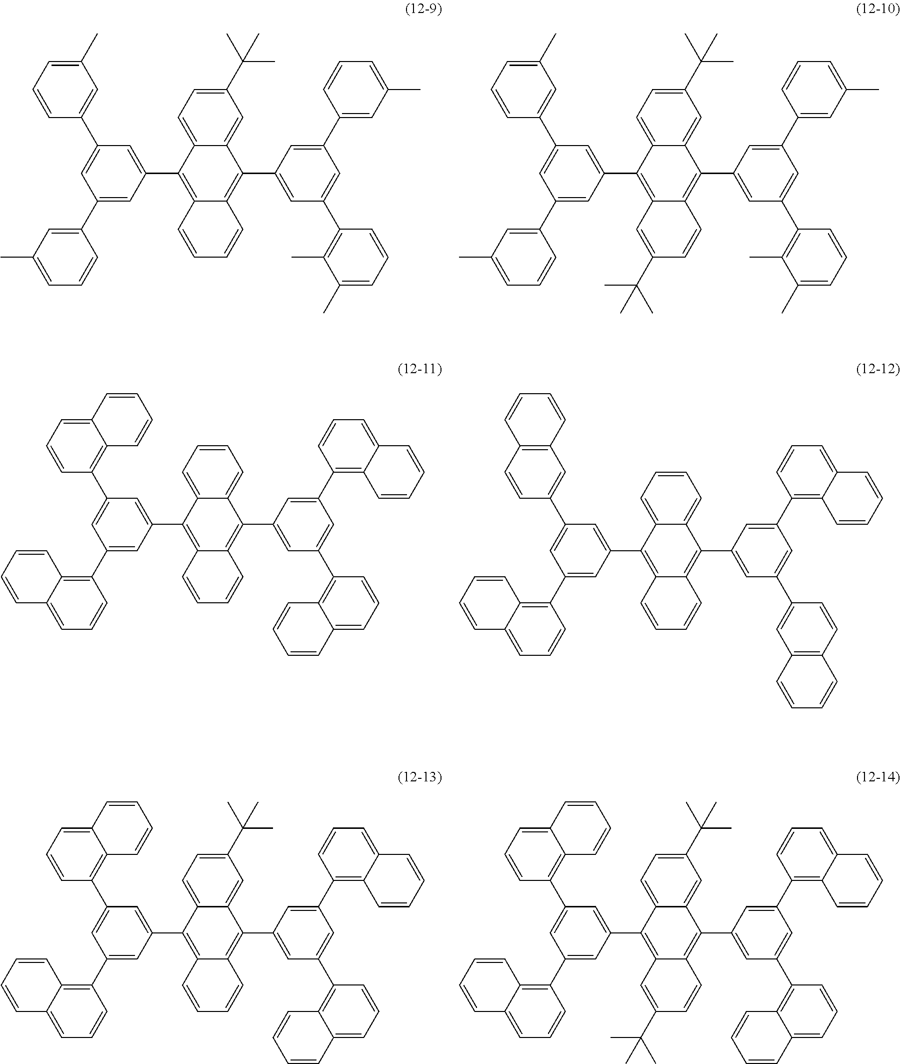

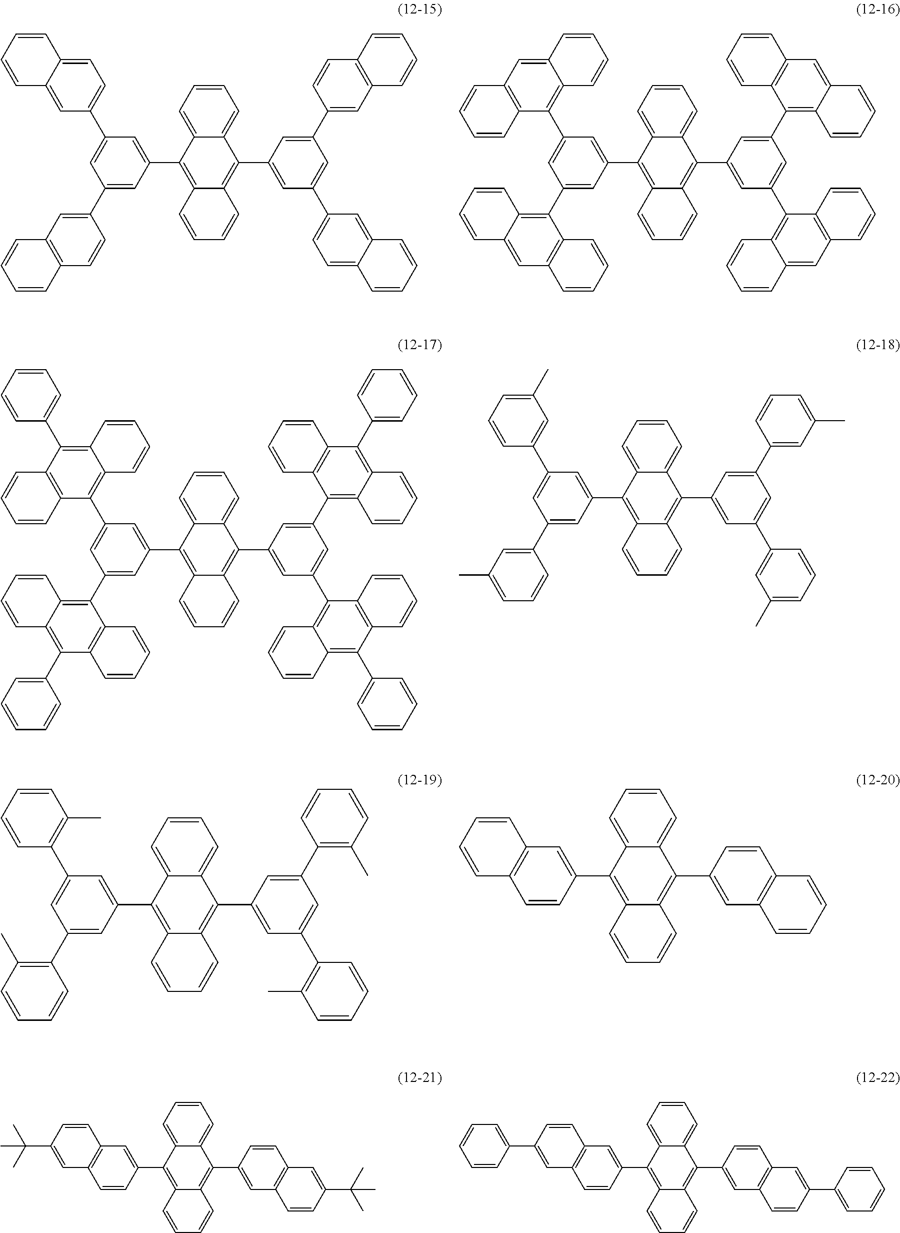

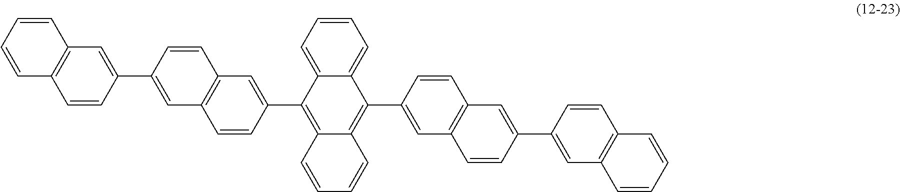

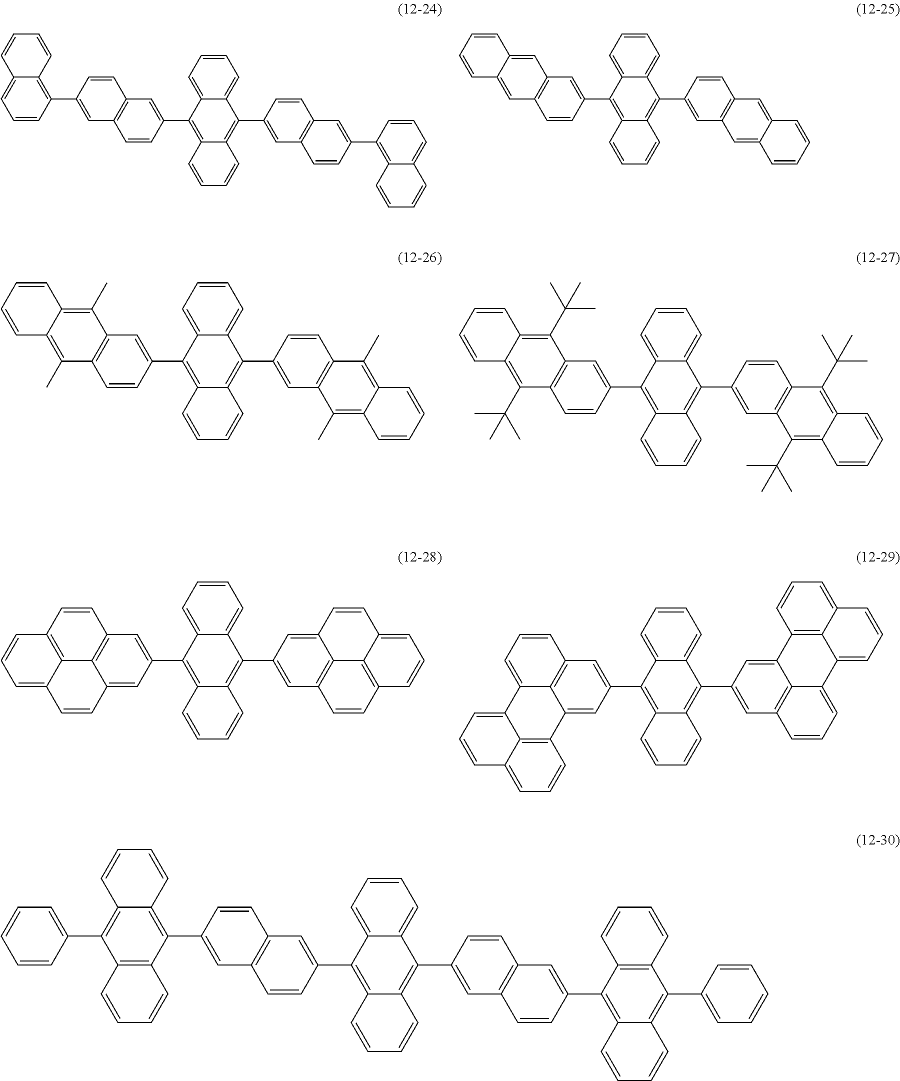

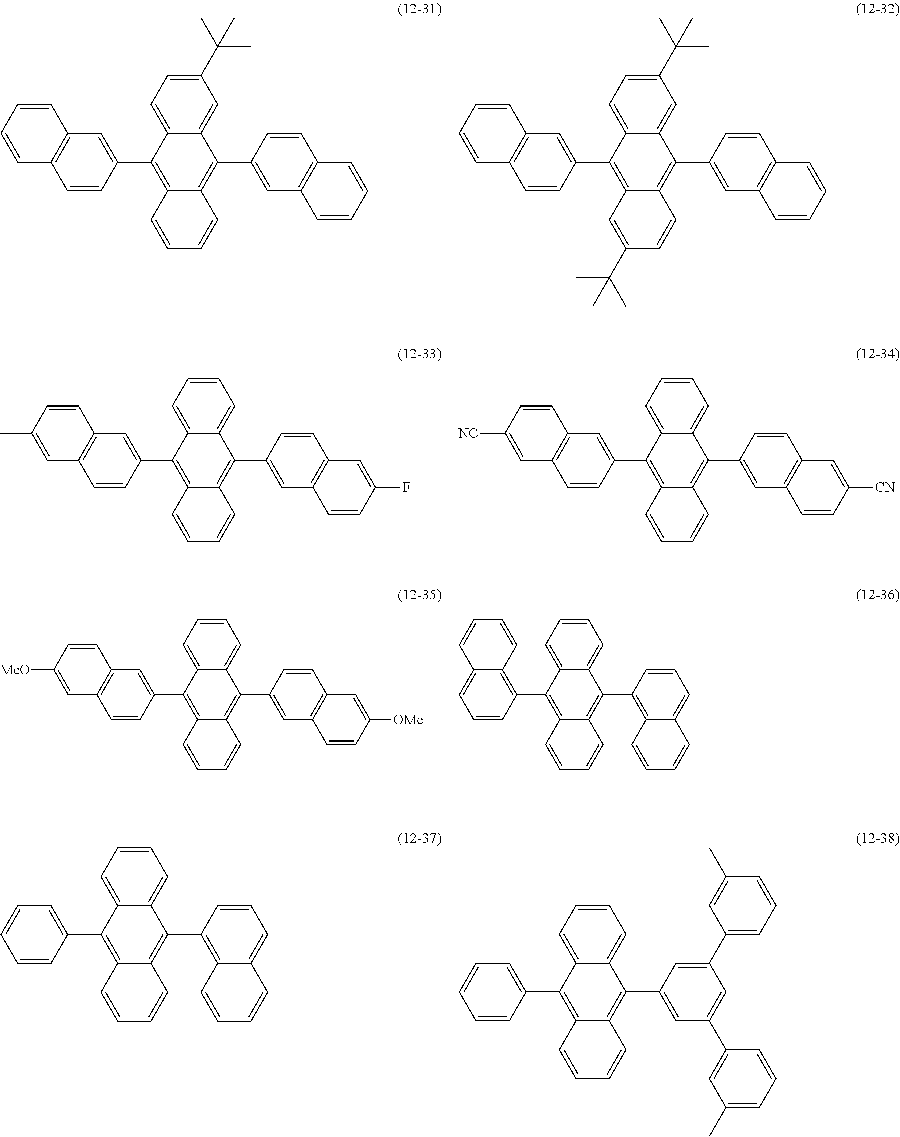

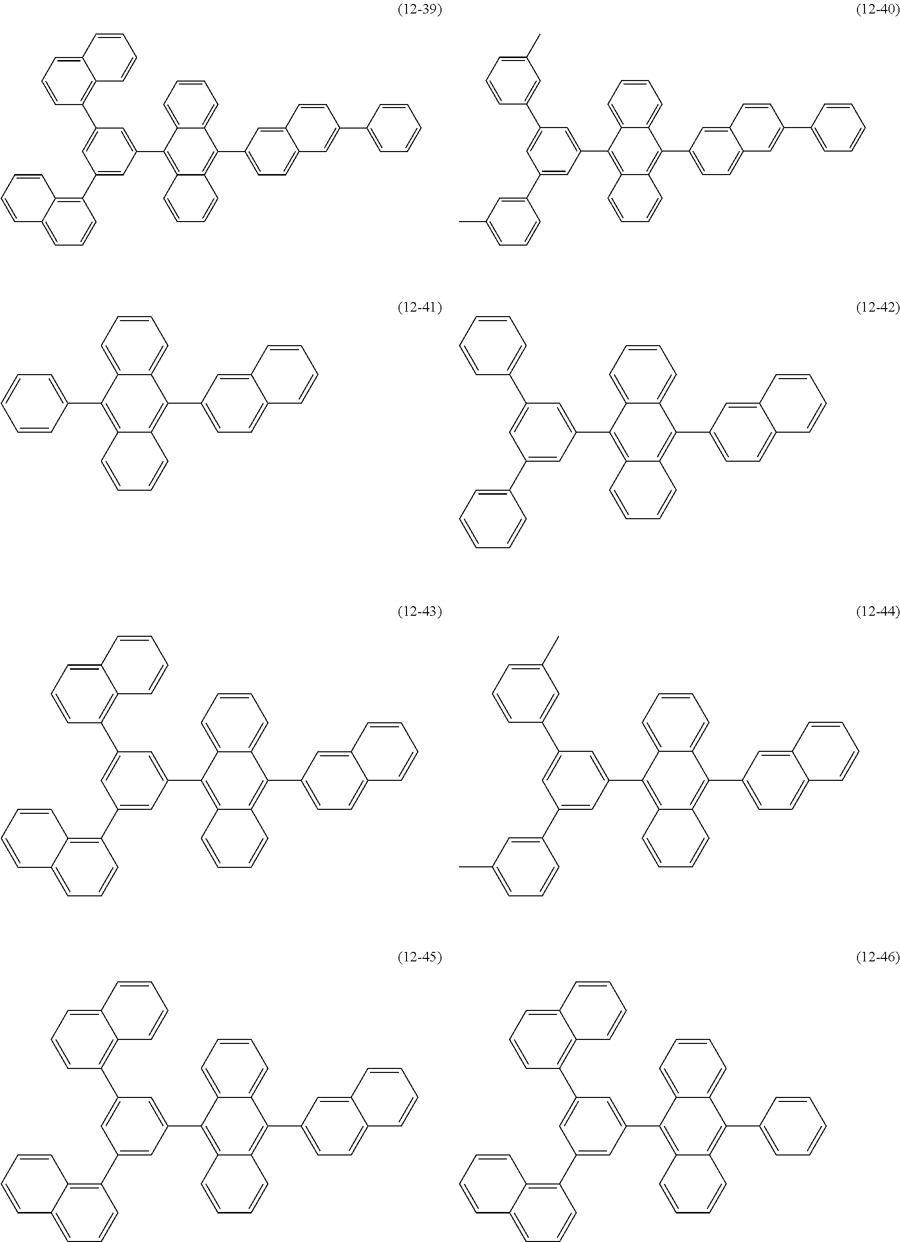

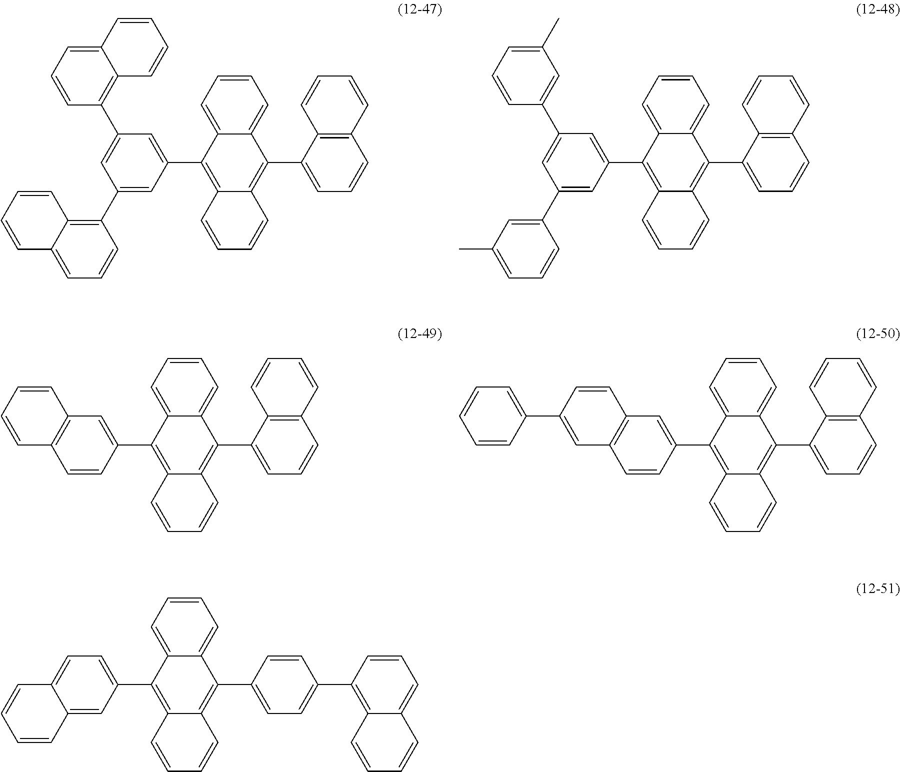

On the other hand, the luminescent guest materials for the blue light-emitting layer 16CB are materials of high emission efficiency, e.g. organic luminescent materials such as low molecular weight fluorescent materials, phosphorescent dyes and metal complexes.

The blue luminescent guest materials mean compounds whose emission wavelength has a peak within a range of about 400 nm to 490 nm. Such compounds include organic substances such as naphthalene derivatives, anthracene derivatives, naphthacene derivatives, styrylamine derivatives, bis(azinyl)methene boron complexes and the like. Of these, it is preferred to select from aminonaphthalene derivatives, aminoanthracene derivatives, aminochrysene derivatives, aminopyrene derivatives, styrylamine derivatives, and bis(azinyl)methene boron complexes.

The electron transport layer 16D is one that enhances an electron transport efficiency to the red light-emitting layer 16CR, green light-emitting layer 16CG and blue light-emitting layer 16CB and is formed, as a common layer, over the entire surface of the blue light-emitting layer 16CB. Although depending on the entire configuration of element, the thickness of the electron transport layer 16D is preferably, for example, at 5 nm to 300 nm, preferably at 10 nm to 200 nm.

As a material for the electron transport layer 16D, there is preferably used an organic material having excellent electron transportability. When a transport efficiency of electrons to the light-emitting layer 16C, particularly, the red light-emitting layer 16CR and green light-emitting layer 16CG, is increased, a change of emission color in the red organic EL element 10R and green organic EL element 10G ascribed to an intensity of electric filed is suppressed as will be described hereinafter. As such an organic material, there can be used nitrogen-containing heterocyclic derivatives having an electron mobility of from 10⁻⁶ cm²/Vs to 1.0×10⁻¹ cm²/Vs

Specifically, mention is made of those compounds of the foregoing formulas (6) to (8) including benzoimidazole derivatives (formula (6)), pyridylphenyl derivatives (formula (7)), and bipyridine derivatives (formula (8)). More specifically, mention is made of the compounds of the foregoing formulas (6-1) to (6-43), (7-1) to (7-81) and (8-1) to (8-17) although not limited thereto.

It should be noted that the organic material used for the electron transport layer 16D is preferably a compound having an anthracene skeleton, like above-indicated compounds, but not limited thereto. For example, instead of the anthracene skeleton, there may be used benzoimidazole derivatives, pyridylphenyl derivatives and bipyridyl derivatives having a pyrene structure or chrysene structure. The organic materials used for the electron transport layer 16D may be used not only singly, but also in combination of a plurality thereof or in the form of plural layers. Moreover, the above compounds may be used as an electron injection layer 16E as will be described hereinafter.

The electron injection layer 16E is one that enhances an electron injection efficiency and is formed, as a common layer, over the entire surface of the electron transport layer 16D. The material for the electron injection layer 16E includes, for example, lithium oxide (LiO₂), which is an oxide of lithium (Li), cesium carbonate (Cs₂CO₃), which is a composite oxide of cesium (Cs), or a mixture of these oxide and composite oxide. Alternatively, the electron injection layer 16E may not be limited to such materials as indicated above, but can be formed, for example, of an alkaline earth metal such as calcium (Ca), barium (Ba) or the like, an alkali metal such as lithium, cesium or the like, a metal having a small work function, such as indium (In), magnesium (Mg) or the like, or oxides, composite oxides or fluorides of these metals, which are used singly, or in admixture of or in the form of alloys of such metals, oxides, composite oxides and fluorides so as to enhance stability. Moreover, organic materials represented by the formulas (6) to (8) may also be used for the electron transport layer 16D.

Individual layers constituting the organic layer 16 have been described, and the total thickness of the organic layer 16 is preferably in the range of 150 nm to 500 nm. The thickness of the common layer of the organic layer 16 (including the blue light-emitting layer 16CB, electron transport layer 16D and electron injection layer 16E) formed commonly over the entire surface of the red organic EL element 10R, green organic EL element 10G and blue organic EL element 10B is preferably in the range of from 100 nm to 250 nm. Additionally, the thickness (Dw) of the individual layer and the thickness (De) of the common layer should preferably satisfy the relation expressed by the following mathematical formula (1).

Dw>De×0.1 (1)

If the thickness of the organic layer 16 is less than 150 nm, there is an increasing probability of local short circuit breakage of the organic layer 16 ascribed to the lowering of insulation durability caused by defectives, thereby lowering the reliability of the organic EL element. No specific upper limit is defined with respect to the thickness of the organic layer 16. Nevertheless, if the thickness exceeds, for example, 500 nm, a drive voltage necessary for subjecting the organic EL elements to light emission increases and thus, the lowering of luminescent efficiency and life are promoted, thus being not suited for practical application. In view of the above, it is preferable that the thickness of the organic layer 16 is within a range of 150 nm to 500 nm.

Emission lights h generated at the respective light-emitting layers 16C (16CR, 16CG, and 16CB) should have emission intensities in the red, green and blue wavelength regions. It is preferred that the organic layer 16 has a maximum emission intensity in all the red, green and blue wavelength regions intended to be taken out and that an emission intensity in unnecessary wavelength regions is small. When using such an organic layer 16, there can be obtained an organic EL display device 1 that has a high light taking-out efficiency in necessary emission regions and also has a high color purity. It is important that the thickness of the organic layer 16 be so set in exact detail as to establish, between the lower electrode 14 and the upper electrode 17, a resonator unit resonating an intended wavelength.

In the respective organic EL element 10 (10R, 10G, and 10B), optical path length L of the resonator unit between the lower electrode 14 and the upper electrode 17 is set at such a value that light in a desired wavelength region set for the respective organic EL element 10 (10R, 10G, and 10B) is resonated at opposite ends of the resonator unit for each element. Accordingly, where a phase shift, which is caused upon reflection of emission light h generated in the light-emitting layer 16C at the opposite ends of the resonator unit, is taken as Φ radian, an optical path length of the resonator unit taken as L, and a peak wavelength of a spectrum of light intended to be taken out among reflected lights h generated in the emission layer taken as λ, the optical path length L of the resonator unit has to be configured within a range satisfying the following mathematical formula (2). In this case, in order to maximize a light taking-out efficiency, m in the formula (2) is a positive integer, so that it is necessary that L be so set as to satisfy this m.

(2L)/λ+Φ/(2π)=m (2)

wherein Φ=phase shift caused upon reflection of emission light h, L=optical path length of the resonator unit, and m=positive integer.

In order to prevent short-circuiting between the upper electrode 17 and the lower electrode 14, the organic layer 16 should be formed as thick, for which the optical path length L should be made large. To this end, m is increased to make a large optical path length L. Accordingly, m is set at not less than 1 so that the optical path length L of the organic layer 16 is increased. In this regard, however, since the red, green and blue wavelengths differ from one another, resulting in different optical path lengths L. Although the optical path lengths differ, corresponding values of m have to be equal to one another. When m for red is taken as m_{R}, m for green taken as m_{G} and m for blue taken as m_{B}, the respective optical path lengths L are so set as to allow m_{R}=m_{G}=m_{B}. When the lower electrode 14 and upper electrode 17 are fixed and the wavelengths to be taken out (e.g. red λ=630 nm, green λ=530 nm and blue λ=460 nm) are fixed by means of the respective organic EL elements 10R, 10G, and 10B, m in the mathematical formula (2) is regulated by the optical path length L.

The organic EL display device 1 of the embodiment of this disclosure is constituted of a plurality of organic EL elements 10R, 10G, and 10B wherein the organic layer 16 of these organic EL elements 10R, 10G, and 10B is formed by a coating method and a vacuum deposition method. As described hereinbefore, the coating method includes dissolving a film-forming material in a solvent, coating on a base material (i.e. substrate 11 herein) and subjected to heat treatment to remove the solvent. Hence, exact control of the film thickness is difficult, thereby permitting a difference in film thickness among the respective organic EL elements. In contrast thereto, in the vacuum deposition method, a film-forming material is evaporated to deposit on a surface of a base material, so that control of the film thickness is easy and a difference in film thickness is unlikely to occur in the respective organic EL elements.

With the organic EL display device, in order to obtain an intended wavelength in the resonator unit, i.e. in the organic layer 16, the film thickness has to be exactly set as set out hereinabove. However, film formation of a high molecular weight material by a vacuum deposition method is difficult, and it is necessary to form, by a coating method, the hole injection layer 16A (16AR, 16AG, and 16AB), hole transport layer 16B (16BR, 16BG, and 16BB), and red light-emitting layer 16CR and green light-emitting layer 16CG. In this regard, however, a difficulty is involved in controlling the thickness of the layers (individual layers) formed by a coating method for the reason set out above. In this embodiment, a variation in thickness of the respective organic EL elements is suppressed by decreasing the thicknesses of individual layers and increasing a ratio of the layer formed by a vacuum deposition method (i.e. common layer). More particularly, the device is so set as to take out the respective color emission lights in an optically efficient manner and the thickness of the common layer is not less than 50% relative to the total thickness of the organic layer 16, thereby enabling uniform light emission in the display region.

It will be noted that a minimum thickness sufficient for the respective hole injection layers 16A (16AR, 16AG, and 16AB), the respective hole transport layers (16BR, 16BG, and 16BB) and the red light-emitting layer 16CR and green light-emitting layer 16CG to be properly functioned is preferably at not less than 30 nm. From the foregoing, the total thickness of the organic layer 16 is preferably within a range of 150 nm to 500 nm wherein the thickness (De) of the common layer formed by a vacuum deposition method should preferably be greater than the thickness (Dw) of the individual layers formed by a coating method. The relation between the individual layers and the common layer is preferably so controlled as to satisfy the afore-indicated mathematical formula (1).

The upper electrode 17 has a thickness, for example, of 2 nm to 15 nm and is formed of a metal conductive film. More particularly, where the upper electrode 17 is used as an anode, there are mentioned Ni, Ag, Au, Pt, palladium (Pd), selenium (Se), rhodium (Rh), ruthenium (Ru), iridium (Ir), rhenium (Re), W, molybdenum (Mo), Cr, tantalum (Ta), niobium (Nb) and alloys thereof, and conductive materials having a great work function such as SnOx, ITO, ZnOx, TiO and the like. Where the upper electrode 17 is used as a cathode, there are mentioned conductive materials having a small work function and including alloys of active metals such as lithium (Li), Mg, calcium (Ca) and the like and metals of Ag, Al, indium (In) and the like. This electrode may have a structure wherein the above metal and conductive material are laminated. In addition, a compound layer made, for example, of an active metal such as Li, Mg, Ca or the like and a halogen atom such as fluorine (F), bromine (Br) or the like or oxygen may be inserted between the upper electrode 17 and the electron injection layer 16E.

Further, the upper electrode 17 may be in the form of a mixed layer containing organic light-emitting materials such as an aluminum quinoline complex, a styrylamine derivative, a phthalocyanine derivative and the like. In this case, another layer having light permeability, such as MgAg, may be separately formed as a third layer. It will be noted that with an active matrix drive system, the upper electrode 17 is formed all over the substrate 11 in a state of being insulated with the lower electrode 14 by means of the organic layer 16 and the partition wall 15, and is used as a common electrode for the red organic EL element 10R, green organic EL element 10G and blue organic EL element 10B. It is to be noted that with a top emission type, the upper electrode 17 is at a side from which light generated in the organic layer 16 is taken out, so that its light permeability is controlled by a thickness thereof. The reflectance of the upper electrode 17 is preferably in the range of from 0.1% to less than 50%. In doing so, a resonance intensity of a micro-resonator structure is set under proper conditions, color selectivity and intensity of the light taken out from the front face of the display device become larger, and the dependence of brightness and chromaticity on view angle can be kept low.

The protective layer 30 has a thickness, for example, of 2 to 3 μm and may be formed of either an insulating material or a conductive material. Preferable insulating materials include inorganic amorphous insulating materials such as, for example, amorphous silicon (α-Si), amorphous silicon carbide (α-SiC), amorphous silicon nitride (α-Si₁₋ₓNₓ) and amorphous carbon (α-C). Such an inorganic amorphous insulating material does not form grains, resulting in a good protective film with low moisture permeability.

A sealing substrate 40 is positioned at a side of the upper electrode 17 of the red organic EL element 10R, green organic EL element 10G and blue organic EL element 10B and seals the red organic EL element 10R, green organic EL element 10G and blue organic EL element 10B along with an adhesive layer (not shown). The sealing substrate 40 is constituted of a material, such as glass, which is transparent against light generated at the red organic EL element 10R, green organic EL element 10G and blue organic EL element 10B. The sealing substrate 40 is provided, for example, with light-shielding films serving as a color filer and a black matrix (both not shown), through which lights generated by the red organic EL element 10R, green organic EL element 10G and blue organic EL element 10B are taken out and which absorb outside light reflected at the red organic EL element 10R, green organic EL element 10G and blue organic EL element 10B and related wirings, thereby improving contrast.

The color filter has a red filter, a green filter and a blue filter (all not shown), which are arranged correspondingly to the red organic EL element 10R, green organic EL element 10G and blue organic EL element 10B. The red filter, green filter and blue filter are tightly formed, for example, in a rectangular shape. These red filter, green filter and blue filter are, correspondingly, formed of a resin incorporated with a pigment therein, and proper selection of pigment ensures such a control that light permeability in an intended red, green or blue wavelength region becomes high and light permeability in other wavelength regions becomes low.

Further, a wavelength range of high permeability in the color filter and a peak wavelength λ of a spectrum of light taken out from the resonator structure are coincident with each other. This permits only light, which has a wavelength equal to the peak wavelength λ of a spectrum of light to be taken out, to be passed through the color filter among outside lights incident from the sealing substrate 40 and also permits outside lights of other wavelengths to be prevented from breaking into the respective color organic EL elements 10R, 10G, and 10B.

The light-shielding film is formed of a black resin film, which is incorporated, for example, with a black colorant and has an optical density of not smaller than 1, or a thin film filter making use of the interference of thin film. The use of the black resin film is preferred because of the inexpensive, easy formation. The thin film filter is, for example, a lamination of one or more of thin films made of a metal, a metal nitride or a metal oxide, and light is attenuated by utilizing the interference of thin film. As a thin film, mention is made of an alternate laminate of Cr and chromium (III) oxide (Cr₂O₃).

This organic EL display device 1 can be manufactured, for example, in the following way.

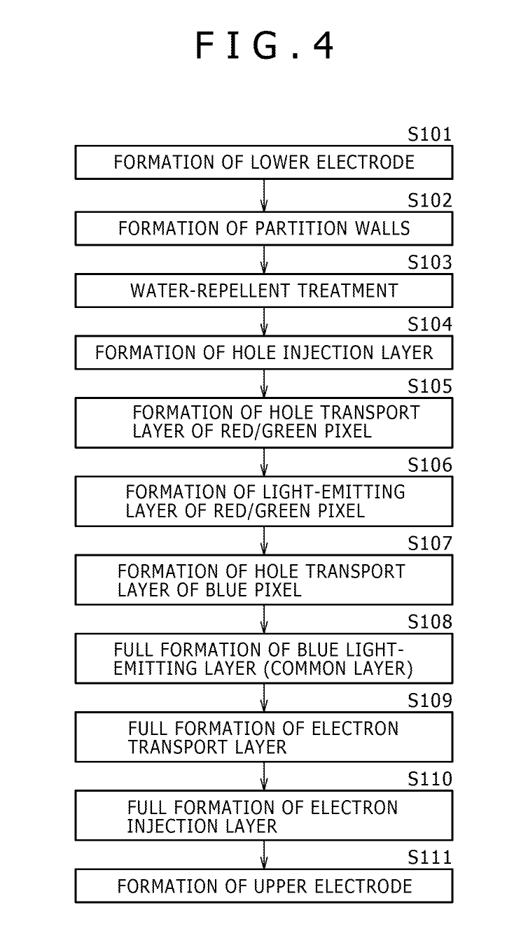

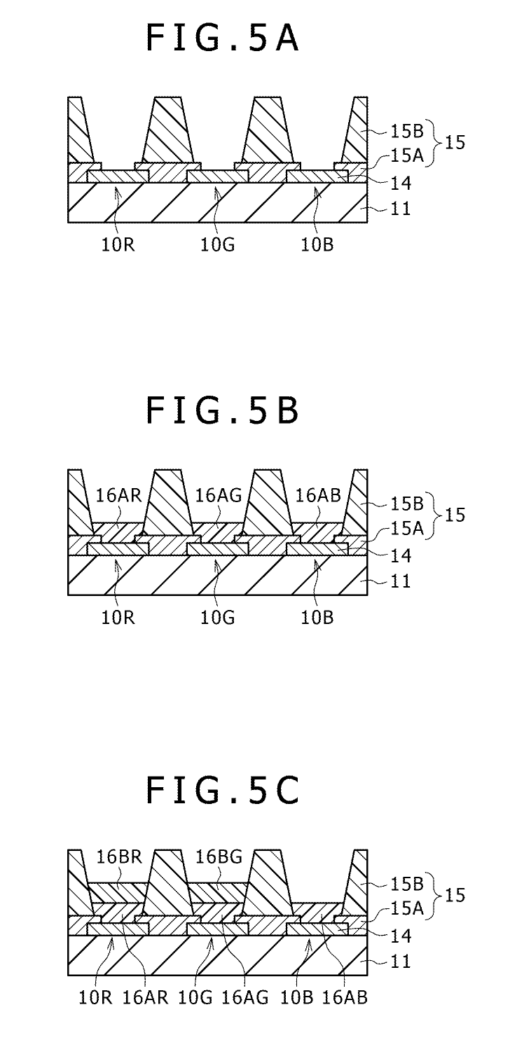

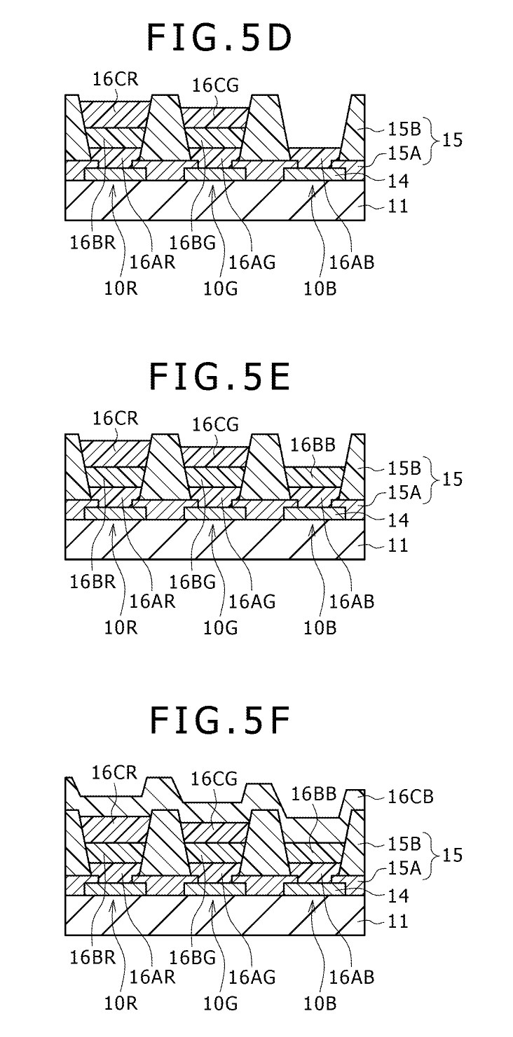

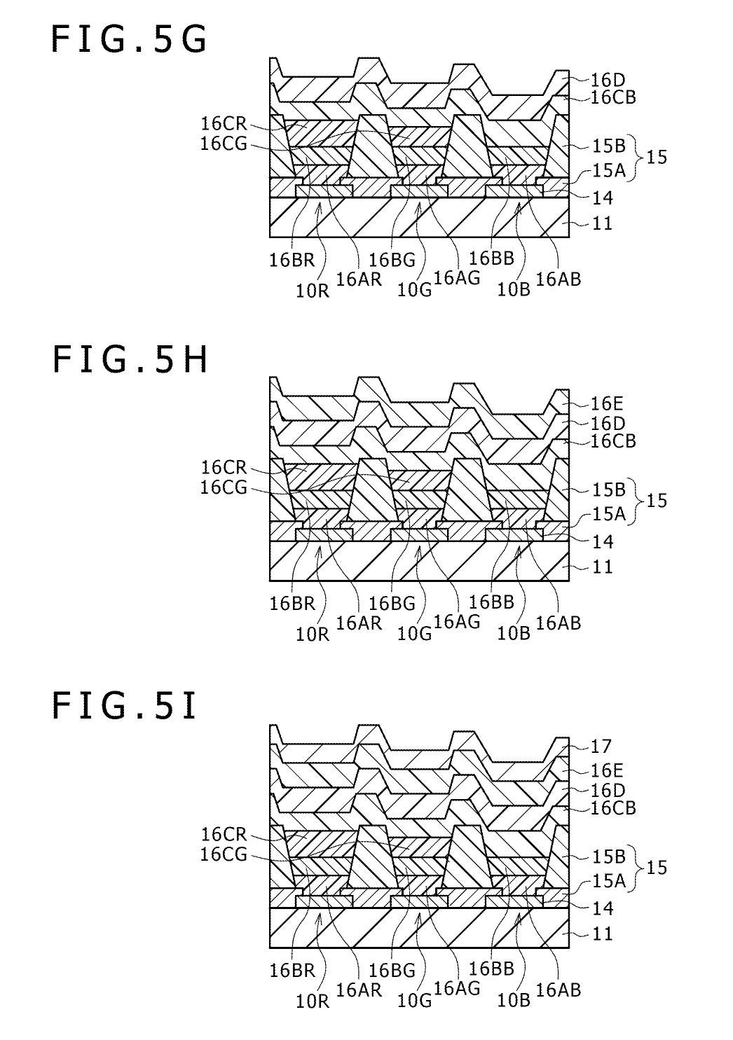

FIG. 4 shows a flowchart of a method of manufacturing an organic EL display device 1, and FIGS. 5A to 5I, correspondingly, show sequential steps of the manufacturing method shown in FIG. 4. Initially, a pixel drive circuit 140 including a drive transistor Tr1 is formed on a substrate 11 made of such a material as set out before, and a flattening insulating film (not shown) made, for example, of a photosensitive resin is formed.

### (Step of Forming Lower Electrode 14)

Next, a transparent conductive film made, for example, of ITO is formed over the whole surface of the substrate 11, followed by patterning of the transparent conductive film to form a lower electrode 14 for each of a red organic EL element 10R, a green organic EL element 10G and a blue organic EL element 10B as shown in FIG. 5A (step S101). On this occasion, the lower electrode 14 is electrically connected to a drain electrode of the drive transistor Tr1 via a contact hole (not shown) of the flattening insulating film (not shown).

### (Step of Forming Partition Wall 15)

Subsequently, as shown in FIG. 5A, an inorganic insulating material such as SiO₂ is formed over the lower electrode 14 and the flattening insulating film (not shown), for example, by a CVD (chemical vapor deposition) method, followed by patterning according to a photolithographic technique and an etching technique, thereby forming a lower partition wall 15A.

Thereafter, also as shown in FIG. 5A, an upper partition wall 15B made of such a photosensitive resin as indicated before is formed in position on the lower partition wall 15A, particularly, at a position surrounding an emission region of pixel. In doing so, a partition wall 16 made of the upper partition wall 15A and the lower partition wall 15B is formed (Step S102).

After the formation of the partition wall 15, the surface of the substrate 11 at the side of forming the lower electrode 14 and the partition wall 15 is subjected to oxygen plasma treatment, thereby removing pollutants such as of organic matter deposited on the surface to improve wettability. More particularly, the substrate 11 is heated to a given temperature, for example, of about 70° C. to 80° C., followed by subjecting to plasma treatment (O₂ plasma treatment) using oxygen as a reactant gas under an atmospheric pressure.

### (Step of Carrying Out Water-Repellent Treatment)

After completion of the plasma treatment, water-repellent treatment (liquid repellent treatment) is carried out (step S103), with the result that the upper partition wall 15B is lowered in wettability at the upper and side faces thereof. More particularly, plasma treatment using tetrafluoromethane as a reactant gas (CF₄ plasma treatment) is carried out at an atmospheric pressure and the substrate 11, heated for the plasma treatment, is cooled down to room temperature. Eventually, the upper partition wall 15B becomes liquid-repellent at the upper and side faces thereof, thereby lowering wettability.

It will be noted that in the CF₄ plasma treatment, the exposed faces of the lower electrode 14 and the lower partition wall 15A are subject to some influence. Nevertheless, ITO used as a material for the lower electrode 14 and SiO₂ used as a constituent material of the lower partition wall 15A exhibit poor affinity for fluorine and thus, the faces whose wettability is improved by the oxygen plasma treatment have wettability that is kept as it is.

### (Step of Forming Hole Injection Layers 16AR, 16AG, and 16AB)

After completion of the water-repellent treatment, as shown in FIG. 5B, the hole injection layers 16AR, 16AG, and 16AB made of materials set out hereinbefore are formed within a region surrounded by the upper partition walls 15B, correspondingly, (step S104). The hole injection layers 16AR, 16AG, and 16AB are formed by a coating method such as a spin coating method or a droplet discharge method. Especially, since it is necessary to selectively provide materials for forming the hole injection layers 16AR, 16AG, and 16AB on the regions surrounded by the upper partition walls 15B, the use of an inkjet method or nozzle coating method within a category of the droplet discharge method is preferred.

More particularly, according to an inkjet method, for example, a solution or dispersion such as of polyaniline or polythiophene used as a material for forming the hole injection layers 16AR, 16AG, and 16AB is applied onto an exposed surface of the lower electrode 14. Thereafter, thermal treatment (drying treatment) is carried out to form the hole injection layers 16AR, 16AG, and 16AB.

In the thermal treatment, after drying the solvent or dispersion medium, the treatment is carried out by heating at high temperatures. Where a conductive polymer such as polyaniline or polythiophene is used, an air or oxygen atmosphere is preferred. This is because oxidation of the conductive polymer with oxygen allows easy development of conductivity.

The heating temperature is preferably at 150° C. to 300° C., more preferably at 180° C. to 250° C. Although depending on the temperature and the atmosphere, the time is preferably at about 5 minutes to 300 minutes, more preferably at 10 minutes to 240 minutes. The dry thickness is preferably at 5 nm to 100 nm, more preferably at 8 nm to 50 nm.

### (Step of Forming Hole Transport Layers 16BR and 16BG of Red Organic EL Element 10R and Green Organic EL Element 10G)

After the formation of the hole injection layers 16AR, 16AG, and 16AB, as shown in FIG. 5C, hole transport layers 16BR and 16BG, made of materials set out hereinbefore, are, respectively, formed on the hole injection layers 16AR and 16AG with respect to the red organic EL element 10R and green organic EL element 10G. The hole transport layers 16BR and 16BG are formed by a coating method such as a spin coating method or a droplet discharge method. Especially, since materials for forming the hole transport layers 16BR and 16BG should be selectively applied onto the regions surrounded by the upper partition walls 15B, it is preferred to use a droplet discharge method, particularly, an inkjet method or a nozzle coating method.

More particularly, according to an inkjet method, for example, a mixed solution or dispersion of a high molecular weight polymer and a low molecular weight material used to form the hole transport layers 16BR, 16BG is formed on the exposed surfaces of the hole injection layers 16AR and 16AG, respectively. Thereafter, thermal treatment (drying treatment) is carried out to form the hole transport layers 16BR and 16BG of the red organic EL element 10R and the green organic EL element 10G.

In the thermal treatment, the solvent or dispersion medium was dried, followed by heating at high temperatures. The coating atmosphere and the drying, heating atmosphere for solvent are preferably an atmosphere made mainly of nitrogen (N₂). If oxygen or moisture is present, there is concern that the luminescent efficiency and life of the resulting organic EL display device lower. Especially, the heating step is greatly influenced by oxygen or moisture, to which care should be paid. The oxygen concentration is preferably in the range of 0.1 ppm to 100 ppm, more preferably not larger than 50 ppm. If the content of oxygen exceeds 100 ppm, the formed thin film is polluted at the interface thereof, and thus, there is concern that the luminescent efficiency and life of the resulting organic EL display device lower. With an oxygen concentration of less than 0.1 ppm, there is no problem on element characteristics, but with the possibility that a great deal of costs of an apparatus for keeping the atmosphere at such a concentration of less than 0.1 ppm are incurred in view of existing mass-production processes.

As to moisture, the dew point is preferably at −80° C. to −40° C., more preferably at not higher than −50° C., and much more preferably at not higher than −60° C. If there is a moisture content sufficient to enable the dew point to be higher than −40° C., the formed thin film is polluted at the interface thereof, along with concern that the luminescent efficiency and life of the resulting organic EL display device lower. With a moisture content corresponding to a dew point of less than −80° C., there is no problem on element characteristics, but with the possibility that the a great deal of costs of an apparatus for keeping the atmosphere at such a concentration of less than −80° C. are incurred in view of existing mass-production processes.

The heating temperature is preferably at 100° C. to 230° C., more preferably at 100° C. to 200° C. This heating temperature is preferably at least lower than a temperature used to form the hole injection layers 16AR, 16AG, and 16AB. Although depending on the temperature and atmosphere, the time is preferably at about 5 minutes to 300 minutes, more preferably at 10 minutes to 240 minutes. The dry thickness may depend on the whole configuration of element and is preferably within a range of 10 nm to 200 nm, more preferably 15 nm to 150 nm.

### (Step of Forming Red Light-Emitting Layer 16CR and Green Light-Emitting Layer 16CG)

After the formation of the hole transport layers 16BR and 16BG of the red organic EL element 10R and green organic EL element 10G, as shown in FIG. 5D, a red light-emitting layer 16CR made of a mixed material of a high molecular weight material and a low molecular weight material as indicated hereinbefore is formed on the hole transport layer 16BR of the red organic EL element. Likewise, a green light-emitting layer 16CG made of a mixed material of a high molecular weight material and a low molecular weight material as indicated hereinbefore is formed on the hole transport layer 16BG of the green organic EL element (step S106). The red light-emitting layer 16CR and green light-emitting layer 16CG are both formed by a coating method such as a spin coating method or a droplet discharge method. Especially, since it is necessary to selectively provide materials for forming the red light-emitting layer 16CR and green light-emitting layer 16CG on the region surrounded by the upper partition walls 15B, the use of a droplet discharge method, particularly, an inkjet method or a nozzle coating method, is preferred.

More particularly, according to an inkjet method, for example, a mixed solution or dispersion, which is obtained by dissolving a high molecular weight material and a low molecular weight material used to form the red light-emitting layer 16CR or the green light-emitting layer 16CG in a mixed solvent of xylene and cyclohexylbenzene at 2:8 at a concentration, for example, of 1 wt %, is applied onto the exposed surface of the hole transport layer 16BR or 16BG. Thereafter, thermal treatment is carried out in the same manner and conditions as the thermal treatment (drying treatment) illustrated with respect to the step of forming the hole transport layers 16BR and 16BG of the red organic EL element 10R and green organic EL element 10G, thereby forming the red light-emitting layer 16CR and green light-emitting layer 16CG.

### (Step of Forming Hole Transport Layer 16BB of Blue Organic EL Element 10B)

After the formation of the red light-emitting layer 16CR and green light-emitting layer 16CG, as shown in FIG. 5E, a hole transport layer 16BB made of such a low molecular weight material as illustrated before is formed on the hole injection layer 16AB for the blue organic emission element 10B (step S107). The hole transport layer 16BB is formed by a coating method such as a spin coating method or a droplet discharge method. Especially, since it is necessary to selectively provide the material for forming the hole transport layer 16BB on the region surrounded by the upper partition walls 15B, the use of a droplet discharge method, particularly, an inkjet method or a nozzle coating method, is preferred.

More particularly, according to an inkjet method, for example, a mixed solution or dispersion of a low molecular weight material for the hole transport layer 16BB is applied onto the exposed surface of the hole injection layer 16AB. Thereafter, thermal treatment is carried out in the same manner and conditions as the thermal treatment (drying treatment) illustrated with respect to the step of forming the hole transport layers 16BR and 16BG of the red organic EL element 10R and green organic EL element 10G, thereby forming the hole transport layer 16BB.

### (Step Sequences)

The step of forming the hole transport layers 16BR and 16BG of the red organic EL element 10R and green organic EL element 10G, the step of forming the hole transport layer 16BB of the blue organic EL element 10B and the step of forming the red light-emitting layer 16CR and green light-emitting layer 16CG may be carried out in any arbitrary order, but at least an underlying layer on which layers to be formed are developed should be formed beforehand and subjected to a heating step out of the heating and drying steps. Coating should be carried out in such a way that the temperature of the heating step is at least equal to or lower than in a previous step. For instance, in case where the heating temperatures for the red light-emitting layer 16CR and green light-emitting layer 16CG are at the same level of 130° C. and the heating temperature for the hole transport layer 16BB of the blue organic EL element 10B is also at the same level of 130° C., coating for the red light-emitting layer 16CR and green light-emitting layer 16CG may be carried out, followed by subsequent coating, without drying, for the hole transport layer 16BB for the blue organic EL element and subjecting the red light-emitting layer 16CR, green light-emitting layer 16CG and hole transport layer 16BB for the blue organic EL element 10B to drying and heating steps.

In the respective steps set out above, it is preferred to carry out drying and heating in separate steps. This is because a coated wet film is very likely to flow and is prone to cause film unevenness in the drying step. A preferred drying step is a uniform drying procedure at a normal pressure. Moreover, it is preferred to dry without applying wind during drying. In the heating step, fluidity lowers by evaporating the solvent to some extent and a cured film results. Thereafter, heat is gently applied whereupon it becomes possible to remove a very small amount of the solvent left and cause rearrangement of a light-emission material or a material for hole transport layer at the molecular level.

### (Step of Forming Blue Light-Emitting Layer 16CB)

After the formation of the red light-emitting layer 16CR, green light-emitting layer 16CG and blue hole transport layer 16BB, as shown in FIG. 5F, a blue light-emitting layer 16CB made of such a low molecular weight material as indicated before is formed, as a common layer, over the whole surface of the respective layers 16CR, 16CG, and 16BB according to a vacuum deposition method (step S108).

### (Step of Forming Electron Transport Layer 16D, Electron Injection Layer 16E and Upper Electrode 17)

After the formation of the blue light-emitting layer 16CB, as shown in FIGS. 5G, 5H and 5I, an electron transport layer 16D, electron injection layer 16E and upper electrode 17, which are made of such materials as indicated before, are formed on the whole surface of the blue light-emitting layer 16CB according to a vacuum deposition method (Steps S109, S110 and S111).

After the formation of the upper electrode 17, as shown in FIG. 3, a protective layer 30 is formed by a film-forming method wherein an energy of film-forming particles is small, e.g. a vacuum deposition method or a CVD method, in such a way that the underlying layer is not adversely influenced. Where the protective layer 30 is formed, for example, of amorphous silicon nitride, it is formed in a thickness of 2 to 3 μm by a CVD method. On this occasion, in order to prevent brightness from lowering owing to the degradation of the organic layer 16, it is preferred that the film-forming temperature is set at normal temperature and film formation is made under conditions of minimizing the stress of film so as to prevent the protective layer 30 from being peeled off.

The blue light-emitting layer 16CB, electron transport layer 16D, electron injection layer 16E, upper electrode 17 and protective layer 30 are formed all over the whole surface without use of a mask. The formation of the blue light-emitting layer 16CB, electron transport layer 16D, electron injection layer 16E, upper electrode 17 and protective layer 30 is continuously made in the same film-forming apparatus without exposure to air. This leads to preventing the degradation of the organic layer 16 ascribed to the moisture in air.

It will be noted that where an auxiliary electrode (not shown) is formed in the same step as the lower electrode 14, the organic layer 16 formed all over the upper portion of the auxiliary electrode may be removed by a laser abrasion technique or the like prior to the formation of the upper electrode 17. By this, the upper electrode 17 can be directly connected to the auxiliary electrode, thereby improving contactness.

After the formation of the protective layer 30, a light-shielding film made of such a material as indicated before is formed on a sealing substrate 40 made of the afore-indicated material. Subsequently, a material for red color filter (not shown) is coated on the sealing substrate 40 such as by spin coating, followed by patterning with a photolithographic technique and baking to form a red color filter. Subsequently, a blue color filter (not shown) and a green color filter (not shown) are successively formed in the same manner as the red color filter (not shown).

Thereafter, an adhesive layer (not shown) is formed on the protective layer 30, and the sealing substrate 40 is bonded via the adhesive layer. In this way, the organic EL display device 1 shown in FIGS. 1 to 3 is brought to completion.

In this organic EL display device 1, a scanning signal is supplied from a scanning line drive circuit 130 to each pixel via a gate electrode of the write transistor Tr2 and an image signal from a signal line drive circuit 120 is retained in a retention capacitor Cs via the write transistor Tr2. More particularly, a drive transistor Tr1 is subjected to on-off control depending on the signal retained in the retention capacitor Cs. This enables the red organic EL element 10R, green organic EL element 10G and blue organic EL element 10B to be applied with a drive current Id, whereupon electrons and holes are recombined together thereby emitting light. This light is taken out by passing through the lower electrode 14 and substrate 11 for bottom emission or by passing through the upper electrode 17, color filter (not shown) and sealing substrate 40 for top emission.

With hitherto employed organic EL elements, such a step of removing a solvent such as by heat treatment for solvent removal in coating methods as set out hereinbefore is needed, so that exact control of film thickness is difficult, thereby causing a variation in the film thickness. The variation in film thickness results in the lowering of luminescent efficiency and the change in emission spectra. Additionally, since a variation in film thickness occurs on an element-to-element basis, so that an organic EL display device making use of a plurality of organic EL elements involves uneven brightness and color.

In contrast, according to this embodiment, while the common layer including the blue light-emitting layer 16CB, electron transport layer 16D and electron injection layer 16E is formed by a vacuum deposition method that allows easy control of film thickness, an individual layer including the hole injection layers 16AR, 16AG, and 16AB and hole transport layers 16BR, 16BG, and 16BB for the respective color light emissions and the red light-emitting layer 16CR and green light-emitting layer 16CG are formed by coating methods. The thickness of the common layer is made larger than the thickness of the individual layer formed by coating, so that variations in thickness of the respective organic EL elements 10R, 10G, and 10B are reduced. In other words, the luminescent efficiency and the variation of chromaticity in a plurality of organic EL display elements of the organic EL display device 1 can be suppressed.

As set out above, since the organic EL display device 1 of this embodiment is so configured that the thickness of the common layer formed by the vacuum deposition method is larger than the thickness of the individual layer formed by a coating method, a thickness variation of the respective organic EL elements 10R, 10G, and 10B is reduced. Accordingly, a difference in luminescent efficiency and a variation in chromaticity among the organic EL elements 10R, 10G, and 10B can be suppressed. More particularly, the brightness and color unevenness in the display region, which will be caused by non-uniformity in thickness of the organic EL elements 10R, 10G, and 10B, are reduced, making it possible to manufacture a high-quality display of the organic EL display device.

### Second Embodiment

A second embodiment is now described. Like reference numerals as used in the first embodiment indicate like members or elements, which are not particularly illustrated again. Although a whole configuration of an organic EL display device according to the second embodiment of the present disclosure is not shown, there is formed, for example, a display region wherein a plurality of red organic EL elements 20R, green organic EL element 20G and blue organic EL element 20B are arranged in matrices on a substrate 11, like the first embodiment. A pixel drive circuit is provided within the display region.

In the display region, the red organic EL elements 20R generating red light, the green organic EL elements 20G generating green light and blue organic EL elements 20B generating blue light are successively arranged in matrices as a whole. It is to be noted that a combination of adjacent red organic EL element 20R, green organic EL element 20G and blue organic EL element 20B provides one pixel.

Like the first embodiment, a signal line drive circuit and a scanning line drive circuit, serving as drivers for picture display, are provided around the display region.

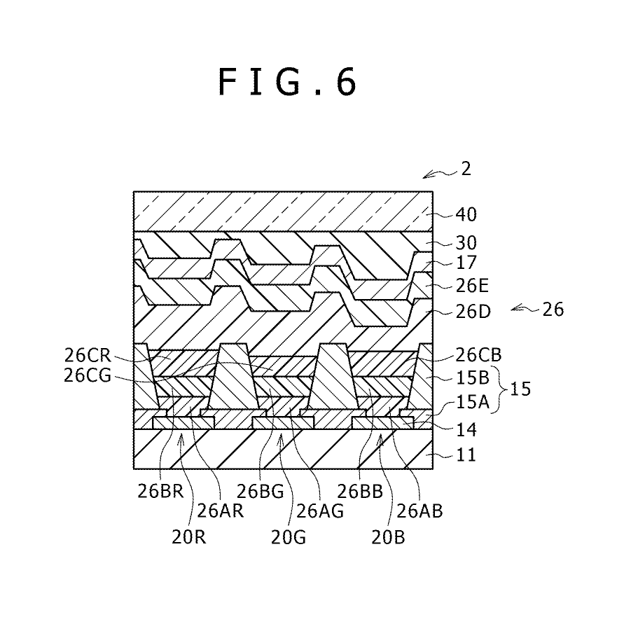

FIG. 6 shows a sectional configuration of the display region of the organic EL display device according to the second embodiment. Like the first embodiment, the red organic EL element 20R, green organic EL element 20G and blue organic EL element 20B are so configured that a drive transistor Tr1 of a pixel drive circuit and a flattening insulating film (not shown) are provided therebetween and there are successively stacked, as viewed from the side of the substrate 11, a lower electrode 14 serving as an anode, a partition wall 15, an organic layer 26 including a light-emitting layer 26C described hereinafter, and an upper electrode 17 serving as a cathode. Except for the organic layer 26, the substrate 11, lower electrode 14, partition wall 15 and upper electrode 17, and a protective layer 20 and a sealing substrate 40 are configured in the same way as in the first embodiment. In this case, the thickness of the common layer formed by a vacuum deposition method is designed to be larger than the thickness of the individual layer formed by a coating method.

The organic EL display device 2 of the embodiment differs from that of the first embodiment in that a blue light-emitting layer 26CB is formed only at the blue organic EL element 20B. More particularly, with the organic EL display device 2 of this embodiment, the individual layer includes the respective hole injection layer 26A (26AR, 26AG, and 26AB), the respective hole transport layer 26B, (26BR, 26BG, and 26BB) and the respective light-emitting layer 26C (26CR, 26CG, and 26CB), whereas the common layer includes an electron transport layer 26D and an electron injection layer 26E.

In particular, the organic layer 26 of the red organic EL element 20R is so configured to stack, as viewed from the side of the lower electrode 14, the hole injection layer 26AR, hole transport layer 26BR, red light-emitting layer 26CR, electron transport layer 26D and electron injection layer 26E. Like the red organic EL element 20R, the organic layer 26 of the green organic EL element 20G (and also of the blue organic EL element 20B) include, for example, stacked as viewed from the side of the lower electrode 14, the hole injection layer 26AG (26AB), hole transport layer 26BG (26BB), green light-emitting layer 26CG (blue light-emitting layer 26CB), electron transport layer 26D and electron injection layer 26E.

The blue light-emitting layer 26CG can be formed of such a material as used for the red light-emitting layer 16CR and green light-emitting layer 16CG illustrated in the first embodiment according to a coating method. The thickness of the organic light-emitting layer 26CB is preferably, for example, at 10 nm to 200 nm, more preferably at 15 nm to 150 nm, as with the case of the red light-emitting layer 16CR and green light-emitting layer 16CG. The high molecular weight material used as the blue light-emitting layer 16CB may be ADS136BE (registered tradename) represented by the formula (13) and made by American Dye Source Inc., and a blue phosphorescent material represented by the formula (14).

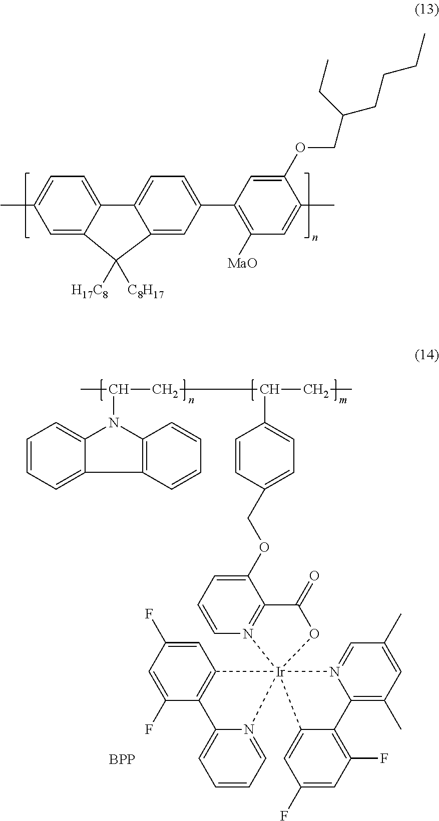

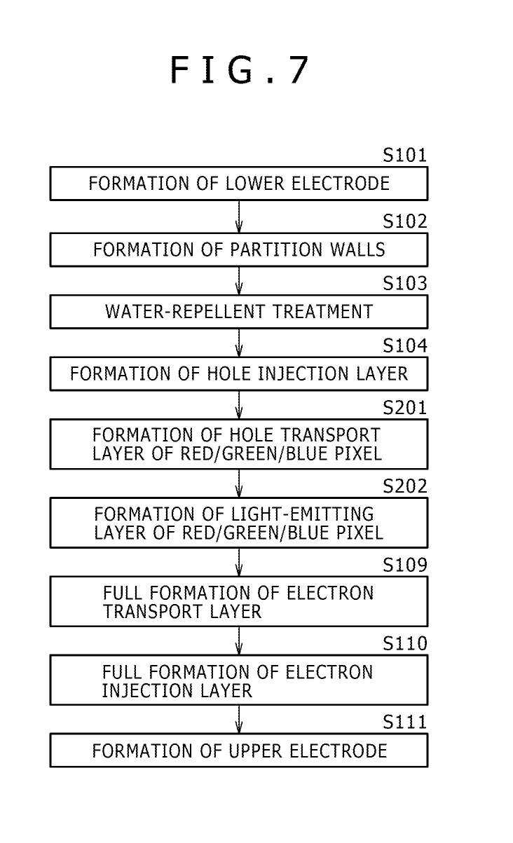

The organic EL display device 2 can be manufactured according to a procedure, as shown in FIG. 7, including adding, between the step S104 and the step S109 illustrated in the first embodiment, step S201 (formation of red, green, blue hole transport layers 26BR, 26BG, and 26BB) and step S202 (formation of light-emitting layers 26CR, 26CG, and 26CB) in this order.

### (Step of Forming Hole Transport Layers 26BR, 26BG, and 26BB)

After the formation of the hole injection layers 26AR, 26AG, and 26AB, hole transport layers 26BR, 26BG, and 26BB containing such a high molecular weight material and low molecular weight material as set out before are, respectively, formed on the hole injection layers 26AR, 26AG, and 26AB according to a coating method for each of the red organic EL element 20R, green organic EL element 20G and blue organic EL element 20B (Step S201).

### (Step of Forming Red Light-Emitting Layer 26CR, Green Light-Emitting Layer 26CG and Blue Light-Emitting Layer 26CB)

After the formation of the hole transport layers 26BR, 26BG, and 26BB, a red light-emitting layer 26CR made of a mixed material of such a high molecular weight material and low molecular weight material as set out before is formed on the hole transport layer BR of the red organic EL element 20R according to a coating method. Likewise, a green light-emitting layer 26CG and a blue light-emitting layer 26CB, which are, respectively, made of a mixed material such a high molecular weight material and low molecular weight material as set out before, are formed on the hole transport layers 26BG, 26BB of the green organic EL element 20G and blue organic EL element 20B according to a coating method, respectively (step S202).

In this way, with the organic EL display device 2 of this embodiment, the blue light-emitting layer 26CB is formed only for the blue organic EL element 20B by coating. In the organic EL display device 2 having a configuration as stated above, when the thickness of the common layer formed by a vacuum deposition method is larger than a thickness of the individual layer formed by a coating method, effects similar to those of the first embodiment can be obtained.

### (Module and Application Examples)

Application examples of the organic EL display device illustrated in the foregoing embodiments are now described. The organic EL display devices of the embodiments are applicable as a display device in all fields of electronic apparatus for image or picture display of a video signal input from outside or internally generated video signal, such as television apparatus, digital cameras, note-type personal computers, portable terminal devices such as cell phones, or video cameras.

### (Module)

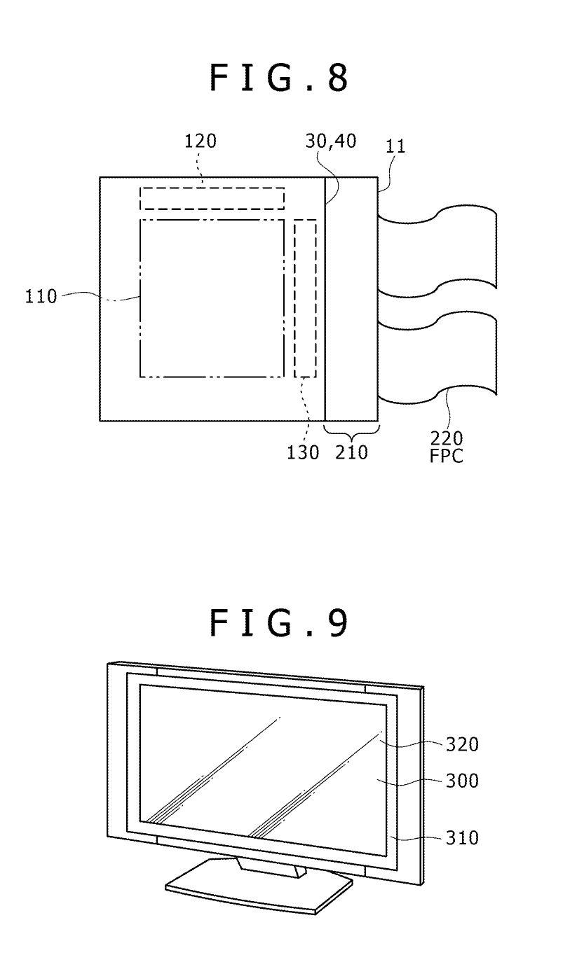

The organic EL display device of the embodiments may be assembled, as a module shown, for example, in FIG. 8, in different types of electronic apparatus such as of Application Examples 1 to 5 appearing hereinafter. This module includes, for example, a substrate 11, a region 210 provided at one side of the substrate 11 and exposed from a protective layer 30 and a sealing substrate 40, and external connection terminals (not shown) formed on the exposed region 210 by extending wirings of a signal line drive circuit 120 and a scanning line drive circuit 130. The external connection terminals may be provided with flexible printed circuit (FPC) boards 220 for inputting/outputting a signal.

### Application Example 1

FIG. 9 shows an appearance of a television apparatus, to which the organic EL display device of either of the foregoing embodiments is applied. This television apparatus has, for example, a picture display screen 300 including a front panel 310 and a filter glass 320 wherein the picture display screen 300 is constituted of the organic EL display device of the embodiment.

### Application Example 2

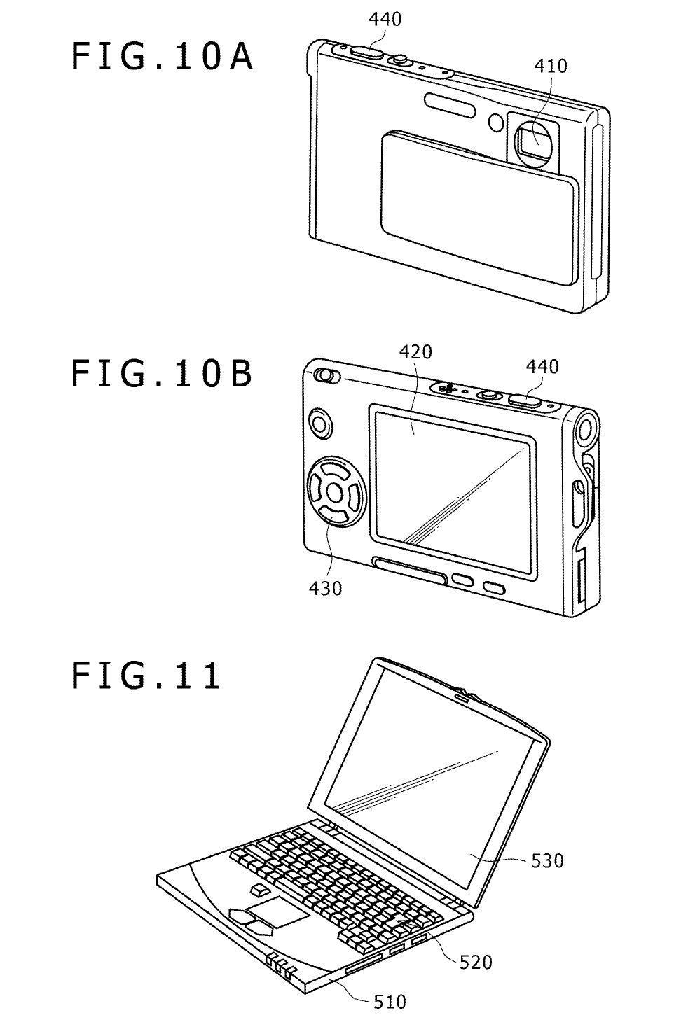

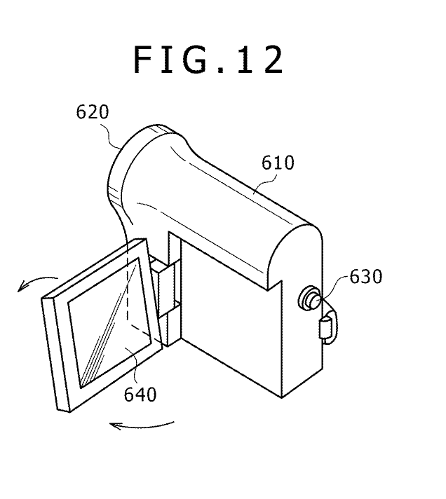

FIGS. 10A and 10B, respectively, show an appearance of a digital camera, to which the organic EL display device of either of the foregoing embodiments is applied. This digital camera has, for example, a flash emission unit 410, a display unit 420, a menu switch 430 and a shutter button 440, and the display unit 420 is constituted of the organic EL display device of the embodiment.

### Application Example 3

FIG. 11 shows an appearance of a note-type personal computer, to which the organic EL display device of either of the foregoing embodiments is applied. This note-type personal computer has, for example, a body 510, a keyboard 520 for inputting a character and the like and a display unit 530 for picture display wherein the display unit 530 is constituted of the organic EL display device of the embodiment.

### Application Example 4

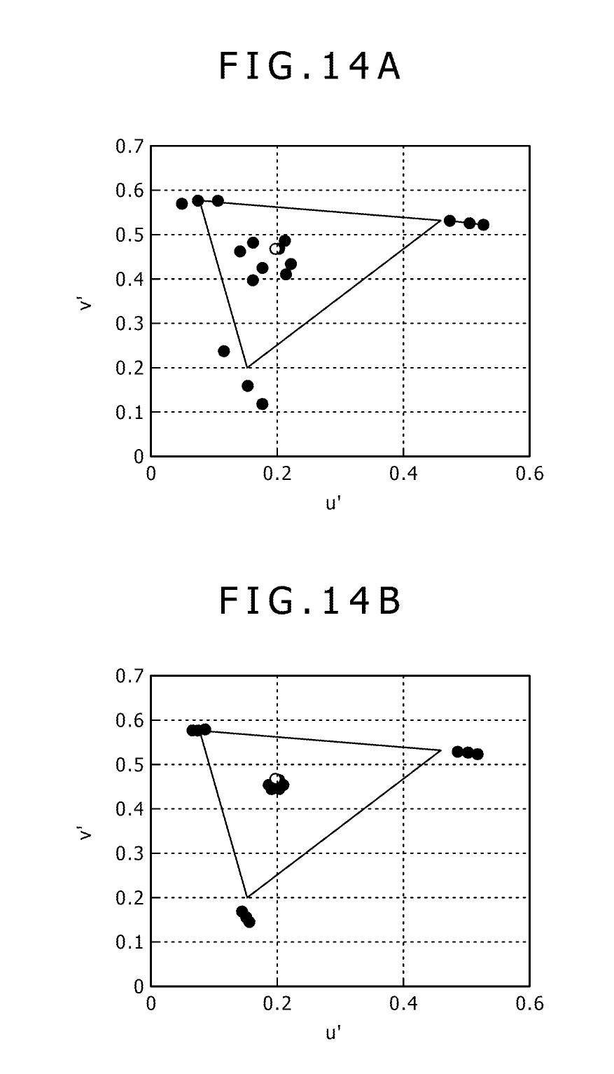

FIG. 14 shows an appearance of a video camera, to which the organic EL display device of either of the foregoing embodiments is applied. This video camera has, for example, a body 610, a subject lens 620 provided at a front side of the body 610, a shooting start/stop switch 630 and a display unit 640 wherein the display unit 640 is constituted of the organic EL display device of the embodiment.

### Application Example 5

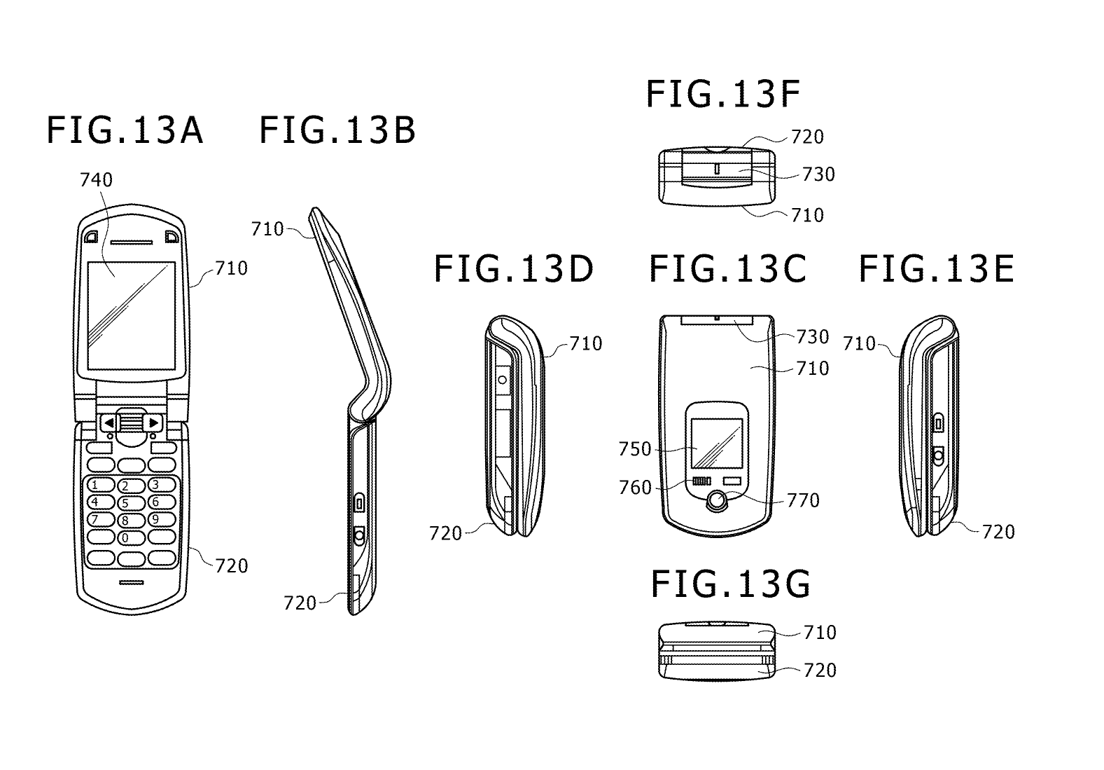

FIGS. 13A to 13G are, respectively, an appearance of a mobile phone, to which the organic EL display device of either of the foregoing embodiments is applied. This mobile phone has, for example, an upper chassis 710 and a lower chassis 720 connected with a connection unit (hinge unit) 730 and also has a display 740, a subdisplay 750, a picture light 760, and a camera 770. The display 740 or subdisplay 750 is constituted of the organic EL display device of the embodiment.

### Example 1

Red organic EL elements 10R, green organic EL elements 10G and blue organic EL elements 10B were, respectively, formed on a substrate 11 having a thickness of 25 mm×25 mm.

Initially, a glass substrate (25 mm×25 mm) provided as the substrate 11, on which a 130-nm thick Al—Nd alloy layer made of Al and neodium (Nd) was formed on the substrate 11 as a lower electrode 14. Thereafter, patterning for forming R, G and B pixels was performed by photolithography, followed by wet etching and peeling off of a photoresist to form the lower electrode 14 (step S101).

Next, a 50-nm thick SiO₂ film as formed by CVD (chemical vapor deposition) as partition walls separating the respective pixels from each other, followed by patterning with photolithography, dry etching and removal of a photoresist (step S102).

Subsequently, ND1501 (polyaniline, made by Nissan Chemical Industries, Ltd.) was coated in a thickness of 15 nm in air by a spin coating method for used as hole injection layers 16AR, 16AG, and 16AB, followed by thermal curing on a hot plate at 220° C. for 30 minutes (step S104).

In an atmosphere of N₂ (dew point: −60° C., oxygen concentration: 10 ppm), a polymer of the following formula (15) (polyvinyl carbazole) was coated on the hole injection layers 16AR and 16AG as hole transport layers 16BR and 16BG according to a spin coating method, respectively. The thickness was at 150 nm for the hole transport layer 16BR for the red organic EL element 10R and was at 20 nm for the hole transport layer 16BG for the green organic EL element 10G. Thereafter, thermal curing on a hot plate was performed in an atmosphere of N₂ (dew point: −60° C., oxygen concentration: 10 ppm) at 180° C. for 60 minutes (step S105).

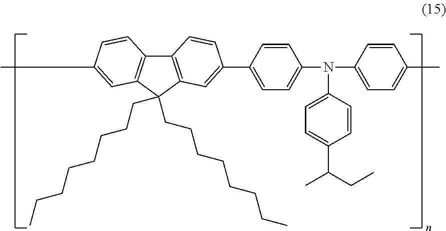

After the formation of the hole transport layers 16BR, and 16BG, a mixed material obtained by mixing a fluorenone polyarylene material having a benzothiazole block and a low molecular weight material represented, for example, by the foregoing formula (4-6) at a mixing ratio by weight of 2:1 was dissolved in xylene and coated, as a red light-emitting layer 16CR, on the hole transport layer 10BR of the red organic EL element 10R in a thickness of 80 nm according to a spin coating method. Likewise, a mixed material obtained by mixing a fluorenone polyarylene material having an anthracene block and a low molecular weight material represented, for example, by the foregoing formula (4-6) at a mixing ratio by weight of 2:1 was dissolved in xylene and coated, as a green light-emitting layer 16CG, on the hole transport layer 16BG of the green organic EL element 10G in a thickness of 80 nm according to a spin coating method. Subsequently, thermal curing on a hot plate was performed in an atmosphere of N₂ (dew point: −60° C., oxygen concentration: 10 ppm) at 130° C. for 10 minutes (step S106).

After the formation of the red light-emitting layer 16CR and green light-emitting layer 16CG, a lower molecular weight material represented, for example, by the afore-indicated formula (4-38) was coated, as a hole transport layer 16BB, in a thickness of 50 nm on the hole injection layer 16AB for the blue organic EL element 10B according to a spin coating method. Subsequently, thermal curing on a hot plate was performed in an atmosphere of N₂ (dew point: −60° C., oxygen concentration: 10 ppm) at 100° C. for 60 minutes (step S107).

After the formation of the hole transport layer 16BB, the substrate 11 for the red organic El element 10R after completion of formation of the red light-emitting layer 16CR, the substrate 11 for the green organic EL element 10G after completion of formation of the green light-emitting layer 16CG, and the substrate 11 for the blue organic EL element 10B after completion of formation of the hole transport layer 16BB were moved to a vacuum deposition machine, followed by formation of an electron transport layer 16D and subsequent layers.

Initially, AND (9,10-di(2-naphthyl)anthracene) represented by the formula (12-20) and a blue dopant of the following formula (16) were co-deposited at a ratio by weight of 95:5 to provide a blue light-emitting layer 16CB (step S108).

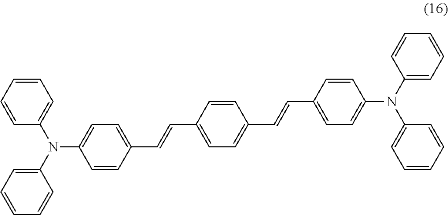

After the formation of the blue-light emitting layer 16CB, an organic material represented, for example, by the foregoing formula (7-15) was formed in a thickness of 15 nm as an electron transport layer 16D by a vacuum deposition method (step S109). Subsequently, LiF was formed in a thickness of 0.3 nm as an electron injection layer 16E (step S110) and a 10-nm thick Mg—Ag upper electrode 17 was formed, both by a vacuum deposition method (step S111). Finally, a protective layer 30 made of SiN was formed by a CVD method, followed by solid sealing with a transparent resin.

Two types of red organic EL elements 10R, green organic EL elements 10G and blue organic EL elements 10B were made, respectively. Samples wherein the thickness of the common layer (De) is larger than the thickness (Dw) of the individual layer, i.e. Dw<De, are taken as Examples of the present disclosure, and samples wherein the thickness (De) of the common layer is smaller than the thickness (Dw) of the individual layer, i.e. Dw>De, are taken as Comparative Examples. The emission spectra, luminescent efficiency (cd/A) when driven at a current density of 10 mA/cm², and chromaticity coordinates (x, y) were measured. As to the variation in chromaticity observed in panel plane, USC chromaticity coordinates (u′, v′) were measured and their differences Δu′, v′ were calculated, thereby confirming a chromaticity variation observed in the plane. The USC chromaticity is more uniform between the distance on chromaticity diagram and the human sense than the xy chromaticity, thus being suited as an index indicating a degree of variation of emission color.

Tables 1 and 2 show the tabulated results of a thickness ratio and the measurements in Comparative Examples and Examples respectively. Table 3 shows a brightness difference and a chromaticity different in Comparative Examples 1-1, 1-2 and Examples 1-1, 1-2 as a whole. FIGS. 16A and 16B, respectively, show characteristic diagrams showing a chromaticity distribution of the respective red organic EL elements 10R, green organic EL elements 10G and blue organic EL elements 10B of the Comparative Examples and Examples. It will be noted that the reference sample is one that has a layer thickness optically designed properly relative to the respectively preset layer thicknesses.

TABLE 1

| | Blue organic EL element (Dw:De = 80:20) | | | | Green organic EL element (Dw:De = 80:20) | | | | Red organic EL element (Dw:De = 80:20 ) | | | |
|---|---|---|---|---|---|---|---|---|---|---|---|---|
| | | | | Variation | | | | Variation | | | | Variation |
| | | | | in chro- | | | | in chro- | | | | in chro- |
| | Efficiency | vs. | Chro- | maticity | Efficiency | vs. | Chro- | maticity | Efficiency | vs. | Chro- | maticity |
| | (cd/A) | Ref | maticity | (Δu′v′) | (cd/A) | Ref | maticity | (Δu′v′) | (cd/A) | Ref | maticity | (Δu′v′) |
| Reference | 2.4 | — | 0.13, 0.06 | — | 10.8 | — | 0.21, 0. 72 | — | 7.5 | — | 0.69, 0.32 | — |
| Sample | | | | | | | | | | | | |
| Comparative | 2.3 | 96% | 0.12, 0.11 | 0.089 | 8.5 | 79% | 0.28, 0.68 | 0.031 | 5.1 | 68% | 0.70, 0.30 | 0.023 |
| Example 1-1 | | | | | | | | | | | | |
| Comparative | 1.5 | 63% | 0.14, 0.04 | 0.047 | 6.3 | 58% | 0.14, 0.72 | 0.027 | 3.6 | 48% | 0.67, 0.33 | 0.032 |
| Example 1-2 | | | | | | | | | | | | |

TABLE 2

| | Blue organic EL element (Dw:De = 20:80) | | | | Green organic EL element (Dw:De = 30:70) | | | | Red organic EL element (Dw:De = 45:55) | | | |
|---|---|---|---|---|---|---|---|---|---|---|---|---|
| | | | | Variation | | | | Variation | | | | Variation |
| | | | | in chro- | | | | in chro- | | | | in chro- |
| | Efficiency | vs. | Chro- | maticity | Efficiency | vs. | Chro- | maticity | Efficiency | vs. | Chro- | maticity |
| | (cd/A) | Ref | maticity | (Δu′v′) | (cd/A) | Ref | maticity | (Δu′v′) | (cd/A) | Ref | maticity | (Δu′v′) |
| Reference | 2.3 | — | 0.13, 0.06 | — | 12.2 | — | 0.68, 0.32 | — | 10.3 | — | 0.68, 0.32 | — |
| Sample | | | | | | | | | | | | |
| Example | 2.4 | 104% | 0.13, 0.07 | 0.015 | 12.0 | 98% | 0.69, 0.31 | 0.010 | 9.0 | 88% | 0.69, 0.31 | 0.015 |
| 1-1 | | | | | | | | | | | | |
| Example | 2.1 | 91% | 0.14, 0.06 | 0.013 | 11.1 | 91% | 0.68, 0.32 | 0.009 | 8.5 | 85% | 0.68, 0.32 | 0.015 |
| 1-2 | | | | | | | | | | | | |

TABLE 3

Standard difference

| | Comparative | |
|---|---|---|
| | Example | Example |
| Brightness | −45% | −12% |
| difference (%) | | |
| Chromaticity | 0.08 | 0.02 |
| (Δu′v′) | | |

As will be seen from Tables 1 and 2, when the thickness of the common layer is larger than that of the individual layer in the respective red, green and blue organic EL elements 10R, 10G and 10B, the difference in luminescent efficiency and the variation in chromaticity relative to the reference sample are small. In the Comparative Examples of the red, green and blue organic EL elements 10R, 10G, and 10B (Table 1), the variation in emission spectrum relative to the reference sample is great, whereas the variation in luminescent efficiency of the Examples relative to the reference sample is very small (Table 2). Moreover, as will be seen from Table 3, the brightness and chromaticity differences of the red, green and blue organic EL elements 10R, 10G and 10B become small. Especially, when taking into account the fact that the brightness difference of currently available organic EL display devices is at approximately 20%, a difference in luminescent efficiency among a plurality of organic EL elements is adequately reduced. More particularly, because of the ease in thickness control, a variation in thickness among organic EL elements is reduced, thereby enabling a difference in luminescent efficiency and a variation in chromaticity on element-to-element basis to be suppressed.

It will be noted that such effects as set out above are obtained not only with the case where the blue light-emitting layer 16CB is formed as a common layer by a vacuum deposition method as having illustrated in the foregoing Examples, but also with the case where the blue light-emitting layer 16CB is formed as an individual layer by a coating method. Although a spin coating method is used for the coating method in the Examples, the manner of coating is not critical. Similar results as in those of the Examples could be obtained in case of an organic EL display device, which was obtained by spraying an organic EL material according to a spraying procedure any of various printing techniques including an inkjet technique, a nozzle jet technique, an offset technique, a flexo technique, a gravure technique and the like and a spray-coating method, and selectively coating through a high-precision mask.

The present disclosure has been illustrated by way of the embodiments and Examples, to which the disclosure should not be construed as limited, and many alterations and modifications may be possible without departing from the spirit of the disclosure.

For instance, the materials and thicknesses of the respective layers described in the embodiments and Examples, and the manner of film formation and film-forming conditions are not limited to those described, and other types of materials and thicknesses may be used. Other film-forming methods and conditions may also be used.

Although a low molecular weight material (monomer) is used as the blue hole transport layer 16BB in Examples 1-1 and 1-2, a polymerized oligomer material or polymer material may also be used without limitation. It will be noted that where a low molecular weight material is used for a coating method such as a spin coating method or an inkjet method, the viscosity of a solution to be coated usually becomes small, so that limitation may be undesirably placed on a control range of layer thickness. This problem is solved by use of an oligomer or polymer material having an increased molecular weight.

Further, although hole transport characteristics of the red light-emitting layers 16CR and 26CR and green light-emitting layers 16CG and 26CG are improved in the embodiments and Examples by addition of a low molecular weight material thereto, similar effects can be obtained by using a polymer material having a structural site or a substituent group functioning for hole transport in order to form the red light-emitting layers 16CR and 26CR and green light-emitting layers 16CG and 26CG.

In the foregoing embodiments and Examples, configurations of the organic EL elements 10R, 10G and 10B have been specifically illustrated. However, all the layers indicated may not be always provided, or other layer may be added thereto. For instance, the hole transport layers 16BB and 26BB of the blue organic EL elements 10B and 20B may be omitted, and instead, a common hole transport layer 26F may be formed directly on the hole injection layers 16AB and 26AB, respectively. This permits the number of manufacturing steps and costs to be reduced and saved. Moreover, a layer having a hole blocking characteristic may be provided, as a common layer, between the red light-emitting layer 26CR, green light-emitting layer 26CG and blue light-emitting layer 26CB, each formed as an individual layer and the electron transport layer 26D provided as the common layer. In doing so, the movement of holes to the electron transport layer 26D is suppressed thereby improving a luminescent efficiency and reducing a chromaticity change ascribed to the movement of the emission region.

In the foregoing embodiments and Examples, the display device provided with the red and green organic EL elements as an organic EL element other than the blue EL element has been illustrated. This disclosure may be applicable to a display device made up, for example, of a blue organic EL element and a yellow organic EL element.

Still further, in the foregoing embodiments, an active matrix display device has been illustrated, and the present disclosure may be applied to a passive matrix display device. In addition, the configuration of a pixel drive circuit for active matrix drive is not limited to as illustrated in the embodiments. Capacitor elements and transistors may be added to the circuit, if required. In this case, a necessary drive circuit may be added to depending on the alteration of pixel drive circuit, aside from such signal lien drive circuit 120 and scanning line drive circuit 130 as set out before.

The present disclosure contains subject matter related to that disclosed in Japanese Priority Patent Application JP 2011-009853 filed in the Japan Patent Office on Jan. 20, 2011, the entire content of which is hereby incorporated by reference.

What is claimed is:

1. An organic electro luminescence display device comprising:
on a substrate, a plurality of lower electrodes provided correspondingly in number to organic electro luminescence elements for a plurality of color light emissions;
an organic layer provided on the lower electrodes and including a plurality of hole injection/transport layers having at least one of hole injection and hole transport characteristics, a plurality of organic light-emitting layers; and
a plurality of electron injection/transport layers having at least one of electron injection and electron transport characteristics, and an upper electrode formed on said organic layer,
wherein said hole injection/transport layer, said organic light-emitting layer and said electron injection/transport layer are classified into an individual layer formed for each of said organic electro luminescence elements for the respective color light emissions and a common layer formed on the entire surface of said organic electro luminescence elements of the respective color light emissions, and
a thickness of said common layer is larger than a thickness of said individual layer.

2. The organic electro luminescence display device according to claim 1,
wherein said respective organic electro luminescence elements include a blue first organic electro luminescence element and a second organic electro luminescence element for other color.

3. The organic electro luminescence display device according to claim 2,
wherein said organic layer includes a hole injection/transport layer provided on each of said first organic electro luminescence element and said second organic electro luminescence element, a second organic light-emitting layer formed on the hole injection/transport layer for said second organic electro luminescence element, a blue first organic light-emitting layer provided over an entire surface of said second organic light-emitting layer and the hole injection/transport layer for said first organic electro luminescence element, and an electron injection/transport layer formed on said first organic light-emitting layer and having at least one of electron injection and electron transport characteristics.

4. The organic electro luminescence display device according to claim 2,
wherein said organic layer comprises said hole injection/transport layer provided on each of said first organic electro luminescence element and said second organic electro luminescence element, a first organic light-emitting layer and a second organic light-emitting layer formed on said hole injection/transport layer for each of said first organic electro luminescence element and said second organic electro luminescence element, and an electron injection/transport layer formed on said first organic light-emitting layer and said second organic light-emitting layer and having at least one of electron injection and electron transport characteristics.

5. The organic electro luminescence display device according to claim 1,
wherein said individual layer is formed by a coating method.

6. The organic electro luminescence display device according to claim 1,
wherein said common layer is formed by a vacuum deposition method.

7. The organic electro luminescence display device according to claim 1,
wherein said organic layer has a thickness of 150 nm to 500 nm.

8. The organic electro luminescence display device according to claim 1,
wherein said common layer has a thickness of 100 nm to 250 nm.

9. The organic electro luminescence display device according to claim 1,
wherein said a thickness (Dw) of said common layer and a thickness (De) of said individual layer has a relation represented by the following mathematical formula
Dw>De×0.1.

10. The organic electro luminescence display device according to claim 1,
wherein said electron injection/transport layer is made of a nitrogen-containing heterocyclic compound represented by the formula (1) 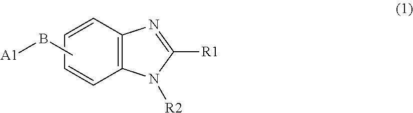
in which A1 represents a hydrogen atom or halogen atom, an alkyl group having 1 to 20 carbon atoms, or a hydrocarbon group or nitrogen-containing heterocyclic group or a derivative thereof having 6 to 60 carbon atoms and having a polycyclic aromatic hydrocarbon group made of 3 to 40 aromatic rings condensed, B is a single bond, or a divalent aromatic ring group or a derivative thereof, R1 and R2 are independently a hydrogen atom or halogen atom, an alkyl group having 1 to 20 carbon atoms, an aromatic hydrocarbon group having 6 to 60 carbon atoms, a nitrogen-containing heterocyclic ring group, or an alkoxy group having 1 to 20 carbon atoms, or a derivative thereof.

11. The organic electro luminescence display device according to claim 1,
wherein said electron injection/transport layer is made of a nitrogen-containing heterocyclic compound represented by the formula (2) 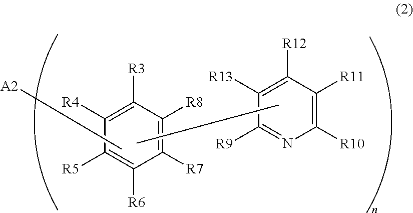
in which A2 is an n-valent group made of two to five aromatic rings condensed, or a derivative thereof, R3 to R8 independently represent a hydrogen atom or halogen atom, or a free atomic valence bonding to any one of A2 or R9 to R13, R9 to R13 independently represent a hydrogen atom or halogen atom, or a free atomic valence bonding to any one of R3 to R8, and n is an integer of not smaller than two and n number of pyridylphenyl groups may be the same or different.

12. The organic electro luminescence display device according to claim 1,
wherein said electron injection/transport layer is made of a nitrogen-containing heterocyclic compound represented by the formula (3) 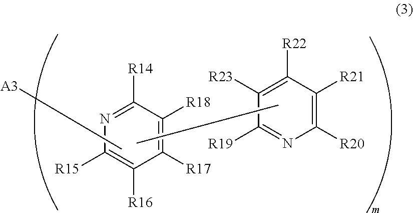
in which A3 represents an m-valent group made of two to five aromatic rings condensed or a derivative thereof, R14 to R18 independently represent a hydrogen atom or halogen atom, or a free atomic valence bonding to any one of A3 or R19 to R23, R19 to R23 independently represent a hydrogen atom or halogen atom, or a free atomic valence bonding to any one of R14 to R18, m is an integer of not smaller than two and m number of bipyridyl groups may be the same or different.

13. The organic electro luminescence display device according to claim 2,
wherein said second organic electro luminescence element for other color includes at least one of a red organic electro luminescence element, a green organic electro luminescence element and a yellow organic electro luminescence element.

14. A method for manufacturing an organic electro luminescence display device comprising:
forming, on a substrate, a lower electrode for each of first organic electro luminescence elements for blue light emission and second organic electro luminescence elements for other light emission;
forming a hole injection/transport layer having at least one of hole injection and hole transport characteristics on the lower electrode for each of the first organic electro luminescence elements and the second organic electro luminescence elements according to a coating method;
forming a second organic light-emitting layer for other light emission on the hole injection/transport layer for the second organic electro luminescence element according to a coating method;
forming a first organic light-emitting layer for blue light emission over an entire surface of said second organic light-emitting layer and said hole injection/transport layer for said first organic electro luminescence element according to a vacuum deposition method;
forming an electron injection/transport layer having at least one of electron injection and electron transport characteristics on said first organic light-emitting layer and said second organic light-emitting layer according to a vacuum deposition method; and
forming an upper electrode over an entire surface of said electron injection/transport layer.

15. The method according to claim 14,
wherein said coating method is an inkjet method, a nozzle coating method, a spin coating method, an offset method, a flexo method or a relief method.

16. A method for manufacturing an organic electro luminescence display device comprising:
forming, on a substrate, a plurality of lower electrodes for a corresponding plurality of organic electro luminescence elements;
forming a plurality of hole injection/transport layers having at least one of hole injection and hole transport characteristics on the lower electrodes with respect to each of the organic electro luminescence elements according to a coating method;
forming a plurality of organic light-emitting layers on the hole injection/transport layers with respect to each of the organic electro luminescence elements according to a coating method;
forming an electron injection/transport layer having at least one electron injection and electron transport characteristics over an entire surface of the plurality of organic light-emitting layers according to a vapor deposition method; and
forming an upper electrode over an entire surface of the electron injection/electron transport layer.

17. The method according to claim 16,
wherein said coating method is an inkjet method, a nozzle coating method, a spin coating method, an offset method, a flexo method or a relief method.
